(19) United States
(12) Patent Application Publication
(10) Pub. No.: US 2024/0297621 A1
(43) Pub. Date: Sep. 5, 2024

(54) METHODS, APPARATUS, AND ARTICLES OF MANUFACTURE TO IMPROVE DIGITAL PRE-DISTORTION

(71) Applicant: Texas Instruments Incorporated, Dallas, TX (US)

(72) Inventors: Jawaharlal Tangudu, Bangalore (IN); Goutham Ramesh, Bangalore (IN); Sarma Sundareswara Gunturi, Bangalore (IN); Harsh Garg, Delhi (IN); Jaiganesh Balakrishnan, Bangalore (IN); Mathews John, Bangalore (IN); Sashidharan Venkatraman, Bangalore (IN); Sanjay Pennam, Visakhapatnam (IN)

(21) Appl. No.: 18/592,045

(22) Filed: Feb. 29, 2024

(30) Foreign Application Priority Data
Mar. 2, 2023 (IN) 202341013991
Mar. 10, 2023 (IN) 202341016020

(51) Int. Cl. H03F 1/32; H03F 3/21

(52) U.S. Cl. CPC H03F 1/3241; H03F 3/21; H03F 2201/3233

(57) ABSTRACT

An example method includes switching a first multiplexer circuit associated with first delay circuitry from (a) a first sub-lookup table (LUT) of a first LUT of digital pre-distortion (DPD) corrector circuitry to (b) a first corresponding sub-LUT of a second LUT of the DPD corrector circuitry, the first sub-LUT associated with the first delay circuitry, the second LUT storing updated values to compensate for non-linearity of power amplifier circuitry of a transmitter including the DPD corrector circuitry. The method includes, based on a value of a counter being equal to a difference between (1) a first delay of the first delay circuitry and (2) a second delay of second delay circuitry, switching a second multiplexer circuit associated with the second delay circuitry from (a) a second sub-LUT of the first LUT to (b) a second corresponding sub-LUT of the second LUT, the second sub-LUT associated with the second delay circuitry.

### CROSS-REFERENCE TO RELATED APPLICATION

This patent application claims the benefit of and priority to Indian Provisional Patent Application Serial No. 202341013991 filed Mar. 2, 2023, and Indian Provisional Patent Application Serial No. 202341016020 filed Mar. 10, 2023, which applications are hereby incorporated herein by reference in their entireties.

### TECHNICAL FIELD

This description relates generally to wireless communication and, more particularly, to methods, apparatus, and articles of manufacture to improve digital pre-distortion.

### BACKGROUND

Wireless communications technology enables a wide variety of electronic devices (e.g., mobile phones, tablets, laptops, etc.) to support the execution of increasingly diverse and complex workloads. The secure, efficient, and accurate exchange of information over a wireless medium includes technical challenges. One such technical challenge is attenuation, which refers to the continued dissipation of a signal as the signal traverses a medium. In general, a signal will have more attenuation when transmitted through a wireless medium than the signal would have when transmitted through a wired medium. To counteract signal attenuation, manufacturers include power amplifier (PA) circuitry in a device to boost the power of a signal before transmission through a medium.

### SUMMARY

For methods, apparatus, and articles of manufacture to improve digital pre-distortion, an example apparatus includes envelope generator circuitry having an output terminal and an input terminal coupled to a digital pre-distortion (DPD) terminal. The apparatus includes first delay circuitry having a first output terminal, a second output terminal, a third output terminal, and an input terminal coupled to the output terminal of the envelope generator circuitry. The apparatus includes a first lookup table (LUT) having an output terminal and an input terminal coupled to the first output terminal of the first delay circuitry. The apparatus includes a second LUT having an output terminal and an input terminal coupled to the second output terminal of the first delay circuitry. The apparatus includes a third LUT having an output terminal and an input terminal coupled to the third output terminal of the first delay circuitry. The apparatus includes second delay circuitry having a first output terminal, a second output terminal, a third output terminal, a fourth output terminal, and an input terminal coupled to the DPD terminal. The apparatus includes a first multiplier circuit having an output terminal, a first input terminal coupled to the output terminal of the first LUT, and a second input terminal coupled to the first output terminal of the second delay circuitry. The apparatus includes conjugate generator circuitry having an output terminal and an input terminal coupled to the second output terminal of the second delay circuitry. The apparatus includes a second multiplier circuit having an output terminal, a first input terminal coupled to the output terminal of the second LUT, and a second input terminal coupled to the output terminal of the conjugate generator circuitry. The apparatus includes a third multiplier circuit having an output terminal, a first input terminal coupled to the output terminal of the third LUT, and a second input terminal coupled to the third output terminal of the second delay circuitry. The apparatus includes first adder circuitry having an output terminal, a first input terminal, a second input terminal, and a third input terminal, the first input terminal of the first adder circuitry coupled to the output terminal of the first multiplier circuit. The apparatus includes squared signal generator circuitry having an output terminal and an input terminal coupled to the DPD terminal. The apparatus includes third delay circuitry having an output terminal and an input terminal coupled to the output terminal of the squared signal generator circuitry. The apparatus includes a fourth multiplier circuit having an output terminal coupled to the second input terminal of the first adder circuitry, a first input terminal coupled to the output terminal of the second multiplier circuit, and a second input terminal coupled to the output terminal of the third delay circuitry. The apparatus includes squared envelope generator circuitry having an output terminal and an input terminal coupled to the DPD terminal. The apparatus includes fourth delay circuitry having an output terminal and an input terminal coupled to the output terminal of the squared envelope generator circuitry. The apparatus includes a fifth multiplier circuit having an output terminal coupled to the third input terminal of the first adder circuitry, a first input terminal coupled to the output terminal of the third multiplier circuit, and a second input terminal coupled to the output terminal of the fourth delay circuitry. The apparatus includes second adder circuitry having an output terminal, a first input terminal coupled to the fourth output terminal of the second delay circuitry, and a second input terminal coupled to the output terminal of the first adder circuitry. Other examples are described.

For methods, apparatus, and articles of manufacture to improve digital pre-distortion, an example apparatus includes envelope generator circuitry having an output terminal and an input terminal coupled to a digital pre-distortion (DPD) terminal. The apparatus includes first delay circuitry having a first output terminal, a second output terminal, a third output terminal, and an input terminal coupled to the output terminal of the envelope generator circuitry. The apparatus includes a first lookup table (LUT) having an output terminal and an input terminal coupled to the first output terminal of the first delay circuitry. The apparatus includes second delay circuitry having an output terminal and an input terminal coupled to the output terminal of the first LUT. The apparatus includes a second LUT having an output terminal and an input terminal coupled to the second output terminal of the first delay circuitry. The apparatus includes third delay circuitry having an output terminal and an input terminal coupled to the output terminal of the second LUT. The apparatus includes a third LUT having an output terminal and an input terminal coupled to the third output terminal of the first delay circuitry. The apparatus includes fourth delay circuitry having an output terminal and an input terminal coupled to the output terminal of the third LUT. The apparatus includes fifth delay circuitry having a first output terminal, a second output terminal, and an input terminal coupled to the DPD terminal. The apparatus includes squared envelope generator circuitry having an output terminal and an input terminal coupled to the DPD terminal. The apparatus includes squared signal generator circuitry having an output terminal and an input terminal coupled to the DPD terminal. The apparatus includes sixth delay circuitry having an output terminal and an input terminal coupled to the DPD terminal. The apparatus includes sub-term generator circuitry having a first output terminal, a second output terminal, a first input terminal coupled to the output terminal of the sixth delay circuitry, a second input terminal coupled to the output terminal of the squared envelope generator circuitry, and a third input terminal coupled to the output terminal of the squared signal generator circuitry. The apparatus includes seventh delay circuitry having an output terminal and an input terminal coupled to the first output terminal of the sub-term generator circuitry. The apparatus includes eighth delay circuitry having an output terminal and an input terminal coupled to the second output terminal of the sub-term generator circuitry. The apparatus includes a first multiplier circuit having an output terminal, a first input terminal coupled to the output terminal of the second delay circuitry, and a second input terminal coupled to the first output terminal of the fifth delay circuitry. The apparatus includes a second multiplier circuit having an output terminal, a first input terminal coupled to the output terminal of the third delay circuitry, and a second input terminal coupled to the output terminal of the seventh delay circuitry. The apparatus includes a third multiplier circuit having an output terminal, a first input terminal coupled to the output terminal of the fourth delay circuitry, and a second input terminal coupled to the output terminal of the eighth delay circuitry. The apparatus includes first adder circuitry having an output terminal, a first input terminal coupled to the output terminal of the first multiplier circuit, a second input terminal coupled to the output terminal of the second multiplier circuit, and a third input terminal coupled to the output terminal of the third multiplier circuit. The apparatus includes second adder circuitry having an output terminal, a first input terminal coupled to the second output terminal of the fifth delay circuitry, and a second input terminal coupled to the output terminal of the first adder circuitry. Other examples are described.

For methods, apparatus, and articles of manufacture to improve digital pre-distortion, an example method includes switching a first multiplexer circuit associated with first delay circuitry from (a) a first sub-lookup table (LUT) of a first LUT of digital pre-distortion (DPD) corrector circuitry to (b) a first corresponding sub-LUT of a second LUT of the DPD corrector circuitry, the first sub-LUT associated with the first delay circuitry, the second LUT storing updated values to compensate for non-linearity of power amplifier circuitry of a transmitter including the DPD corrector circuitry. The method includes, based on a value of a counter being equal to a difference between (1) a first delay of the first delay circuitry and (2) a second delay of second delay circuitry, switching a second multiplexer circuit associated with the second delay circuitry from (a) a second sub-LUT of the first LUT to (b) a second corresponding sub-LUT of the second LUT, the second sub-LUT associated with the second delay circuitry. Other examples are described.

For methods, apparatus, and articles of manufacture to improve digital pre-distortion, an example includes processor circuitry having an output terminal, the processor circuitry configured to generate a signal. The apparatus includes digital pre-distortion (DPD) corrector circuitry having an input terminal and an output terminal, the input terminal coupled to the output terminal of the processor circuitry. The apparatus includes power amplifier (PA) circuitry having an input terminal coupled to the output terminal of the DPD corrector circuitry, the DPD corrector circuitry configured to: access at least one lookup table based on first delayed versions of an envelope of the signal to determine first values, second values, and third values of non-linear functions that model a non-linearity of the PA circuitry; determine first products based on the first values and second delayed versions of the signal; determine second products based on the second values, conjugates of the second delayed versions of the signal, and a squared version of the signal; determine third products based on the third values, the second delayed versions of the signal, and a squared envelope of the signal; and determine the pre-distorted version of the signal based on a pre-distortion signal and the signal, the pre-distortion signal based on the first products, the second products, and the third products. Other examples are described.

### BRIEF DESCRIPTION OF THE DRAWINGS

FIG. 1A is an example block diagram of a communication system.

FIG. 1B is a block diagram of an example implementation of the transmitter circuitry of FIG. 1A.

FIG. 2 is a block diagram of a first example implementation of the DPD corrector circuitry of FIG. 1B.

FIG. 3 is a block diagram of an example implementation of the lookup table (LUT) adder circuitry of FIG. 2.

FIG. 4 is a block diagram of a second example implementation of the DPD corrector circuitry of FIG. 1B.

FIGS. 5A and 5B (collectively referred to as FIG. 5) are a block diagram of a third example implementation of the DPD corrector circuitry of FIG. 1B.

FIG. 6A is a block diagram of a fourth example implementation of the DPD corrector circuitry of FIG. 1B.

FIG. 6B is a block diagram of an example implementation of the sub-term generator circuitry of FIG. 6A.

FIG. 7 is a block diagram of a fifth example implementation of the DPD corrector circuitry of FIG. 1B.

FIG. 8 is a flowchart representative of at least one of example machine-readable instructions or example operations that may be at least one of executed, instantiated, or performed using an example programmable circuitry implementation of the DPD corrector circuitry of any of FIG. 1, 2, 4, 5, 6A, or 7.

FIG. 9 is a sequence diagram representative of example operations to update an example concatenated LUT.

FIG. 10 is a block diagram of an example implementation of an example spare concatenated LUT shared between at least two instances of transmitter circuitry of example transceiver circuitry.

FIG. 11 is a flowchart representative of at least one of example machine-readable instructions or example operations that may be at least one of executed, instantiated, or performed using example programmable circuitry to update one or more concatenated LUTs.

FIG. 12 is a block diagram of a first example implementation of an example LUT that supports parallelization.

FIG. 13 is a block diagram of an example implementation of the input mapping circuitry of FIG. 12.

FIGS. 14A and 14B (collectively referred to as FIG. 14) are a flowchart representative of at least one of example machine-readable instructions or example operations that may be at least one of executed, instantiated, or performed using an example programmable circuitry implementation of the input mapping circuitry of any of FIG. 12 or 13.

FIG. 15 is a block diagram of a second example implementation of an example LUT that supports parallelization.

FIGS. 16A and 16B (collectively referred to as FIG. 16) are a flowchart representative of at least one of example machine-readable instructions or example operations that may be at least one of executed, instantiated, or performed using an example programmable circuitry implementation of the input mapping circuitry of FIG. 15.

FIG. 17 is a block diagram of an example processing platform including programmable circuitry structured to at least one of execute, instantiate, or perform at least one of the example machine-readable instructions or the example operations of any of FIG. 8, 11, 14, or 16 to implement the DPD corrector circuitry of any of FIG. 1, 2, 4, 5, 6, or 7.

The same reference numbers or other reference designators are used in the drawings to designate the same or similar (at least one of functional or structural) features.

### DETAILED DESCRIPTION

The drawings are not necessarily to scale. Generally, the same reference numbers in the drawing(s) and this description refer to the same or like parts. Although the drawings show regions with clean lines and boundaries, at least one of some or all of these lines or some or all of these boundaries may be idealized. In reality, at least one of the boundaries or the lines may be at least one of unobservable, blended, or irregular.

Manufacturers include PA circuitry in electronic devices (e.g., wireless base stations) to boost the power of signals before transmission through a medium. To improve the efficiency of PA circuitry (e.g., to increase a ratio of output power to input power), the PA circuitry is operated in a non-linear region (e.g., a saturation region). As the temperature of or input signal profile to PA circuitry changes, the non-linearity of the PA circuitry can change. In examples described herein, linearity refers to a measure of how well an input signal and a corresponding output signal can be linearly related (e.g., characterized using a linear equation). While an electronic device (e.g., a wireless base station) can save power and resources by operating PA circuitry at an improved efficiency, the PA circuitry can generate non-linear output signals as a result of being operated in a non-linear region.

For example, PA circuitry operated in a non-linear region creates harmonic distortion (HD) and inter-modulation (IMD) spectral components in an output signal. Such distortion can increase at least one of an adjacent channel leakage ratio (ACLR) or an error vector magnitude (EVM) in an output signal generated by PA circuitry. ACLR is a measure of (a) relative power in specified channels offset from an assigned channel of a transmitted signal with respect to (b) the power transmitted within the assigned channel. EVM is a measure of deviation of amplitudes and phase shifts of symbols in a transmitted signal from ideal constellation points. In examples described herein, an example frequency band may be divided into one or more channels where a channel refers to a frequency range within the frequency band. Accordingly, ACLR is a measure of signal leakage outside an assigned frequency range and EVM is a measure of in-range signal quality loss. Therefore, an increase in ACLR or EVM results in a lower probability of a receiver properly decoding a received signal.

In some examples, manufacturers utilize digital pre-distortion (DPD) correction to compensate for nonlinearity of PA circuitry. For example, DPD correction is utilized in every instance of transmitter circuitry of a wireless base station. Digital circuitry implementing DPD correction can be integrated with a base-band processor or a transceiver system on a chip (SoC). DPD correction includes distorting an input baseband signal before the input baseband signal is sent to the PA circuitry. For example, a nonlinear output caused by PA circuitry can be characterized as a function ƒ(x), where x is the input signal to the PA circuitry and ƒ⁻¹( ) is a distortion function representative of the non-linearity of the PA circuitry. DPD correction counteracts nonlinearity by applying an inverse function, ƒ⁻¹( ) to the input signal and providing the output to the PA circuitry. In some examples, the inverse function f⁻¹( ) is referred to as a pre-distortion. As such, the non-linearity introduced by PA circuitry is counteracted by the pre-distortion applied to the input signal and the PA circuitry generates an amplified version of the input signal (e.g., ƒ(ƒ⁻¹(x))=x). Thus, DPD correction reduces nonlinearity of PA circuitry while allowing the PA circuitry to operate at an improved efficiency.

Manufacturers may use a wide variety of DPD models to define an inverse function ƒ⁻¹( ). One such model is a generalized memory polynomial (GMP) model. The GMP model is illustrated below in Equation 1.

$$y ( n ) = x ( n ) + {\sum }_{k = 1}^{M} x ( n - {l}_{1} ( k ) ) * {f}_{k} ( \vert x ( n - {l}_{2} ( k ) ) \vert ) \qquad Equation 1$$

In the example of Equation 1, x(n) represents an input signal, y(n) represents a pre-distorted version of the input signal, and |x(n)| represents a function to compute the envelope of x(n). For example, |x(n)| can be determined by computing the square root of the sum of the squared real and squared imaginary components of x(n) (e.g., |x(n)|={square root over (Re(x(n))²+Im(x(n))²))}. In Equation 1, l₁ (k) and l₂ (k) represent delays (e.g., at least one of positive or negative) applied to x(n) and |x(n)|, respectively. Also, in Equation 1, the non-linearity of PA circuitry is modeled by M non-linear functions fk( ). In Equation 1, ƒₖ(|x(n−l₂(k)|) represents an output of a non-linear function indexed by |x(n−l₂(k)|.

There are a variety of types of PA circuitry and a variety of use cases for PA circuitry. For example, PA circuitry can be manufactured using a variety of process nodes (e.g., a Gallium Nitride (GaN) based process node, a laterally-diffused metal-oxide semiconductor (LDMOS) based process node, etc.) and with a variety of architectures (e.g., a Doherty architecture, a class AB architecture, etc.). Also, PA circuitry can be operated at a variety of power levels depending on use case (e.g., <5 Watts (W) in small cell applications, 5-10 W in massive multiple-input multiple-output (MIMO) applications, >10 W in macro base station applications, etc.) and across a variety of signal bandwidths (e.g., anywhere between 20 Megahertz (MHz) to 300 MHz). Each type of PA circuitry and use case includes different non-linearity. As such, there are many non-linear functions to model the non-linearity of PA circuitry. To accommodate for different PA types and use-cases, the non-linear functions of the GMP model can be implemented by programmable lookup tables (LUTs).

As described above, PA circuitry can be utilized in cellular base station applications. For example, in small cell and massive MIMO applications, a transceiver SoC (e.g., an integrated transceiver SoC) supports a large signal bandwidth (e.g., 200 MHZ) and may have an instantaneous bandwidth (IBW) in the range of 100s of MHz (e.g., 400 MHz). To support DPD functionality over such a signal bandwidth, digital circuitry implementing DPD correction (e.g., a GMP model) would need to sample an input signal at a rate of up to about 1,000 mega samples per second (MSPS) for each instance of transmitter circuitry of the transceiver SoC.

However, the clock rate of digital circuitry of the transceiver SoC may be lower than the oversampling rate required for DPD correction. As such, the transceiver SoC implements a parallelized digital circuitry implementation of a DPD model to compensate for non-linearity in PA circuitry for each instances of transmitter circuitry of the transceiver SoC. For example, in a parallelized-by-two digital circuitry implementation of a DPD model (e.g., DPD corrector circuitry), the DPD corrector circuitry processes two samples of an input signal (e.g., x(n) and x(n+1)) each clock cycle. When parallelizing by two (e.g., DPD corrector circuitry with a parallelization factor of two) and operating with a clock rate of 500 MHz, DPD corrector circuitry can support an oversampling rate of up to about 1,000 MSPS for each instances of transmitter circuitry of a transceiver SoC.

As described above, the non-linearity of PA circuitry can change as the temperature of or input signal profile to the PA circuitry changes. As such, DPD corrector circuitry includes a spare set of LUTs for each instances of transmitter circuitry of a transceiver SoC. Also, the transceiver SoC includes DPD estimator circuitry to estimate an updated model of PA circuitry non-linearity and periodically update the spare set of LUTs with values corresponding to the updated model. However, including a spare LUT for each of the N LUTs utilized in DPD corrector circuitry effectively doubles the on-chip area consumed by the LUTs.

In parallelized-by-two DPD corrector circuitry, a LUT can be implemented by a dual port memory. As a dual port memory supports two read operations per clock cycle, the DPD corrector circuitry indexes a LUT with two samples of an input signal (e.g., x(n) and x(n+1)) in the same clock cycle to determine the non-linear function of a DPD model for the two samples in a single clock cycle. When implementing a LUT with a dual port memory, DPD corrector circuitry consumes a large amount of area on a chip and consumes a large amount of power.

As the area and power consumption of a dual port memory can be more than two times that of a single port memory, parallelized-by-two DPD corrector circuitry can utilize two instances of a single port memory to parallelize by two. For example, the two single port memories store the same data and each of the two single port memories can support one read operation per clock cycle. As such, the DPD corrector circuitry indexes a first single port memory with a first sample of an envelope of input signal (e.g., |x(n)|) and indexes a second single port memory with a second sample of the envelope of the input signal (e.g., |x(n+1)|) in the same clock cycle to determine the non-linear function of a DPD model for the two samples in a single clock cycle. Parallelizing by two via two single port memories reduces the area and power consumption of DPD corrector circuitry with respect to parallelizing-by-two via dual port memories. However, parallelizing by two by using two single port memories still consumes significant area on a chip and still consumes significant power.

In addition to the large amount of area and power consumed by LUTs of DPD corrector circuitry, some DPD models do not operate well for higher signal bandwidths. For example, the GMP model does not operate well for signal bandwidths greater than 100 MHz. As such, in some examples the GMP model is augmented with a dynamic deviation reduction (DDR) model. A DDR model leverages the fact that as an order of a term (e.g., x, x², x³, etc.) increases in the non-linear characterization of PA circuitry, the term has a smaller impact on the overall distortion caused by the PA circuitry. However, the addition of a DDR model provides marginal improvements over the GMP model.

Examples described herein include an example DPD model that improves pre-distortion modeling accuracy at higher bandwidths. For example, example DPD models described herein include a larger number of terms to support higher signal bandwidths. Advantageously, examples described herein reduce area and power consumption utilized to implement DPD models. For example, described methods, apparatus, and articles of manufacture reduce the number of LUTs and associated hardware circuitry to support the LUTs when implementing a DPD model. Examples described herein also reduce the number of LUTs utilized to support updating for variation in PA circuitry non-linearity. Furthermore, examples described herein include example LUT architecture to support parallelized implementations in an area and power efficient manner.

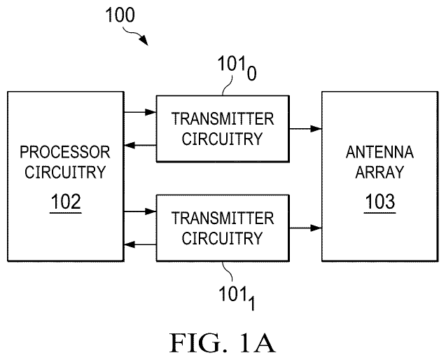

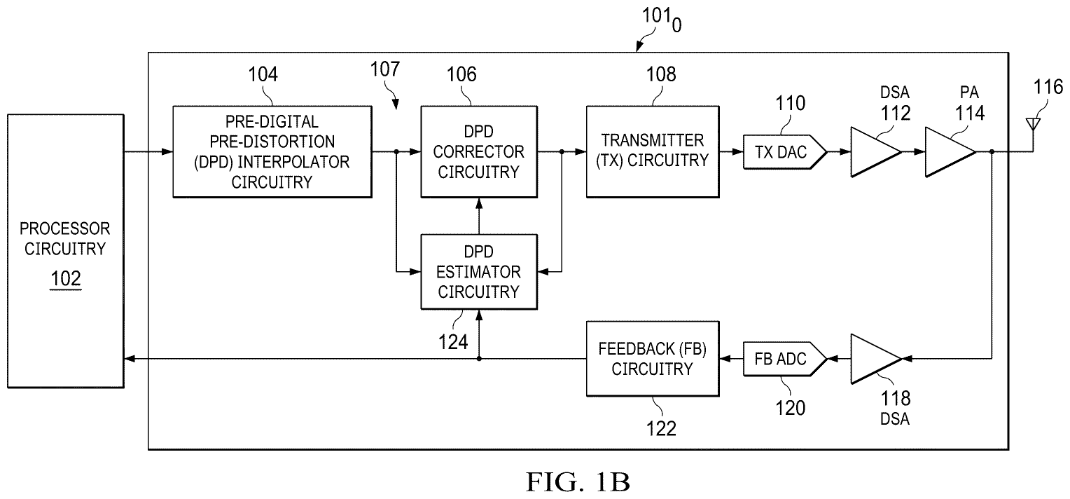

FIG. 1A is an example block diagram of a communication system 100. In the example of FIG. 1A, the communication system 100 includes at least two instances of transmitter circuitry. For example, the communication system 100 includes first example transmitter circuitry 1010 and second example transmitter circuitry 1011. In the example of FIG. 1A, the communication system 100 also includes example processor circuitry 102 and an example antenna array 103.

In the illustrated example of FIG. 1A, each of the transmitter circuitry 1010 and the transmitter circuitry 1011 has a first output terminal, a second input terminal, and an input terminal. Also, the processor circuitry 102 has a first output terminal, a second output terminal, a first input terminal, and a second input terminal. In the example of FIG. 1A, the antenna array 103 has a first input terminal and a second input terminal. As described above, an example frequency band may be divided into one or more channels where a channel refers to a frequency range within the frequency band. In the example of FIG. 1A, the transmitter circuitry 1010 is to perform transmission in a first channel of a frequency band and the transmitter circuitry 1011 is to perform transmission in a second channel of the frequency band (e.g., where the second channel is at least one of the same as or different than the first channel).

In the illustrated example of FIG. 1A, each of the transmitter circuitry 1010 and the transmitter circuitry 1011 is implemented by at least one digital circuitry or analog circuitry. In the example of FIG. 1A, the first output terminal of the transmitter circuitry 1010 is coupled to the first input terminal of the processor circuitry 102 and the second output terminal of the transmitter circuitry 1010 is coupled to the first input terminal of the antenna circuitry 103. Also, the input terminal of the transmitter circuitry 1010 is coupled to the first output terminal of the processor circuitry 102. In the example of FIG. 1A, the first output terminal of the transmitter circuitry 1011 is coupled to the second input terminal of the processor circuitry 102 and the second output terminal of the transmitter circuitry 1011 is coupled to the second input terminal of the antenna circuitry 103. Also, the input terminal of the transmitter circuitry 1011 is coupled to the second output terminal of the processor circuitry 102.

In the illustrated example of FIG. 1A, the processor circuitry 102 is implemented by a processor. For example, the processor circuitry 102 is implemented by a central processor unit (CPU). Also or alternatively, the processor circuitry 102 is implemented by a graphics processor unit (GPU), a digital signal processor (DSP), or custom hardware (e.g., implemented by at least one of an Application Specific Integrated Circuit (ASIC) or a Field Programmable Gate Array (FPGA)), among others. In the example of FIG. 1A, the first output terminal of the processor circuitry 102 is coupled to the input terminal of the transmitter circuitry 101₀ and the second output terminal of the processor circuitry 102 is coupled to the input terminal of the transmitter circuitry 101₁. Also, the first input terminal of the processor circuitry 102 is coupled to the first output terminal of the transmitter circuitry 101₀ and the second input terminal of the processor circuitry 102 is coupled to the first output terminal of the transmitter circuitry 101₁.

In the illustrated example of FIG. 1A, the antenna array 103 includes at least two discrete antennas. For example, the antenna array 103 includes at least two sector antennas. In some examples, the antenna array 103 includes at least two integrated antennas. For example, an integrated antenna includes at least one of a patch antenna, a microstrip antenna, an antenna-on-package (AoP) antenna, among others. In the example of FIG. 1A, the first input terminal of the antenna array 103 is coupled to the output terminal of the transmitter circuitry 101₀ and the second input terminal of the antenna array 103 is coupled to the output terminal of the transmitter circuitry 101₁.

In the illustrated example of FIG. 1A, the processor circuitry 102 generates one or more digital signals to be transmitted via the antenna array 103. In the example of FIG. 1A, the transmitter circuitry 101₀ converts a first digital signal (e.g., a base-band signal in a first channel) to a radio frequency (RF) band signal to be transmitted via an antenna of the antenna array 103. Advantageously, the transmitter circuitry 101₀ applies DPD correction to the first digital signal to counteract non-linearity of PA circuitry of the transmitter circuitry 101₀. In the example of FIG. 1A, the transmitter circuitry 101₁ operates similarly to the transmitter circuitry 101₀.

FIG. 1B is a block diagram of an example implementation of the transmitter circuitry 101₀ of FIG. 1A. In the example of FIG. 1B, the transmitter circuitry 101₀ includes example pre-digital pre-distortion (DPD) interpolator circuitry 104, example digital pre-distortion (DPD) corrector circuitry 106, example transmitter circuitry 108, an example transmitter digital-to-analog converter (DAC) circuit 110, first example digital step attenuator (DSA) circuitry 112, and example power amplifier (PA) circuitry 114. In the example of FIG. 1B, the transmitter circuitry 101₀ is associated with an example antenna 116. For example, the antenna 116 is a first antenna of the antenna array 103. The transmitter circuitry 101₀ also includes second example DSA circuitry 118, an example feedback analog-to-digital converter (ADC) circuit 120, example feedback circuitry 122, and example digital pre-distortion (DPD) estimator circuitry 124.

In the illustrated example of FIG. 1B, each of the pre-DPD interpolator circuitry 104, the transmitter circuitry 108, the transmitter DAC circuit 110, the DSA circuitry 112, the PA circuitry 114, the DSA circuitry 118, the feedback ADC circuit 120, and the feedback circuitry 122 has an output terminal and an input terminal. Also, in the example of FIG. 1B, the DPD corrector circuitry 106 has a first input terminal, a second input terminal, and an output terminal. The example DPD estimator circuitry 124 also has a first input terminal, a second input terminal, a third input terminal, and an output terminal.

As described above, the processor circuitry 102 is implemented by a processor. For example, the processor circuitry 102 is implemented by a CPU. Also or alternatively, the processor circuitry 102 is implemented by a GPU, a DSP, or custom hardware (e.g., implemented by at least one of an ASIC or an FPGA), among others. In the example of FIG. 1B, an output terminal of the processor circuitry 102 (e.g., the first output terminal) is coupled to the input terminal of the pre-DPD interpolator circuitry 104 and an input terminal (e.g., the first input terminal) of the processor circuitry 102 is coupled to the output terminal of the feedback circuitry 122.

In the illustrated example of FIG. 1B, the pre-DPD interpolator circuitry 104 is implemented by digital circuitry. In the example of FIG. 1B, the output terminal of the pre-DPD interpolator circuitry 104 is coupled to the first input terminal of the DPD corrector circuitry 106 and the first input terminal of the DPD estimator circuitry 124. In some examples, the output terminal of the pre-DPD interpolator circuitry 104 is referred to as an example DPD terminal 107. Also, the input terminal of the pre-DPD interpolator circuitry 104 is coupled to the output terminal of the processor circuitry 102. In the example of FIG. 1B, the DPD corrector circuitry 106 of FIG. 1B is implemented by digital circuitry. Also, the output terminal of the DPD corrector circuitry 106 is coupled to the input terminal of the transmitter circuitry 108 and the third input terminal of the DPD estimator circuitry 124. In the example of FIG. 1B, the first input terminal of the DPD corrector circuitry 106 is coupled to the output terminal of the pre-DPD interpolator circuitry 104 (e.g., the DPD terminal 107) and the second input terminal of the DPD corrector circuitry 106 is coupled to the output terminal of the DPD estimator circuitry 124.

In the illustrated example of FIG. 1B, the transmitter circuitry 108 is implemented by at least one of analog circuitry or digital circuitry. Also, in the example of FIG. 1B, the output terminal of the transmitter circuitry 108 is coupled to the input terminal of the transmitter DAC circuit 110 and the input terminal of the transmitter circuitry 108 is coupled to the output terminal of the DPD corrector circuitry 106. In the example of FIG. 1B, the transmitter DAC circuit 110 is implemented by at least one of digital circuitry or analog circuitry. Also, in the example of FIG. 1B, the output terminal of the transmitter DAC circuit 110 is coupled to the input terminal of the DSA circuitry 112 and the input terminal of the transmitter DAC circuit 110 is coupled to the output terminal of the transmitter circuitry 108.

In the illustrated example of FIG. 1B, the DSA circuitry 112 is implemented by at least one of digital circuitry or analog circuitry. Also, in the example of FIG. 1B, the output terminal of the DSA circuitry 112 is coupled to the input terminal of the PA circuitry 114 and the input terminal of the DSA circuitry 112 is coupled to the output terminal of the transmitter DAC circuit 110. In the example of FIG. 1B, the PA circuitry 114 is implemented by at least one of digital circuitry or analog circuitry. Also, in the example of FIG. 1B, the output terminal of the PA circuitry 114 is coupled to the antenna 116 and the input terminal of the DSA circuitry 118. In the example of FIG. 1B, the input terminal of the PA circuitry 114 is coupled to the output terminal of the DSA circuitry 112.

In the illustrated example of FIG. 1B, the antenna 116 is implemented by a discrete antenna. For example, the antenna 116 is implemented by a sector antenna. In some examples, the antenna 116 is an integrated antenna. For example, the antenna 116 can be implemented by at least one of a patch antenna, a microstrip antenna, an antenna-on-package (AoP) antenna, among others. In the example of FIG. 1B, the DSA circuitry 118 is implemented by at least one of digital circuitry or analog circuitry. Also, in the example of FIG. 1B, the output terminal of the DSA circuitry 118 is coupled to the input terminal of the feedback ADC circuit 120 and the input terminal of the DSA circuitry 118 is coupled to the output terminal of the PA circuitry 114.

In the illustrated example of FIG. 1B, the feedback ADC circuit 120 is implemented by at least one of digital circuitry or analog circuitry. In the example of FIG. 1B, the output terminal of the feedback ADC circuit 120 is coupled to the input terminal of the feedback circuitry 122 and the input terminal of the feedback ADC circuit 120 is coupled to the output terminal of the DSA circuitry 118. Also, in the example of FIG. 1B, the feedback circuitry 122 is implemented by at least one of analog circuitry or digital circuitry. In the example of FIG. 1B, the output terminal of the feedback circuitry 122 is coupled to the input terminal of the processor circuitry 102 and the second input terminal of the DPD estimator circuitry 124. Also, in the example of FIG. 1B, the input terminal of the feedback circuitry 122 is coupled to the output terminal of the feedback ADC circuit 120.

In the illustrated example of FIG. 1B, the DPD estimator circuitry 124 is implemented by digital circuitry. In the example of FIG. 1B, the output terminal of the DPD estimator circuitry 124 is coupled to the second input terminal of the DPD corrector circuitry 106. Also, in the example of FIG. 1B, the first input terminal of the DPD estimator circuitry 124 is coupled to the output terminal of the pre-DPD interpolator circuitry 104 (e.g., the DPD terminal 107), the second input terminal of the DPD estimator circuitry 124 is coupled to the output terminal of the feedback circuitry 122, and the third input terminal of the DPD estimator circuitry 124 is coupled to the output terminal of the DPD corrector circuitry 106.

In example operation, the processor circuitry 102 generates a digital signal (e.g., x(n)) to be transmitted via the antenna 116. Also, the pre-DPD interpolator circuitry 104 oversamples the digital signal (e.g., x(n)) generated by the processor circuitry 102 to avoid the effects of aliasing that may result from bandwidth expansion during pre-distortion of the digital signal (e.g., x(n)). For example, if the input signal from the processor circuitry 102 is sampled at about 250 MSPS (e.g., the input signal has a bandwidth of 200 MHZ), then the pre-DPD interpolator circuitry 104 oversamples the input signal to about 750 MSPS (e.g., with an interpolation factor of 3).

In the illustrated example of FIG. 1B, the DPD corrector circuitry 106 generates a pre-distorted digital signal (e.g., y(n) as described in Equation 1 above, as described in Equation 2 below, etc.). In the example of FIG. 1B, the DPD corrector circuitry 106 is parallelized-by-two. For example, the DPD corrector circuitry 106 includes (1) a first instance of DPD corrector circuitry that performs DPD correction on a first sample of an input signal (e.g., x(n)) and (2) a second instance of DPD corrector circuitry that performs DPD correction on a second sample of the input signal (e.g., x(n+1)). Example parallelization of the DPD corrector circuitry 106 facilitates higher sampling rates for DPD correction while also permitting the communication system 100 to operate at a lower clock rate. Also or alternatively, the DPD corrector circuitry 106 can be parallelized by any amount (e.g., parallelized-by-two, parallelized-by-three, parallelized-by-four, etc.).

In the illustrated example of FIG. 1B, the processor circuitry 102 programs the DPD corrector circuitry 106 at startup of the communication system 100 to compensate for non-linearity of the PA circuitry 114. For example, the processor circuitry 102 programs the DPD corrector circuitry 106 based on the DPD model implemented by the DPD corrector circuitry 106 at startup of the communication system 100. Also, the processor circuitry 102 programs delay circuitry of the DPD corrector circuitry 106 at startup of the communication system 100 based on a DPD model implemented by the DPD corrector circuitry 106.

In the illustrated example of FIG. 1B, the transmitter circuitry 108 interpolates the pre-distorted signal (e.g., y(n)) generated by the DPD corrector circuitry 106 to introduce additional data points. For example, the additional data points increase the sample rate of the pre-distorted signal (e.g., y(n)) signal 204. The example transmitter circuitry 108 at least one of up samples (e.g., adds data points to, etc.) or up converts (e.g., converts a base-band signal to at least one of an intermediate frequency (IF) band signal or RF band signal, etc.) the pre-distorted signal (e.g., y(n)). In the example of FIG. 1B, the transmitter DAC circuit 110 converts the signal generated by the transmitter circuitry 108 from a digital signal to an analog signal. As a result, information transmitted via the antenna 116 is encoded continuously across a range of voltages rather than a discrete set of voltages.

In the illustrated example of FIG. 1B, the DSA circuitry 112 attenuates the signal generated by the transmitter DAC circuit 110 so that the PA circuitry 114 consumes a consistent amount of power. In particular, the DSA circuitry 112 attenuates the signal generated by the transmitter DAC circuit 110 based on the gain of the PA circuitry 114, which may change based on temperature. The DSA circuitry 112 also provides the attenuated signal to the PA circuitry 114, which amplifies the signal for transmission via the antenna 116.

In the illustrated example of FIG. 1B, the DSA circuitry 118 receives an analog signal from the PA circuitry 114 and attenuates the signal. In some examples, the DSA circuitry 118 attenuates the analog signal based on at least one operating parameter of the feedback ADC circuit 120. In the example of FIG. 1B, the feedback ADC circuit 120 converts the attenuated signal generated by the DSA circuitry 118 from an analog signal to a digital signal. Also, the feedback circuitry 122 decimates (e.g., down converts, down samples, removes data points from, etc.) the digital signal. As a result, the digital signal generated by the feedback circuitry 122 can be fed back to and interpreted by the DPD estimator circuitry 124 and the processor circuitry 102.

When operating in a high efficiency range, the PA circuitry 114 amplifies analog signals received from the DSA circuitry 112 but also distorts the analog signals as described above. Advantageously, the DPD corrector circuitry 106 pre-distorts input signals from the processor circuitry 102 to counteract distortion introduced by the PA circuitry 114. As such, analog signals transmitted via the antenna 116 are scaled versions of the signal generated by the processor circuitry 102. As described above, as the temperature of or input signal profile to the PA circuitry 114 changes, the non-linearity of the PA circuitry 114 can change. As such, the DPD estimator circuitry 124 monitors signals output from the PA circuitry 114 and adjusts at least one value of a non-linear function stored in the DPD corrector circuitry 106 to track changes in the non-linearity of the PA circuitry 114. For example, the DPD estimator circuitry 124 evaluates a signal generated by the PA circuitry 114 as compared to the oversampled signal input to and pre-distorted signal output from the DPD corrector circuitry 106. Based on the comparison, the DPD estimator circuitry 124 estimates at least one updated value of a non-linear function stored in the DPD corrector circuitry 106.

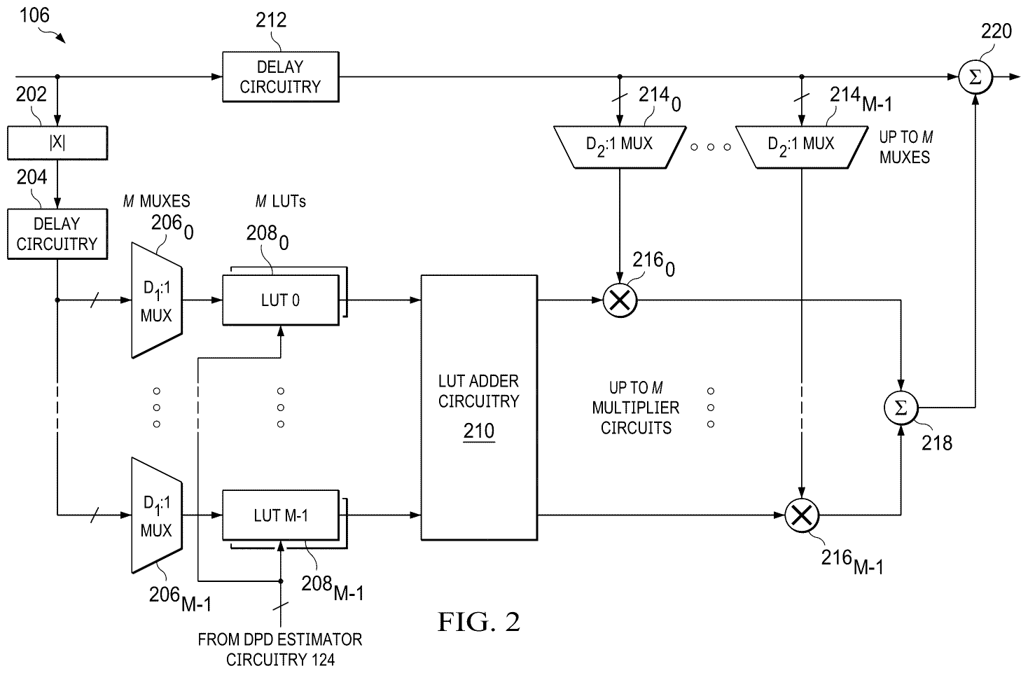

FIG. 2 is a block diagram of a first example implementation of the DPD corrector circuitry 106 of FIG. 1B. In the example of FIG. 2, the DPD corrector circuitry 106 includes example envelope generator circuitry 202, first example delay circuitry 204, first example multiplexer circuits 206₀-206_{M-1}, example lookup tables (LUTs) 208₀-208_{M-1}, and example lookup table (LUT) adder circuitry 210. In the example of FIG. 2, the DPD corrector circuitry 106 includes second example delay circuitry 212, second example multiplexer circuits 2140-214M-1, example multiplier circuits 2160-216M-1, first example adder circuitry 218, and second example adder circuitry 220.

In the illustrated example of FIG. 2, the envelope generator circuitry 202 has an output terminal and an input terminal and the delay circuitry 204 has D₁ output terminals and an input terminal. In the example of FIG. 2, each of the multiplexer circuits 206₀-206_{M-1} has an output terminal and D₁ input terminals and each of the LUTs 208₀-208_{M-1} has an output terminal, a first input terminal, and a second input terminal. Also, in the example of FIG. 2, the LUT adder circuitry 210 has up to M output terminals and M input terminals. For example, the LUT adder circuitry 210 can include first through eighth output terminals and input terminals, first through ninth output terminals and input terminals, first through tenth output terminals and input terminals, or any number of output terminals and input terminals. In the example of FIG. 2, the delay circuitry 212 has D₂ output terminals and an input terminal and each of the multiplexer circuits 214₀-214_{M-1} has an output terminal and D₂ input terminals. Also, in the example of FIG. 2, each of the multiplier circuits 216₀-216_{M-1} has an output terminal, a first input terminal, and a second input terminal. In the example of FIG. 2, the adder circuitry 218 has an output terminal and up to M input terminals and the adder circuitry 220 has an output terminal, a first input terminal, and a second input terminal.

In the illustrated example of FIG. 2, the envelope generator circuitry 202 is implemented by digital circuitry. In the example of FIG. 2, the output terminal of the envelope generator circuitry 202 is coupled to the input terminal of the delay circuitry 204 and the input terminal of the envelope generator circuitry 202 is coupled to the DPD terminal 107 (e.g., is coupled to processor circuitry via the DPD terminal 107 of the pre-DPD interpolator circuitry 104). Also, in the example of FIG. 2, the delay circuitry 204 is implemented by one or more D flip-flop circuits. In some examples, the delay circuitry 204 is implemented by one or more first in, first out (FIFO) queues. In the example of FIG. 2, the D₁ output terminals of the delay circuitry 204 are coupled to the D₁ input terminals of each of the multiplexer circuits 206₀-206_{M-1} and the input terminal of the delay circuitry 204 is coupled to the output terminal of the envelope generator circuitry 202.

In the illustrated example of FIG. 2, each of the multiplexer circuits 206₀-206_{M-1} is implemented by digital circuitry. In the example of FIG. 2, the D₁ input terminals of each of the multiplexer circuits 206₀-206_{M-1} are coupled to the D₁ output terminals of the delay circuitry 204. Also, the output terminals of the multiplexer circuits 206₀-206_{M-1} are coupled to the first input terminals of the LUTs 208₀-208_{M-1}, respectively. For example, the output terminal of the multiplexer circuit 206₀ is coupled to the first input terminal of the LUT 208₀.

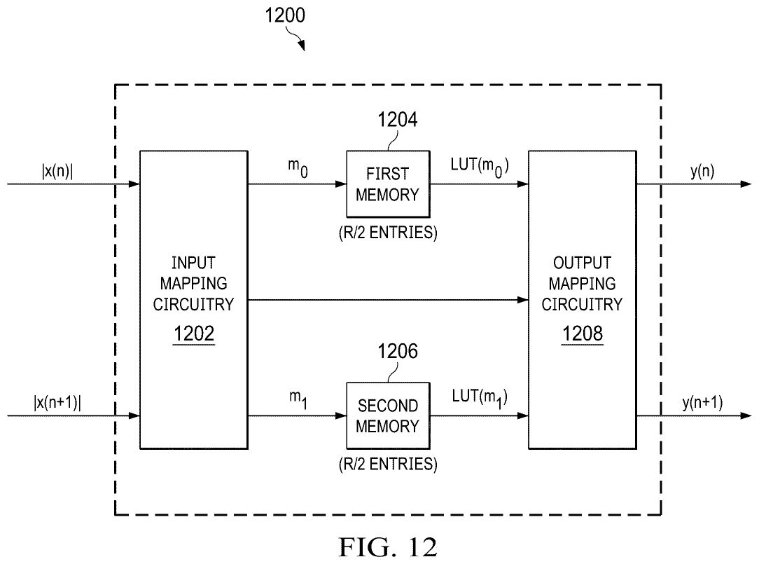

In the illustrated example of FIG. 2, each of the LUTs 208₀-208_{M-1} is implemented by digital circuitry and at least one memory. For example, each of the LUTs 208₀-208_{M-1} is implemented by digital circuitry and one memory. In some examples, each of the LUTs 208₀-208_{M-1} is implemented by digital circuitry and two memories as described further below in connection with FIGS. 12, 13, 14, 15, and 16. In the example of FIG. 2, each of the LUTs 208₀-208_{M-1} stores 512 entries of 32 bits of data (e.g., each of the LUTs 208₀-208_{M-1} has 512 rows and each row is 32 bits wide). In the example of FIG. 2, the output terminals of the LUTs 208₀-208_{M-1} are coupled to the M input terminals of the LUT adder circuitry 210, respectively. Also, the first input terminals of the LUTs 208₀-208_{M-1} are coupled to the output terminals of the multiplexer circuits 206₀-206_{M-1}, respectively. In the example of FIG. 2, the second input terminal of each of the LUTs 208₀-208_{M-1} is coupled to the output terminal of the DPD estimator circuitry 124.

In the illustrated example of FIG. 2, the LUT adder circuitry 210 is implemented by digital circuitry and M instances of adder circuitry. In the example of FIG. 2, the up to M output terminals of the LUT adder circuitry 210 are coupled to the first input terminals of the multiplier circuits 216₀-216_{M-1}, respectively. Also, the M input terminals of the LUT adder circuitry 210 are coupled to the output terminals of the LUTs 208₀-208_{M-1}, respectively. In the example of FIG. 2, the delay circuitry 212 is implemented by one or more D flip-flop circuits. In some examples, the delay circuitry 212 is implemented by one or more FIFO queues. In the example of FIG. 2, the D₂ output terminals of the delay circuitry 212 are coupled to the D₂ input terminals of each of the multiplexer circuits 214₀-214_{M-1} and the input terminal of the delay circuitry 212 is coupled to the DPD terminal 107 (e.g., is coupled to processor circuitry via the DPD terminal 107 of the pre-DPD interpolator circuitry 104). Also, one of the D₂ output terminals of the delay circuitry 212 is coupled to the first input terminal of the adder circuitry 220.

In the illustrated example of FIG. 2, each of the multiplexer circuits 214₀-214_{M-1} is implemented by digital circuitry. In the example of FIG. 2, the output terminals of the multiplexer circuits 214₀-214_{M-1} are coupled to the second input terminals of the multiplier circuits 216₀-216_{M-1}, respectively. Also, the D₂ input terminals of each of the multiplexer circuits 214₀-214_{M-1} are coupled to the D₂ output terminals of the delay circuitry 212. In the example of FIG. 2, each of the multiplier circuits 216₀-216_{M-1} is implemented by digital circuitry. In the example of FIG. 2, the output terminals of the multiplier circuits 216₀-216_{M-1} are coupled to the up to M input terminals of the adder circuitry 218, respectively. Also, the first input terminals of the multiplier circuits 216₀-216_{M-1} are coupled to the up to M output terminals of the LUT adder circuitry 210, respectively. In the example of FIG. 2, the second input terminals of the multiplier circuits 216₀-216_{M-1} are coupled to the output terminals of the multiplexer circuits 214₀-214_{M-1}, respectively.

In the illustrated example of FIG. 2, each of the adder circuitry 218 and the adder circuitry 220 is implemented by one or more adder circuits (e.g., one or more half adder circuits, one or more full adder circuits, one or more ripple-carry adder circuits, one or more carry-lookahead adder circuits, etc.). In the example of FIG. 2, the output terminal of the adder circuitry 218 is coupled to the second input terminal of the adder circuitry 220. Also, in the example of FIG. 2, the up to M input terminals of the adder circuitry 218 are coupled to the output terminals of the multiplier circuits 216₀-216_{M-1}. In the example of FIG. 2, the output terminal of the adder circuitry 220 is coupled to power amplifier circuitry (e.g., the PA circuitry 114 of FIG. 1B via the transmitter circuitry 108, the transmitter DAC circuit 110, and the DSA circuitry 112) and the third input terminal of the DPD estimator circuitry 124. Also, in the example of FIG. 2, the first input terminal of the adder circuitry 220 is coupled to one of the D₂ output terminals of the delay circuitry 212 and the second input terminal of the adder circuitry 220 is coupled to the output terminal of the adder circuitry 218.

In the illustrated example of FIG. 2, the DPD corrector circuitry 106 implements Equation 1 described above. In the example of FIG. 2, the envelope generator circuitry 202 determines an envelope (e.g., |x(n)|) of an input signal (e.g., x(n)). For example, the envelope generator circuitry 202 determines an envelope of an input signal as described above (e.g., |x(n)|={square root over (Re(x(n))+Im(x(n))²))}. In the example of FIG. 2, the delay circuitry 204 generates D₁ delayed versions of the envelope of the input signal. For example, the delay circuitry 204 generates the D₁ delayed versions of the envelope of the input signal over the range

$$[ ( \frac{{D}_{1}}{2} - 1 , - \frac{{D}_{1}}{2} ] .$$

In the illustrated example of FIG. 2, each of the multiplexer circuits 206₀-206_{M-1} selects one of the D₁ delayed versions of the envelope of the input signal based on a programmed value in a respective register associated with each of the multiplexer circuits 206₀-206_{M-1}. For example, the multiplexer circuit 206₀ selects one of the D₁ delayed versions of the envelope of the input signal based on a programmed value in a register associated with the multiplexer circuit 206₀. In the example of FIG. 2, the registers associated with the multiplexer circuits 206₀-206_{M-1} are programmed at startup of the DPD corrector circuitry 106. For example, the registers associated with the multiplexer circuits 206₀-206_{M-1} are programmed at startup of the communication system 100 of FIG. 1B.

In the illustrated example of FIG. 2, the selected delayed versions of the envelope of the input signal that are output from the multiplexer circuits 206₀-206_{M-1} index the LUTs 208₀-208_{M-1}, respectively. The LUTs 208₀-208_{M-1} output values to the LUT adder circuitry 210 based on the respective indices. In the example of FIG. 2, depending on the complexity of the DPD model implemented by the DPD corrector circuitry 106, the LUT adder circuitry 210 can add one or more values output from the LUTs 208₀-208_{M-1}.

For example, if the values output from two of the LUTs 208₀-208_{M-1} are to be multiplied by the same delayed version of the input signal (e.g., x(n−1)LUT(|x(n−1)|) and x(n−1)LUT(|x(n−2)|)), then the LUT adder circuitry 210 can be configured at startup of the DPD corrector circuitry 106 to add the two values (e.g., LUT(|x(n−1)|)+LUT(|x(n−2)|)) and provide the sum of the two values to one of the multiplier circuits 216₀-216_{M-1} to be multiplied by one of the delayed versions of the input signal (e.g., x(n−1)). In this manner, at startup of the DPD corrector circuitry 106, some of the multiplier circuits 216₀-216_{M-1} and some of the multiplexer circuits 214₀-214_{M-1} can remain disabled thereby reducing power consumption of the DPD corrector circuitry 106. If none of the values output from the LUTs 208₀-208_{M-1} are to be multiplied by the same delayed version of the input signal, then the LUT adder circuitry 210 acts as passthrough circuitry and provides the values output from the LUTs 208₀-208_{M-1} to the multiplier circuits 216₀-216_{M-1}.

In the illustrated example of FIG. 2, the delay circuitry 212 generates D₂ delayed versions of the input signal. For example, the delay circuitry 212 generates the D₂ delayed versions of the input signal over the range

$$[ \frac{{D}_{2}}{2} - 1 , - \frac{{D}_{2}}{2} ] .$$

Also, me delay circuitry 212 provides the input signal (e.g., x(n±0)) to the first input terminal of the adder circuitry 220. In the example of FIG. 2, each of the multiplexer circuits 214₀-214_{M-1} selects one of the D₂ delayed versions of the input signal based on a programmed value in a respective register associated with each of the multiplexer circuits 214₀-214_{M-1}. For example, the multiplexer 214₀ selects one of the D₂ delayed versions of the input signal based on a programmed value in a register associated with the multiplexer 214₀. In the example of FIG. 2, the registers associated with the multiplexer circuits 214₀-214_{M-1} are programmed at startup of the DPD corrector circuitry 106. For example, the registers associated with the multiplexer circuits 214₀-214_{M-1} are programmed at startup of the communication system 100 of FIG. 1B.

In the illustrated example of FIG. 2, each of the multiplexer circuits 214₀-214_{M-1} provides one of the D₂ delayed versions of the input signal to the second input terminal of each of the multiplier circuits 216₀-216_{M-1}, respectively. In the example of FIG. 2, each of the multiplier circuits 216₀-216_{M-1} multiplies the values at the up to M output terminals of the LUT adder circuitry 210 by the values at the output terminals of the multiplexer circuits 214₀-214_{M-1}, respectively. The multiplier circuits 216₀-216_{M-1} provide the products to the input terminals of the adder circuitry 218, which adds the values and provides the sum to the second input terminal of the adder circuitry 220. The adder circuitry 220 adds the input signal (e.g., x(n±0)) with the value at the output terminal of the adder circuitry 218 and provides the sum at the output terminal of the DPD corrector circuitry 106.

As described above, the DPD corrector circuitry 106 of FIG. 1B is parallelized-by-two. For example, the DPD corrector circuitry 106 can be parallelized-by-two to facilitate operation at a higher sampling rate while also operating at a lower clock rate. Accordingly, another instance of the circuitry of FIG. 2 may be implemented in parallel with the circuitry of FIG. 2 to facilitate such parallelization. That is, the circuitry of FIG. 2 may be duplicated and some of the circuitry of FIG. 2 may be adjusted to implement a parallel instance of the circuitry of FIG. 2. For example, in a parallelized-by-two implementation of the circuitry of FIG. 2, each instance of the delay circuitry 204 generates D₁/2 delayed versions of the envelope of the input signal and the multiplexer circuits 206₀-206_{M-1} in each instance of the circuitry of FIG. 2 receive values from both instances of the delay circuitry 204. Similarly, in a parallelized-by-two implementation of the circuitry of FIG. 2, each instance of the delay circuitry 212 generates D₂/2 delayed versions of the envelope of the input signal and the multiplexer circuits 214₀-214_{M-1} in each instance of the circuitry of FIG. 2 receive values from both instances of the delay circuitry 212. As such, in a first clock cycle of the DPD corrector circuitry 106, a first instance of the circuitry of FIG. 2 processes a first sample of an input signal (e.g., x(n)) in parallel with a second instance of the circuitry of FIG. 2 that processes a second sample of the input signal (e.g., x(n+1)). Additional instances of the circuitry of FIG. 2 may be implemented to support additional parallelization (e.g., three instances of the circuitry of FIG. 2 to support a parallelized-by-three implementation, four instances of the circuitry of FIG. 2 to support a parallelized-by-four implementation, etc.).

In a parallelized-by-two implementation of the DPD corrector circuitry 106, another instance of the LUTs 208₀-208_{M-1} can be implemented in a parallel instance of the circuitry of FIG. 2. Also, the LUTs 208₀-208_{M-1} can be shared between each instance of the circuitry of FIG. 2. For example, the LUTs 208₀-208_{M-1} can be implemented once and accessed by a first instance of the circuitry of FIG. 2 and a second instance of the circuitry of FIG. 2 in the same clock cycle as described further below in connection with FIGS. 12, 13, 14, 15, and 16.

Also, as described above, the non-linearity of PA circuitry can fluctuate based on temperature of the PA circuitry or input signal profile to the PA circuitry. As such, the DPD corrector circuitry 106 includes a spare LUT for each of the LUTs 208₀-208_{M-1} (e.g., main LUTs). For example, the spare LUTs can be updated by the DPD estimator circuitry 124 while the DPD corrector circuitry 106 utilizes the LUTs 208₀-208_{M-1} (e.g., the main LUTs) to perform DPD correction. Then, the DPD corrector circuitry 106 can switch from the LUTs 208₀-208_{M-1} (e.g., the main LUTs) to the spare LUTs so that the LUTs 208₀-208_{M-1} (e.g., the main LUTs) can be updated with updated values to model PA circuitry non-linearity. After the LUTs 208₀-208_{M-1} (e.g., the main LUTs) have been updated, the DPD corrector circuitry 106 can switch from the spare LUTs to the LUTs 208₀-208_{M-1} (e.g., the main LUTs).

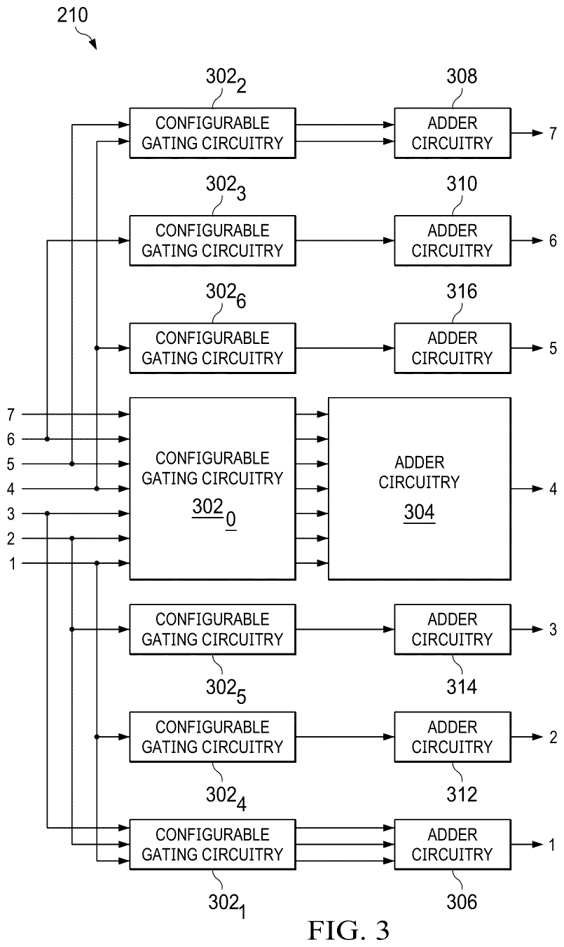

FIG. 3 is a block diagram of an example implementation of the LUT adder circuitry 210 of FIG. 2. As described above, the LUT adder circuitry 210 has M input terminals and M output terminals and includes M instances of adder circuitry. Also, as described above, the LUT adder circuitry 210 can compute any possible summation of values output from the LUTs 208₀-208_{M-1} depending on the complexity of the DPD model implemented by the DPD corrector circuitry 106. For example, the LUT adder circuitry 210 can add one or more mutually exhaustive subsets of the M inputs to the LUT adder circuitry 210. In examples described herein, example operation of the LUT adder circuitry 210 is not dependent on the order of inputs from the LUTs 208₀-208_{M-1} as the data in the LUTs 208₀-208_{M-1} can be adjusted (e.g., swapped, rearranged, etc.) based on the configuration of the LUT adder circuitry 210. In the example of FIG. 3, the LUT adder circuitry 210 can be programmed at startup of the DPD corrector circuitry 106 based on the DPD model implemented by the DPD corrector circuitry 106. As such, the LUT adder circuitry 210 can output between one and M values, depending on a configuration of the LUT adder circuitry 210. While the LUT adder circuitry 210 is described in the context of DPD correction, the LUT adder circuitry 210 is also applicable to any other scenario that includes the computation of all possible summations of M inputs to generate up to N outputs, where N is less than or equal to M.

To facilitate the capability of selecting which of the M input terminals contribute to the one to M values output from the LUT adder circuitry 210, the LUT adder circuitry 210 includes M instances of adder circuitry and M instances of example configurable gating circuitry 302 to select which of the one or more values input to the LUT adder circuitry 210 contribute to the one or more values output from the LUT adder circuitry 210. For example, the LUT adder circuitry 210 includes one instance of adder circuitry having M input terminals, one instance of adder circuitry having M/2 input terminals, one instance of adder circuitry having M/3 input terminals, one instance of adder circuitry having M/4 input terminals, one instance of adder circuitry having M/5 input terminals and so on until the total number of instances of adder circuitry is equal to M.

Implementing the LUT adder circuitry 210 as described above facilitates performing any possible combination of values output from the LUTs 208₀-208_{M-1}. In the example of FIG. 3, the LUT adder circuitry 210 has seven input terminals and seven output terminals. As such, the LUT adder circuitry 210 implements seven instances of adder circuitry and seven instances of the configurable gating circuitry 302. For example, the LUT adder circuitry 210 includes first example configurable gating circuitry 3020, second example configurable gating circuitry 3021, third example configurable gating circuitry 3022, fourth example configurable gating circuitry 3023, fifth example configurable gating circuitry 3024, sixth example configurable gating circuitry 3025, seventh example configurable gating circuitry 3026, first example adder circuitry 304, second example adder circuitry 306, third example adder circuitry 308, fourth example adder circuitry 310, fifth example adder circuitry 312, sixth example adder circuitry 314, and seventh example adder circuitry 316.

In the illustrated example of FIG. 3, the configurable gating circuitry 3020 has a first output terminal, a second output terminal, a third output terminal, a fourth output terminal, a fifth output terminal, a sixth output terminal, a seventh output terminal, a first input terminal, a second input terminal, a third input terminal, a fourth input terminal, a fifth input terminal, a sixth input terminal, and a seventh input terminal. Also, the configurable gating circuitry 3021 has a first output terminal, a second output terminal, a third output terminal, a first input terminal, a second input terminal, and a third input terminal. In the example of FIG. 3, the configurable gating circuitry 3022 has a first output terminal, a second output terminal, a first input terminal, and a second input terminal. Also, each of the configurable gating circuitry 3023, the configurable gating circuitry 3024, the configurable gating circuitry 3025, and the configurable gating circuitry 3026 has an output terminal and an input terminal.

In the illustrated example of FIG. 3, the adder circuitry 304 has an output terminal, a first input terminal, a second input terminal, a third input terminal, a fourth input terminal, a fifth input terminal, a sixth input terminal, and a seventh input terminal. Also, in the example of FIG. 3, the adder circuitry 306 has an output terminal, a first input terminal, a second input terminal, and a third input terminal. In the example of FIG. 3, the adder circuitry 308 has an output terminal, a first input terminal, and a second input terminal. Also, in the example of FIG. 3, each of the adder circuitry 310, the adder circuitry 312, the adder circuitry 314, and the adder circuitry 316 has an output terminal and an input terminal.

In the illustrated example of FIG. 3, each instances of the configurable gating circuitry 302 is implemented by digital circuitry. Also, in the example of FIG. 3, the first output terminal, the second output terminal, the third output terminal, the fourth output terminal, the fifth output terminal, the sixth output terminal, and the seventh output terminal of the configurable gating circuitry 3020 are coupled to the first input terminal, the second input terminal, the third input terminal, the fourth input terminal, the fifth input terminal, the sixth input terminal, and the seventh input terminal of the adder circuitry 304, respectively. Also, the first input terminal, the second input terminal, the third input terminal, the fourth input terminal, the fifth input terminal, the sixth input terminal, and the seventh input terminal of the configurable gating circuitry 3020 operate as the first input terminal, the second input terminal, the third input terminal, the fourth input terminal, the fifth input terminal, the sixth input terminal, and the seventh input terminal of the LUT adder circuitry 210, respectively. Also, the first output terminal, the second output terminal, and the third output terminal of the configurable gating circuitry 3021 are coupled to the first input terminal, the second input terminal, and the third input terminal of the adder circuitry 306, respectively. In the example of FIG. 3, the first input terminal, the second input terminal, and the third input terminal of the configurable gating circuitry 3021 operate as the first input terminal, the second input terminal, and the third input terminal of the LUT adder circuitry 210, respectively.

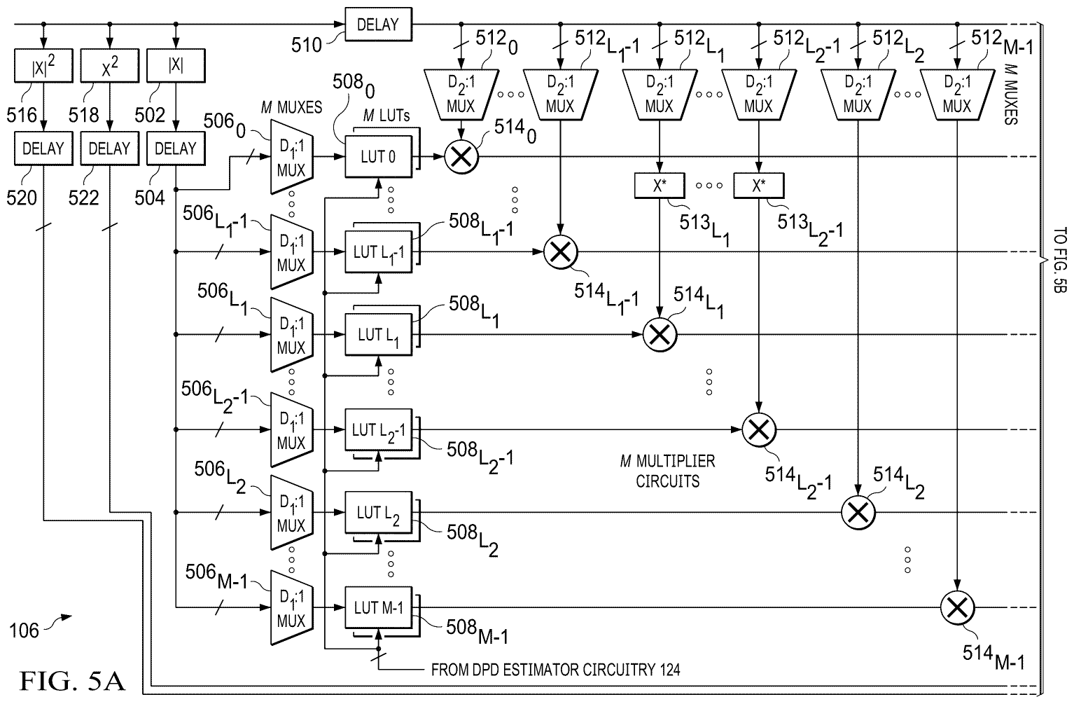

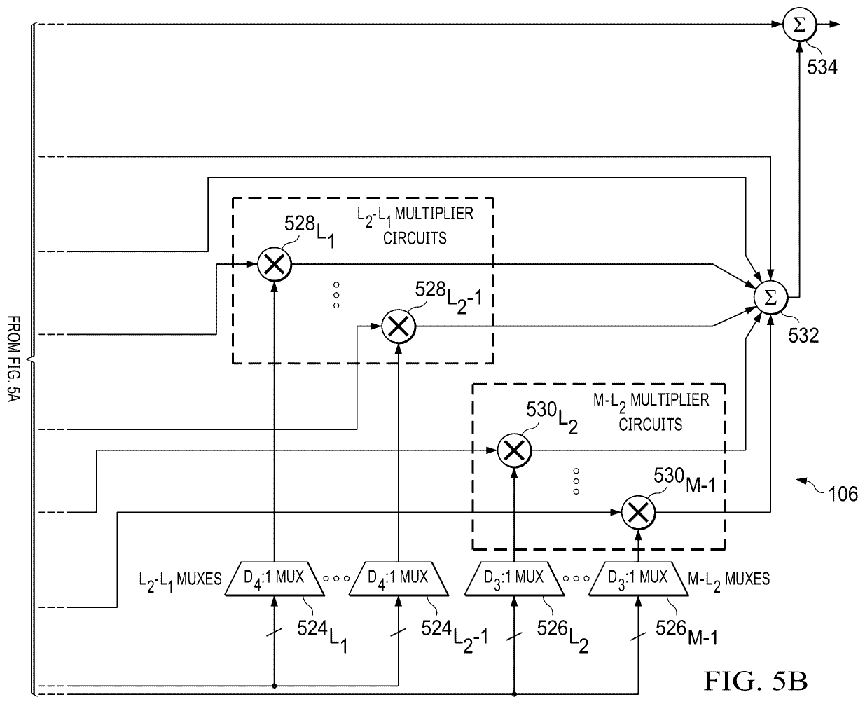

In the illustrated example of FIG. 3, the first output terminal and the second output terminal of the configurable gating circuitry 3022 are coupled to the first input terminal and the second input terminal of the adder circuitry 308, respectively. Also, in the example of FIG. 3, the first input terminal and the second input terminal of the configurable gating circuitry 3022 operate as the fourth input terminal and the fifth input terminal of the LUT adder circuitry 210, respectively. In the example of FIG. 5, the output terminal of the configurable gating circuitry 3023 is coupled to the input terminal of the adder circuitry 310 and the input terminal of the configurable gating circuitry 3023 operates as the sixth input terminal of the LUT adder circuitry 210. In the example of FIG. 3, the output terminal of the configurable gating circuitry 3024 is coupled to the input terminal of the adder circuitry 312 and the input terminal of the configurable gating circuitry 3024 operates as the first input terminal of the LUT adder circuitry 210. Also, in the example of FIG. 3, the output terminal of the configurable gating circuitry 3025 is coupled to the input terminal of the adder circuitry 314 and the input terminal of the configurable gating circuitry 3025 operates as the second input terminal of the LUT adder circuitry 210. In the example of FIG. 3, the output terminal of the configurable gating circuitry 3026 is coupled to the input terminal of the adder circuitry 316 and the input terminal of the configurable gating circuitry 3026 operates as the fourth input terminal of the LUT adder circuitry 210.

In the illustrated example of FIG. 3, each instance of the configurable gating circuitry 302 facilitates at least one enabling or disabling an input terminal of the LUT adder circuitry 210 with respect to the adder circuitry 304, the adder circuitry 306, the adder circuitry 308, the adder circuitry 310, the adder circuitry 312, the adder circuitry 314, and the adder circuitry 316. For example, the configurable gating circuitry 3022 at least one enables or disables transmission of at least one of the values at the fourth input terminal or the fifth input terminal of the LUT adder circuitry 210 to the adder circuitry 308. Other instances of the configurable gating circuitry 302 operate similarly.

In the illustrated example of FIG. 3, the adder circuitry 304 is implemented by six adder circuits (e.g., six half adder circuits, six full adder circuits, six ripple-carry adder circuits, six carry-lookahead adder circuits, etc.). Also, in the example of FIG. 3, the adder circuitry 306 is implemented by two adder circuits (e.g., two half adder circuits, two full adder circuits, two ripple-carry adder circuits, two carry-lookahead adder circuits, etc.). In the example of FIG. 3, the adder circuitry 308 is implemented by one adder circuit (e.g., one half adder circuit, one full adder circuits, one ripple-carry adder circuits, one carry-lookahead adder circuits, etc.). Also, in the example of FIG. 3, each of the adder circuitry 310, the adder circuitry 312, the adder circuitry 314, and the adder circuitry 316 is implemented by a buffer. In the example of FIG. 3, the number of addition operations performed by the LUT adder circuitry 210 is M+0.5M (log₂(M)−1), whereas, with M adder circuits each having M input terminals, the number of addition operations would be M².

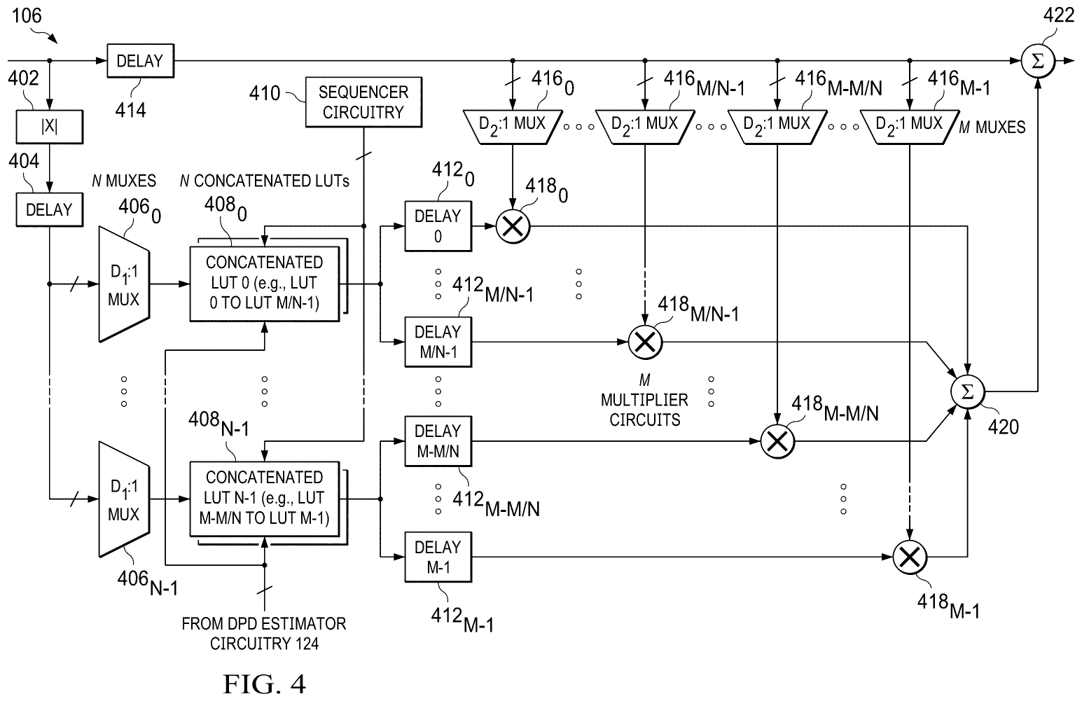

FIG. 4 is a block diagram of a second example implementation of the DPD corrector circuitry 106 of FIG. 1B. In the example of FIG. 4, the DPD corrector circuitry 106 includes example envelope generator circuitry 402, first example delay circuitry 404, first example multiplexer circuits 406₀-406_{N-1}, example concatenated lookup tables (LUTs) 408₀-408_{N-1}, example sequencer circuitry 410, and second example delay circuitry 412₀-412_{M-1}. In the example of FIG. 4, the DPD corrector circuitry 106 includes third example delay circuitry 414, second example multiplexer circuits 416₀-416_{M-1}, example multiplier circuits 418₀-418_{M-1}, first example adder circuitry 420, and second example adder circuitry 422.

In the illustrated example of FIG. 4, the envelope generator circuitry 402 has an output terminal and an input terminal and the delay circuitry 404 has D₁ output terminals and an input terminal. In the example of FIG. 4, each of the multiplexer circuits 406₀-406_{N-1} has an output terminal and D₁ input terminals and each of the concatenated LUTs 408₀-408_{N-1} has MIN output terminals, a first input terminal, a second input terminal, and a third input terminal. Also, in the example of FIG. 4, the sequencer circuitry 410 has N output terminals and each instance of the delay circuitry 412₀-412_{M-1} has an output terminal and an input terminal. In the example of FIG. 4, the delay circuitry 414 has D₂ output terminals and an input terminal and each of the multiplexer circuits 416₀-416_{M-1} has an output terminal and D₂ input terminals. Also, in the example of FIG. 4, each of the multiplier circuits 418₀-418_{M-1} has an output terminal, a first input terminal, and a second input terminal. In the example of FIG. 4, the adder circuitry 420 has an output terminal and M input terminals and the adder circuitry 422 has an output terminal, a first input terminal, and a second input terminal.

In the illustrated example of FIG. 4, the envelope generator circuitry 402 is implemented by digital circuitry. In the example of FIG. 4, the output terminal of the envelope generator circuitry 402 is coupled to the input terminal of the delay circuitry 404 and the input terminal of the envelope generator circuitry 402 is coupled to the DPD terminal 107 (e.g., is coupled to processor circuitry via the DPD terminal 107 of the pre-DPD interpolator circuitry 104). Also, in the example of FIG. 4, the delay circuitry 404 is implemented by one or more D flip-flop circuits. In some examples, the delay circuitry 404 is implemented by one or more FIFO queues. In the example of FIG. 4, the D₁ output terminals of the delay circuitry 404 are coupled to the D₁ input terminals of each of the multiplexer circuits 406₀-406_{N-1} and the input terminal of the delay circuitry 404 is coupled to the output terminal of the envelope generator circuitry 402.

In the illustrated example of FIG. 4, each of the multiplexer circuits 406₀-406_{N-1} is implemented by digital circuitry. In the example of FIG. 4, the output terminals of the multiplexer circuits 406₀-406_{N-1} are coupled to the first input terminals of the concatenated LUTs 408₀-408_{N-1}, respectively. For example, the output terminal of the multiplexer circuit 406₀ is coupled to the first input terminal of the concatenated LUT 4080. Also, the D₁ input terminals of each of the multiplexer circuits 406₀-406_{N-1} are coupled to the D₁ output terminals of the delay circuitry 404.

In the illustrated example of FIG. 4, each of the concatenated LUTs 4080-408N-1 is implemented by digital circuitry and at least one memory. For example, each of the concatenated LUTs 408₀-408_{N-1} is implemented by digital circuitry and one memory. In some examples, each of the concatenated LUTs 408₀-408_{N-1} is implemented by digital circuitry and two memories as described further below in connection with FIGS. 12, 13, 14, 15, and 16. In the example of FIG. 4, each of the concatenated LUTs 408₀-408_{N-1} is representative of a group of 32-bit LUTs having 512 entries. For example, if the concatenated LUTs 408₀-408_{N-1} are representative of M 32-bit LUTs having 512 entries, then each of the concatenated LUTs 408₀-408_{N-1} is representative of MIN 32-bit LUTs having 512 entries where MIN is rounded up to the nearest integer. Also, for example, the concatenated LUT 408₀ is structured to store data representative of a first LUT having 512 entries (e.g., U entries) and a first width of 32 bits (e.g., V-bits) and a second LUT having 512 entries (e.g., U entries) and a second width of 32 bits (e.g., V-bits). As such, the concatenated LUT 408₀ will have 512 entries (e.g., U entries) and a width of 64 bits (e.g., 2*V-bits). For example, a first entry of the concatenated LUT 408₀ includes 32 bits representative of (e.g., V-bits representative of) a first 32-bit entry (e.g., a V-bit entry) of the first LUT and 32 bits representative of (e.g., V-bits representative of) a second 32-bit entry (e.g., a l′-bit entry) of the second LUT. As such, each of the concatenated LUTs 408₀-408_{N-1} stores 512 entries of 32*M/N bits of data (e.g., each of the concatenated LUTs 408₀-408_{N-1} has 512 rows and each row is 32*MIN bits wide). Combining multiple 32-bit LUTs into a single concatenated LUT consumes less area on a chip than implementing the multiple 32-bit LUTs individually. For example, the concatenated LUTs 408₀-408_{N-1} stores more bits per unit area than an individual LUT and as such saves on-chip area while storing the same number of bits.

In the illustrated example of FIG. 4, the MIN output terminals of each of the concatenated LUTs 408₀-408_{N-1} are coupled to the input terminals of MIN instances of the delay circuitry 412₀-412_{M-1}, respectively. For example, the MIN output terminals of the concatenated LUT 408₀ are coupled to the input terminals of the delay circuitry 412₀-412_{M/N-1}, respectively, and the MIN output terminals of the concatenated LUT 408_{N-1} are coupled to the input terminals of the delay circuitry 412_{M-M/N}-412_{M-1}, respectively. Also, in the example of FIG. 4, the first input terminals of the concatenated LUTs 408₀-408_{N-1} are coupled to the output terminals of the multiplexer circuits 406₀-406_{N-1}, respectively. In the example of FIG. 4, the second input terminal of each of the concatenated LUTs 408₀-408_{N-1} is coupled to the output terminal of the DPD estimator circuitry 124 and the third input terminals of the concatenated LUTs 408₀-408_{N-1} are coupled to the N output terminals of the sequencer circuitry 410, respectively. In the example of FIG. 4, the sequencer circuitry 410 is implemented by digital circuitry. Also, the N output terminals of the sequencer circuitry 410 are coupled to the third input terminals of the concatenated LUTs 408₀-408_{N-1}, respectively.

In the illustrated example of FIG. 4, each instance of the delay circuitry 412₀-412_{M-1} is implemented by one or more D flip-flop circuits. In some examples, each instance of the delay circuitry 412₀-412_{M-1} is implemented by one or more FIFO queues. In the example of FIG. 4, the output terminals of the delay circuitry 412₀-412_{M-1} are coupled to the first input terminals of the multiplier circuits 418₀-418_{M-1}, respectively. In the example of FIG. 4, the input terminals of MIN instances of the delay circuitry 412₀-412_{M-1} are coupled to the MIN output terminals of each of the concatenated LUTs 408₀-408_{N-1}, respectively. For example, the input terminals of the delay circuitry 412₀-412_{M/N-1} are coupled to the MIN output terminals of the concatenated LUT 408₀, respectively, and the input terminals of the delay circuitry 412_{M-M/N}-412_{M-1} are coupled to the MIN output terminals of the concatenated LUT 408_{N-1}, respectively.

In the illustrated example of FIG. 4, the delay circuitry 414 is implemented by one or more D flip-flop circuits. In some examples, the delay circuitry 414 is implemented by one or more FIFO queues. In the example of FIG. 4, the D₂ output terminals of the delay circuitry 414 are coupled to the D₂ input terminals of each of the multiplexer circuits 416₀-416_{M-1} and the input terminal of the delay circuitry 414 is coupled to the DPD terminal 107 (e.g., is coupled to processor circuitry via the DPD terminal 107 of the pre-DPD interpolator circuitry 104). Also, one of the D₂ output terminals of the delay circuitry 414 is coupled to the first input terminal of the adder circuitry 422.

In the illustrated example of FIG. 4, each of the multiplexer circuits 416₀-416_{M-1} is implemented by digital circuitry. In the example of FIG. 4, the output terminals of the multiplexer circuits 416₀-416_{M-1} are coupled to the second input terminals of the multiplier circuits 418₀-418_{M-1}, respectively. Also, the D₂ input terminals of each of the multiplexer circuits 416₀-416_{M-1} are coupled to the D₂ output terminals of the delay circuitry 414. In the example of FIG. 4, each of the multiplier circuits 418₀-418_{M-1} is implemented by digital circuitry. In the example of FIG. 4, the output terminals of the multiplier circuits 418₀-418_{M-1} are coupled to the M input terminals of the adder circuitry 420, respectively. Also, the first input terminals of the multiplier circuits 418₀-418_{M-1} are coupled to the output terminals of the delay circuitry 412₀-412_{M-1}, respectively. In the example of FIG. 4, the second input terminals of the multiplier circuits 418₀-418_{M-1} are coupled to the output terminals of the multiplexer circuits 416₀-416_{M-1}, respectively.

In the illustrated example of FIG. 4, each of the adder circuitry 420 and the adder circuitry 422 is implemented by one or more adder circuits (e.g., one or more half adder circuits, one or more full adder circuits, one or more ripple-carry adder circuits, one or more carry-lookahead adder circuits, etc.). In the example of FIG. 4, the output terminal of the adder circuitry 420 is coupled to the second input terminal of the adder circuitry 422. Also, in the example of FIG. 4, the M input terminals of the adder circuitry 420 are coupled to the output terminals of the multiplier circuits 418₀-418_{M-1}. In the example of FIG. 4, the output terminal of the adder circuitry 422 is coupled to power amplifier circuitry (e.g., the PA circuitry 114 of FIG. 1B via the transmitter circuitry 108, the transmitter DAC circuit 110, and the DSA circuitry 112) and the third input terminal of the DPD estimator circuitry 124. Also, in the example of FIG. 4, the first input terminal of the adder circuitry 422 is coupled to one of the D₂ output terminals of the delay circuitry 414 and the second input terminal of the adder circuitry 422 is coupled to the output terminal of the adder circuitry 420.

In the illustrated example of FIG. 4, the DPD corrector circuitry 106 implements Equation 1 described above. In the example of FIG. 4, the envelope generator circuitry 402 determines an envelope (e.g., |x(n)|) of an input signal (e.g., x(n)). For example, the envelope generator circuitry 402 determines an envelope of an input signal as described above (e.g., |x(n)|={square root over (Re(x(n))′+Im(x(n))²))}. In the example of FIG. 4, the delay circuitry 404 generates D₁ delayed versions of the envelope of the input signal. For example, the delay circuitry 404 generates the D₁ delayed versions of the envelope of the input signal over the range

$$[ \frac{{D}_{1}}{2} - 1 , - \frac{{D}_{1}}{2} ] .$$

In the illustrated example of FIG. 4, as the D₁ delayed versions of the envelope of the input signal are utilized to index the concatenated LUTs 408₀-408_{N-1}, the delay circuitry 404 generates the D₁ delayed versions of the envelope of the input signal such that each of the concatenated LUTs 408₀-408_{N-1} is indexed by a signal having a common delay (e.g., a minimum delay) shared between the group of 32-bit LUTs represented by the concatenated LUTs 408₀-408_{N-1}, respectively. For example, the delay circuitry 404 generates (1) a first delayed version of the envelope of the input signal delayed by a first common delay shared between the group of 32-bit LUTs represented by the concatenated LUT 408₀ and (2) a second delayed version of the envelope of the input signal delayed by a second common delay shared between the group of 32-bit LUTs represented by the concatenated LUT 408_{N-1}. As such, a single concatenated LUT can be used to represent a group of 32-bit LUTs. As described below, each instance of the delay circuitry 412₀-412_{M-1} applies a delay to a respective value output by the concatenated LUTs 408₀-408_{N-1}. As such, the respective values output from the delay circuitry 412₀-412_{M-1} correspond to the respective l₂(k) delays to be applied to the envelope of the input signal according to Equation 1 above.

In the illustrated example of FIG. 4, each of the multiplexer circuits 406₀-406_{N-1} selects one of the D₁ delayed versions of the envelope of the input signal based on a programmed value in a respective register associated with each of the multiplexer circuits 406₀-406_{N-1}. For example, the multiplexer circuit 406₀ selects one of the D₁ delayed versions of the envelope of the input signal based on a programmed value in a register associated with the multiplexer circuit 406₀. In the example of FIG. 4, the registers associated with the multiplexer circuits 406₀-406_{N-1} are programmed at startup of the DPD corrector circuitry 106. For example, the registers associated with the multiplexer circuits 406₀-406_{N-1} are programmed at startup of the communication system 100 of FIG. 1B.

In the illustrated example of FIG. 4, the selected delayed versions of the envelope of the input signal that are output from the multiplexer circuits 406₀-406_{N-1} index the concatenated LUTs 408₀-408_{N-1}, respectively. As described above, the delay circuitry 404 generates the D₁ delayed versions of the envelope of the input signal such that each of the concatenated LUTs 408₀-408_{N-1} is indexed by a signal having a common delay shared between the group of 32-bit LUTs represented by the concatenated LUTs 408₀-408_{N-1}, respectively. As such, the respective values output by each of the concatenated LUTs 408₀-408_{N-1} correspond to a common delay with which each of the concatenated LUTs 408₀-408_{N-1} was indexed. In the example of FIG. 4, each instance of the delay circuitry 412₀-412_{M-1} applies a delay to a respective value output by the concatenated LUTs 408₀-408_{N-1}. For example, M registers associated with respective instances of the delay circuitry 412₀-412_{M-1} can be programmed at startup of the DPD corrector circuitry 106 to configure the delays of each instance of the delay circuitry 412₀-412_{M-1} based on the l₂ (k) delay to be applied to the envelope of the input signal according to Equation 1 above.

In the illustrated example of FIG. 4, the delay circuitry 414 generates D₂ delayed versions of the input signal. For example, the delay circuitry 414 generates the D₂ delayed versions of the input signal over the range

$$[ \frac{{D}_{2}}{2} - 1 , - \frac{{D}_{2}}{2} ] .$$

Also, the delay circuitry 414 provides the input signal (e.g., x(n±0)) to the first input terminal of the adder circuitry 422. In the example of FIG. 4, each of the multiplexer circuits 416₀-416_{M-1} selects one of the D₂ delayed versions of the input signal based on a programmed value in a respective register associated with each of the multiplexer circuits 416₀-416_{M-1}. For example, the multiplexer 416₀ selects one of the D₂ delayed versions of the input signal based on a programmed value in a register associated with the multiplexer 416₀. In the example of FIG. 4, the registers associated with the multiplexer circuits 416₀-416_{M-1} are programmed at startup of the DPD corrector circuitry 106. For example, the registers associated with the multiplexer circuits 416₀-416_{M-1} are programmed at startup of the communication system 100 of FIG. 1B.

In the illustrated example of FIG. 4, each of the multiplexer circuits 416₀-416_{M-1} provides one of the D₂ delayed versions of the input signal to the second input terminal of each of the multiplier circuits 418₀-418_{M-1}, respectively. In the example of FIG. 4, each of the multiplier circuits 418₀-418_{M-1} multiplies the values at the M output terminals of the delay circuitry 412₀-412_{M-1} by the values at the output terminals of the multiplexer circuits 416₀-416_{M-1}, respectively. The multiplier circuits 418₀-418_{M-1} provide the products to the input terminals of the adder circuitry 420, which adds the values and provides the sum to the second input terminal of the adder circuitry 422. The adder circuitry 422 adds the input signal (e.g., x(n±0)) with the value at the output terminal of the adder circuitry 420 and provides the sum at the output terminal of the DPD corrector circuitry 106.

As described above, the DPD corrector circuitry 106 of FIG. 1B is parallelized-by-two. For example, the DPD corrector circuitry 106 can be parallelized-by-two to facilitate operation at a higher sampling rate while also operating at a lower clock rate. Accordingly, another instance of the circuitry of FIG. 4 may be implemented in parallel with the circuitry of FIG. 4 to facilitate such parallelization. That is, the circuitry of FIG. 4 may be duplicated and some of the circuitry of FIG. 4 may be adjusted to implement a parallel instance of the circuitry of FIG. 4. For example, in a parallelized-by-two implementation of the circuitry of FIG. 4, each instance of the delay circuitry 404 generates D₁/2 delayed versions of the envelope of the input signal and the multiplexer circuits 406₀-406_{N-1} in each instance of the circuitry of FIG. 4 receive values from both instances of the delay circuitry 404. Similarly, in a parallelized-by-two implementation of the circuitry of FIG. 4, each instance of the delay circuitry 414 generates D₂/2 delayed versions of the envelope of the input signal and the multiplexer circuits 416₀-416_{M-1} in each instance of the circuitry of FIG. 4 receive values from both instances of the delay circuitry 414. Also, the programmed delay values of each of the delay circuitry 412₀-412_{M-1} may be adjusted to implement a parallel instance of the circuitry of FIG. 4. As such, in a first clock cycle of the DPD corrector circuitry 106, a first instance of the circuitry of FIG. 4 processes a first sample of an input signal (e.g., x(n)) in parallel with a second instance of the circuitry of FIG. 4 that processes a second sample of the input signal (e.g., x(n+1)). Additional instances of the circuitry of FIG. 4 may be implemented to support additional parallelization (e.g., three instances of the circuitry of FIG. 4 to support a parallelized-by-three implementation, four instances of the circuitry of FIG. 4 to support a parallelized-by-four implementation, etc.).

In a parallelized-by-two implementation of the DPD corrector circuitry 106, another instance of the concatenated LUTs 408₀-408_{N-1} can be implemented in a parallel instance of the circuitry of FIG. 4. Also, the concatenated LUTs 408₀-408_{N-1} can be shared between each instance of the circuitry of FIG. 4. For example, the concatenated LUTs 408₀-408_{N-1} can be implemented once and accessed by a first instance of the circuitry of FIG. 4 and a second instance of the circuitry of FIG. 4 in the same clock cycle as described further below in connection with FIGS. 12, 13, 14, 15, and 16.

Also, as described above, the non-linearity of PA circuitry can fluctuate based on temperature of the PA circuitry or input signal profile to the PA circuitry. As such, the DPD corrector circuitry 106 includes a spare concatenated LUT for each of the concatenated LUTs 408₀-408_{N-1} (e.g., main concatenated LUTs). For example, the spare concatenated LUTs can be updated by the DPD estimator circuitry 124 while the DPD corrector circuitry 106 utilizes the concatenated LUTs 408₀-408_{N-1} (e.g., the main concatenated LUTs) to perform DPD correction. Because the values output from the concatenated LUTs 408₀-408_{N-1} (e.g., the main concatenated LUTs) may be delayed by different amounts, the sequencer circuitry 410 sequences the switch from the concatenated LUTs 408₀-408_{N-1} (e.g., the main concatenated LUTs) to the spare concatenated LUTs.

For example, the sequencer circuitry 410 sequences the switch of the delay circuitry 412₀-412_{M-1} from the concatenated LUTs 408₀-408_{N-1} (e.g., the main concatenated LUTs) to the spare concatenated LUTs such that the values output from each instance of the delay circuitry 412₀-412_{M-1} switch to updated values from the DPD estimator circuitry 124 in the same clock cycle. In the example of FIG. 4, once the sequencer circuitry 410 has switched the DPD corrector circuitry 106 from the concatenated LUTs 408₀-408_{N-1} (e.g., the main concatenated LUTs) to the spare concatenated LUTs, the sequencer circuitry 410 facilitates updating of the concatenated LUTs 408₀-408_{N-1} (e.g., the main concatenated LUTs) with updated values to model PA circuitry non-linearity. After the concatenated LUTs 408₀-408_{N-1} (e.g., the main concatenated LUTs) have been updated, the sequencer circuitry 410 switches the DPD corrector circuitry 106 from the spare concatenated LUTs to the concatenated LUTs 408₀-408_{N-1} (e.g., the main concatenated LUTs).

FIG. 5 is a block diagram of a third example implementation of the DPD corrector circuitry 106 of FIG. 1B. In the example of FIG. 5, the DPD corrector circuitry 106 includes example envelope generator circuitry 502, first example delay circuitry 504, first example multiplexer circuits 506₀-506_{M-1}, and example lookup tables (LUTs) 508₀-508_{M-1}, second example delay circuitry 510, second example multiplexer circuits 512₀-512_{M-1}, example conjugate generator circuitry 513_{L1}-513_{L2-1}, and first example multiplier circuits 514₀-514_{M-1}. Also, in the example of FIG. 5, the DPD corrector circuitry 106 includes example squared envelope generator circuitry 516, example squared signal generator circuitry 518, third example delay circuitry 520, fourth example delay circuitry 522, third example multiplexer circuits 524_{L1}-524_{L2-1}, fourth example multiplexer circuits 526_{L2}-526_{M-1}, second example multiplier circuits 528_{L1}-528_{L2-1}, third example multiplier circuits 530_{L2}-530_{M-1}, first example adder circuitry 532, and second example adder circuitry 534.

In the illustrated example of FIG. 5, the envelope generator circuitry 502 has an output terminal and an input terminal and the delay circuitry 504 has D₁ output terminals and an input terminal. In the example of FIG. 5, each of the multiplexer circuits 506₀-506_{M-1} has an output terminal and D₁ input terminals, and each of the LUTs 508₀-508_{M-1} has an output terminal, a first input terminal, and a second input terminal. Also, in the example of FIG. 5, the delay circuitry 510 has D₂ output terminals and an input terminal and each of the multiplexer circuits 512₀-512_{M-1} has an output terminal and D₂ input terminals. Also, each instance of the conjugate generator circuitry 513_{L1}-513_{L2-1} has an output terminal and an input terminal. In the example of FIG. 5, each of the multiplier circuits 514₀-514_{M-1} has an output terminal, a first input terminal, and a second input terminal.

In the illustrated example of FIG. 5, each of the squared envelope generator circuitry 516 and the squared signal generator circuitry 518 has an output terminal and an input terminal. Also, in the example of FIG. 5, the delay circuitry 520 has D₃ output terminals and an input terminal and the delay circuitry 522 has D₄ output terminals and an input terminal. In the example of FIG. 5, each of the multiplexer circuits 524_{L1}-524_{L2-1} has an output terminal and D₄ input terminals and each of the multiplexer circuits 526_{L2}-526_{M-1} has an output terminal and D₃ input terminals. Also, in the example of FIG. 5, each of the multiplier circuits 528_{L1}-528_{L2-1} and each of the multiplier circuits 530_{L2}-530_{M-1} has an output terminal, a first input terminal, and a second input terminal. In the example of FIG. 5, the adder circuitry 532 has an output terminal and M input terminals and the adder circuitry 534 has an output terminal, a first input terminal, and a second input terminal.

In the illustrated example of FIG. 5, the envelope generator circuitry 502 is implemented by digital circuitry. In the example of FIG. 5, the output terminal of the envelope generator circuitry 502 is coupled to the input terminal of the delay circuitry 504 and the input terminal of the envelope generator circuitry 502 is coupled to the DPD terminal 107 (e.g., is coupled to processor circuitry via the DPD terminal 107 of the pre-DPD interpolator circuitry 104). Also, in the example of FIG. 5, the delay circuitry 504 is implemented by one or more D flip-flop circuits. In some examples, the delay circuitry 504 is implemented by one or more FIFO queues. In the example of FIG. 5, the D₁ output terminals of the delay circuitry 504 are coupled to the D₁ input terminals of each of the multiplexer circuits 506₀-506_{M-1} and the input terminal of the delay circuitry 504 is coupled to the output terminal of the envelope generator circuitry 502.

In the illustrated example of FIG. 5, each of the multiplexer circuits 506₀-506_{M-1} is implemented by digital circuitry. In the example of FIG. 5, the D₁ input terminals of each of the multiplexer circuits 506₀-506_{M-1} are coupled to the D₁ output terminals of the delay circuitry 504. Also, the output terminals of the multiplexer circuits 506₀-506_{M-1} are coupled to the first input terminals of the LUTs 508₀-508_{M-1}, respectively. For example, the output terminal of the multiplexer circuit 506₀ is coupled to the first input terminal of the LUT 508₀.

In the illustrated example of FIG. 5, each of the LUTs 508₀-508_{M-1} is implemented by digital circuitry and at least one memory. For example, each of the LUTs 508₀-508_{M-1} is implemented by digital circuitry and one memory. In some examples, each of the LUTs 508₀-508_{M-1} is implemented by digital circuitry and two memories as described further below in connection with FIGS. 12, 13, 14, 15, and 16. In the example of FIG. 5, each of the LUTs 508₀-508_{M-1} stores 512 entries of 32 bits of data (e.g., each of the LUTs 508₀-508_{M-1} has 512 rows and each row is 32 bits wide). Also, in the example of FIG. 5, the first input terminals of the LUTs 508₀-508_{M-1} are coupled to the output terminals of the multiplexer circuits 506₀-506_{M-1}, respectively. In the example of FIG. 5, the second input terminal of each of the LUTs 508₀-508_{M-1} is coupled to the output terminal of the DPD estimator circuitry 124.

In the illustrated example of FIG. 5, the output terminals of the LUTs 508₀-508_{M-1} are coupled to the first input terminals of the multiplier circuits 514₀-514_{M-1}, respectively. For example, the output terminals of a first portion (e.g., the LUTs 508₀-508_{L1-1}) of the LUTs 508₀-508_{M-1} are coupled to the first input terminals of a first portion (e.g., the multiplier circuits 514₀-514_{L1-1}) of the multiplier circuits 514₀-514_{M-1}, respectively. Also, for example, the output terminals of a second portion (e.g., the LUTs 508_{L1}-508_{L2-1}) of the LUTs 508₀-508_{M-1} are coupled to the first input terminals of a second portion (e.g., the multiplier circuits 514_{L1}-514_{L2-1}) of the multiplier circuits 514₀-514_{M-1}, respectively. Also, for example, the output terminals of a third portion (e.g., the LUTs 508_{L2}-508_{M-1}) of the LUTs 508₀-508_{M-1} are coupled to the first input terminals of a third portion (e.g., the multiplier circuits 514_{L2}-514_{M-1}) of the multiplier circuits 514₀-514_{M-1}, respectively.

In the illustrated example of FIG. 5, the delay circuitry 510 is implemented by one or more D flip-flop circuits. In some examples, the delay circuitry 510 is implemented by one or more FIFO queues. In the example of FIG. 5, the D₂ output terminals of the delay circuitry 510 are coupled to the D₂ input terminals of each of the multiplexer circuits 512₀-512_{M-1} and the input terminal of the delay circuitry 510 is coupled to the DPD terminal 107 (e.g., is coupled to processor circuitry via the DPD terminal 107 of the pre-DPD interpolator circuitry 104). Also, one of the D₂ output terminals of the delay circuitry 510 is coupled to the first input terminal of the adder circuitry 534.

In the illustrated example of FIG. 5, each of the multiplexer circuits 512₀-512_{M-1} is implemented by digital circuitry. In the example of FIG. 5, the output terminals of a first portion (e.g., the multiplexer circuits 512₀-512_{L1-1}) of the multiplexer circuits 512₀-512_{M-1} are coupled to the second input terminals of a first portion (e.g., the multiplier circuits 514₀-514_{L1-1}) of the multiplier circuits 514₀-514_{M-1}, respectively. Also, the output terminals of a second portion (e.g., the multiplexer circuits 512_{L1}-512_{L2-1}) of the multiplexer circuits 512₀-512_{M-1} are coupled to the input terminals of the conjugate generator circuitry 513_{L1}-513_{L2-1}, respectively. In the example of FIG. 5, the output terminals of a third portion (e.g., the multiplexer circuits 512_{L2}-512_{M-1}) of the multiplexer circuits 512₀-512_{M-1} are coupled to the second input terminals of a third portion (e.g., the multiplier circuits 514_{L2}-514_{M-1}) of the multiplier circuits 514₀-514_{M-1}, respectively. In the example of FIG. 5, the D₂ input terminals of each of the multiplexer circuits 512₀-512_{M-1} are coupled to the D₂ output terminals of the delay circuitry 510.

In the illustrated example of FIG. 5, each instance of the conjugate generator circuitry 513_{L1}-513_{L2-1} is implemented by digital circuitry. In the example of FIG. 5, the output terminals of the conjugate generator circuitry 513_{L1}-513_{L2-1} are coupled to the second input terminals of a second portion (e.g., the multiplier circuits 514_{L1}-514_{L2-1}) of the multiplier circuits 514₀-514_{M-1}, respectively. Also, the input terminals of the conjugate generator circuitry 513_{L1}-513_{L2-1} are coupled to the output terminals of the second portion (e.g., the multiplexer circuits 512_{L1}-512_{L2-1}) of the multiplexer circuits 512₀-512_{M-1}, respectively. In the example of FIG. 5, each of the multiplier circuits 514₀-514_{M-1} is implemented by digital circuitry.

In the illustrated example of FIG. 5, the output terminals of the first portion (e.g., the multiplier circuits 514₀-514_{L1-1}) of the multiplier circuits 514₀-514_{M-1} are coupled to a first portion of the M input terminals of the adder circuitry 532, respectively. Also, the output terminals of the second portion (e.g., the multiplier circuits 514_{L1}-514_{L2-1}) of the multiplier circuits 514₀-514_{M-1} are coupled to the first input terminals of the multiplier circuits 528_{L1}-528_{L2-1}, respectively. In the example of FIG. 5, the output terminals of the third portion (e.g., the multiplier circuits 514_{L2}-514_{M-1}) of the multiplier circuits 514₀-514_{M-1} are coupled to the first input terminals of the multiplier circuits 530_{L2}-530_{M-1}, respectively. Also, in the example of FIG. 5, the first input terminals of the multiplier circuits 514₀-514_{M-1} are coupled to the output terminals of the LUTs 508₀-508_{M-1}, respectively.

In the illustrated example of FIG. 5, the second input terminals of the first portion (e.g., the multiplier circuits 514₀-514_{L1-1}) of the multiplier circuits 514₀-514_{M-1} are coupled to the output terminals of the first portion (e.g., the multiplexer circuits 512₀-512_{L1-1}) of the multiplexer circuits 512₀-512_{M-1}, respectively. In the example of FIG. 5, the second input terminals of the second portion (e.g., the multiplier circuits 514_{L1}-514_{L2-1}) of the multiplier circuits 514₀-514_{M-1} are coupled to the output terminals of the conjugate generator circuitry 513_{L1}-513_{L2-1}, respectively. Also, the second input terminals of the third portion (e.g., the multiplier circuits 514_{L2}-514_{M-1}) of the multiplier circuits 514₀-514_{M-1} are coupled to the output terminals of the third portion (e.g., the multiplexer circuits 512_{L2}-512_{M-1}) of the multiplexer circuits 512₀-512_{M-1}, respectively.

In the illustrated example of FIG. 5, the squared envelope generator circuitry 516 is implemented by digital circuitry. In the example of FIG. 5, the output terminal of the squared envelope generator circuitry 516 is coupled to the input terminal of the delay circuitry 520 and the input terminal of the squared envelope generator circuitry 516 is coupled to the DPD terminal 107 (e.g., is coupled to processor circuitry via the DPD terminal 107 of the pre-DPD interpolator circuitry 104). In the example of FIG. 5, the squared signal generator circuitry 518 is implemented by digital circuitry. Also, the output terminal of the squared signal generator circuitry 518 is coupled to the input terminal of the delay circuitry 522 and the input terminal of the squared signal generator circuitry 518 is coupled to the DPD terminal 107 (e.g., is coupled to processor circuitry via the DPD terminal 107 of the pre-DPD interpolator circuitry 104).

In the illustrated example of FIG. 5, the delay circuitry 520 is implemented by one or more D flip-flop circuits. In some examples, the delay circuitry 520 is implemented by one or more FIFO queues. In the example of FIG. 5, the D₃ output terminals of the delay circuitry 520 are coupled to the D₃ input terminals of each of the multiplexer circuits 526_{L2}-526_{M-1} and the input terminal of the delay circuitry 520 is coupled to the output terminal of the squared envelope generator circuitry 516. Also, in the example of FIG. 5, the delay circuitry 522 is implemented by one or more D flip-flop circuits. In some examples, the delay circuitry 522 is implemented by one or more FIFO queues. In the example of FIG. 5, the D₄ output terminals of the delay circuitry 522 are coupled to the D₄ input terminals of each of the multiplexer circuits 524_{L1}-524_{L2-1} and the input terminal of the delay circuitry 522 is coupled to the output terminal of the squared signal generator circuitry 518.

In the illustrated example of FIG. 5, each of the multiplexer circuits 524_{L1}-524_{L2-1} is implemented by digital circuitry. In the example of FIG. 5, the D₄ input terminals of each of the multiplexer circuits 524_{L1}-524_{L2-1} are coupled to the D₄ output terminals of the delay circuitry 522. Also, the output terminals of the multiplexer circuits 524_{L1}-524_{L2-1} are coupled to the second input terminals of the multiplier circuits 528_{L1}-528_{L2-1}, respectively. For example, the output terminal of the multiplexer circuit 524_{L1} is coupled to the second input terminal of the multiplier circuit 528_{L1}. In the example of FIG. 5, each of the multiplexer circuits 526_{L2}-526_{M-1} is implemented by digital circuitry. Also, in the example of FIG. 5, the D₃ input terminals of each of the multiplexer circuits 526_{L2}-526_{M-1} are coupled to the D₃ output terminals of the delay circuitry 520. In the example of FIG. 5, the output terminals of the multiplexer circuits 526_{L2}-526_{M-1} are coupled to the second input terminals of the multiplier circuits 530_{L2}-530_{M-1}, respectively. For example, the output terminal of the multiplexer circuit 526_{L2} is coupled to the second input terminal of the multiplier circuit 530_{L2}.

In the illustrated example of FIG. 5, each of the multiplier circuits 528_{L1}-528_{L2-1} is implemented by digital circuitry. In the example of FIG. 5, the output terminals of the multiplier circuits 528_{L1}-528_{L2-1} are coupled to a second portion of the M input terminals of the adder circuitry 532, respectively. Also, the first input terminals of the multiplier circuits 528_{L1}-528_{L2-1} are coupled to the output terminals of the second portion (e.g., the multiplier circuits 514_{L1}-514_{L2-1}) of the multiplier circuits 514₀-514_{M-1}, respectively. In the example of FIG. 5, the second input terminals of the multiplier circuits 528_{L1}-528_{L2-1} are coupled to the output terminals of the multiplexer circuits 524_{L1}-524_{L2-1}, respectively.

In the illustrated example of FIG. 5, each of the multiplier circuits 530_{L2}-530_{M-1} is implemented by digital circuitry. In the example of FIG. 5, the output terminals of the multiplier circuits 530_{L2}-530_{M-1} are coupled to a third portion of the M input terminals of the adder circuitry 532, respectively. Also, the first input terminals of the multiplier circuits 530_{L2}-530_{M-1} are coupled to the output terminals of the third portion (e.g., the multiplier circuits 514_{L2}-514_{M-1}) of the multiplier circuits 514₀-514_{M-1}, respectively. In the example of FIG. 5, the second input terminals of the multiplier circuits 530_{L2}-530_{M-1} are coupled to the output terminals of the multiplexer circuits 526_{L2}-526_{M-1}, respectively.

In the illustrated example of FIG. 5, each of the adder circuitry 532 and the adder circuitry 534 is implemented by one or more adder circuits (e.g., one or more half adder circuits, one or more full adder circuits, one or more ripple-carry adder circuits, one or more carry-lookahead adder circuits, etc.). In the example of FIG. 5, the output terminal of the adder circuitry 532 is coupled to the second input terminal of the adder circuitry 534. Also, in the example of FIG. 5, a first portion of the M input terminals of the adder circuitry 532 are coupled to the output terminals of the first portion (e.g., the multiplier circuits 514₀-514_{L1-1}) of the multiplier circuits 514₀-514_{M-1}, respectively. In the example of FIG. 5, a second portion of the M input terminals of the adder circuitry 532 are coupled to the output terminals of the multiplier circuits 528_{L1}-528_{L2-1}, respectively, and a third portion of the M input terminals of the adder circuitry 532 are coupled to the output terminals of the multiplier circuits 530_{L2}-530_{M-1}, respectively. In the example of FIG. 5, the output terminal of the adder circuitry 534 is coupled to power amplifier circuitry (e.g., the PA circuitry 114 of FIG. 1B via the transmitter circuitry 108, the transmitter DAC circuit 110, and the DSA circuitry 112) and the third input terminal of the DPD estimator circuitry 124. Also, in the example of FIG. 5, the first input terminal of the adder circuitry 534 is coupled to one of the D₂ output terminals of the delay circuitry 510 and the second input terminal of the adder circuitry 534 is coupled to the output terminal of the adder circuitry 532.

In the illustrated example of FIG. 5, the DPD corrector circuitry 106 implements Equation 2 described below.

$$y ( n ) = x ( n ) + {\sum }_{k = 1}^{{L}_{1}} x ( n - {l}_{1} ( k ) ) * {f}_{k} ( \vert x ( n - {l}_{2} ( k ) ) \vert ) + {\sum }_{k = {L}_{1} + 1}^{{L}_{2}} {x}^{*} ( n - {l}_{1} ( k ) ) * {f}_{k} ( \vert x ( n - {l}_{2} ( k ) ) \vert ) * {x}^{2} ( n - {l}_{3} ( k ) ) + {\sum }_{k = {L}_{2} + 1}^{M} x ( n - {l}_{1} ( k ) ) * {f}_{k} ( \vert x ( n - {l}_{2} ( k ) ) \vert ) * {\vert x ( n - {l}_{3} ( k ) ) \vert}^{2} \qquad Equation 2$$

In the example of Equation 2, x(n) represents an input signal, y(n) represents a pre-distorted version of the input signal, |x(n)| represents a function to compute the envelope of x(n), x*(n) represents a function to compute the conjugate of x(n), x² (n) represents a squared version of x(n), and |x(n)|² represents a squared envelope of x(n). The envelope (e.g., |x(n)|) of an input signal x(n) can be determined by computing the square root of the sum of the squared real and squared imaginary components of x(n) (e.g., |x(n)|={square root over (Re(x(n))²+Im(x(n))²))}. Also, assuming an input signal x(n) can be defined as the sum of a real and imaginary component (e.g., x(n)=a(n)+i*b(n)), the conjugate (e.g., x*(n)) of the input signal x(n) can be determined by changing the sign of the imaginary component of the input signal x(n) (e.g., x*(n)=a(n)−i*b(n).

In the example Equation 2, l₁ (k) represent a delay (e.g., at least one of positive or negative) applied to x(n) and x*(n), and l₂(k) represents a delay applied to |x(n)|. Also, in Equation 2, l₃(k) represent a delay (e.g., at least one of positive or negative) applied to x² (n) and |x(n)|². In the example of Equation 2, the non-linearity of PA circuitry is modeled by M non-linear functions ƒₖ( ). In Equation 2, ƒₖ (|x(n−l₂(k))|) represents an output of a non-linear function indexed by |x(n−l₂(k))|. By implementing the DPD model of Equation 2, the DPD corrector circuitry 106 improves pre-distortion modeling accuracy at higher bandwidths (e.g., greater than 100 MHZ).

In the illustrated example of FIG. 5, the envelope generator circuitry 502 determines an envelope (e.g., |x(n)|) of an input signal (e.g., x(n)). For example, the envelope generator circuitry 502 determines an envelope of an input signal as described above (e.g., |x(n)|={square root over (Re(x(n))²+Im(x(n))²))}. In the example of FIG. 5, the delay circuitry 504 generates D₁ delayed versions of the envelope of the input signal. For example, the delay circuitry 504 generates the D₁ delayed versions of the envelope of the input signal over the range

$$[ \frac{{D}_{1}}{2} - 1 , - \frac{{D}_{1}}{2} ] .$$

In the illustrated example of FIG. 5, each of the multiplexer circuits 506₀-506_{M-1} selects one of the D₁ delayed versions of the envelope of the input signal based on a programmed value in a respective register associated with each of the multiplexer circuits 506₀-506_{M-1}. For example, the multiplexer circuit 506₀ selects one of the D₁ delayed versions of the envelope of the input signal based on a programmed value in a register associated with the multiplexer circuit 506₀. In the example of FIG. 5, the registers associated with the multiplexer circuits 506₀-506_{M-1} are programmed at startup of the DPD corrector circuitry 106. For example, the registers associated with the multiplexer circuits 506₀-506_{M-1} are programmed at startup of the communication system 100 of FIG. 1B. In the example of FIG. 5, the selected delayed versions of the envelope of the input signal that are output from the multiplexer circuits 506₀-506M-1 index the LUTs 508₀-508_{M-1}, respectively. The LUTs 508₀-508_{M-1} output values to the multiplier circuits 514₀-514_{M-1} based on the respective indices.

In the illustrated example of FIG. 5, the delay circuitry 510 generates D₂ delayed of the input signal. For example, the delay circuitry 510 generates the D₂ delayed versions of the input signal over the range

$$[ \frac{{D}_{2}}{2} - 1 , - \frac{{D}_{2}}{2} ] .$$

Also, the delay circuitry 510 provides the input signal (e.g., x(n±0)) to the first input terminal of the adder circuitry 534. In the example of FIG. 5, each of the multiplexer circuits 512₀-512_{M-1} selects one of the D₂ delayed versions of the input signal based on a programmed value in a respective register associated with each of the multiplexer circuits 512₀-512_{M-1}. For example, the multiplexer 512₀ selects one of the D₂ delayed versions of the input signal based on a programmed value in a register associated with the multiplexer 512₀. In the example of FIG. 5, the registers associated with the multiplexer circuits 512₀-512_{M-1} are programmed at startup of the DPD corrector circuitry 106. For example, the registers associated with the multiplexer circuits 512₀-512_{M-1} are programmed at startup of the communication system 100 of FIG. 1B.

In the illustrated example of FIG. 5, the first portion (e.g., the multiplexer circuits 512₀-512_{L1-1}) of the multiplexer circuits 512₀-512_{M-1} provide one of the D₂ delayed versions of the input signal to the second input terminals of the first portion (e.g., the multiplier circuits 514₀-514_{L1-1}) of the multiplier circuits 514₀-514_{M-1}, respectively. Also, the second portion (e.g., the multiplexer circuits 512_{L1}-512_{L2-1}) of the multiplexer circuits 512₀-512_{M-1} provide one of the D₂ delayed versions of the input signal to the input terminals of the conjugate generator circuitry 513_{L1}-513_{L2-1}, respectively. In the example of FIG. 5, the third portion (e.g., the multiplexer circuits 512_{L2}-512_{M-1}) of the multiplexer circuits 512₀-512_{M-1} provide respective ones of the third delayed versions of the input signal to the second input terminals of the third portion (e.g., the multiplier circuits 514_{L2}-514_{M-1}) of the multiplier circuits 514₀-514_{M-1}, respectively.

In the illustrated example of FIG. 5, each instance of the conjugate generator circuitry 513_{L1}-513_{L2-1} determines a conjugate of respective ones of the D₂ delayed versions of the input signal received from the second portion (e.g., the multiplexer circuits 512_{L1}-512_{L2-1}) of the multiplexer circuits 512₀-512_{M-1}, respectively. For example, each instance of the conjugate generator circuitry 513_{L1}-513_{L2-1} determines a conjugate as described above (e.g., x*(n)=a(n)−i*b(n)). In the example of FIG. 5, each instance of the conjugate generator circuitry 513_{L1}-513_{L2-1} provides the respective conjugates to the second input terminals of the second portion (e.g., the multiplier circuits 514_{L1}-514_{L2-1}) of the multiplier circuits 514₀-514_{M-1}, respectively. Also, in the example of FIG. 5, each of the multiplier circuits 514₀-514_{M-1} multiplies the values at the output terminals of the LUTs 508₀-508_{M-1} by the values at the second input terminals of the multiplier circuits 514₀-514_{M-1}, respectively.

In the illustrated example of FIG. 5, the first portion (e.g., the multiplier circuits 514₀-514_{L1-1}) of the multiplier circuits 514₀-514_{M-1} provide a first portion of the products to the first portion of the M input terminals of the adder circuitry 532. Also, the second portion (e.g., the multiplier circuits 514_{L1}-514_{L2-1}) of the multiplier circuits 514₀-514_{M-1} provide a second portion of the products to the first input terminals of the multiplier circuits 528_{L1}-528_{L2-1}, respectively. In the example of FIG. 5, the third portion (e.g., the multiplier circuits 514_{L2}-514_{M-1}) of the multiplier circuits 514₀-514_{M-1} provide a third portion of the products to the first input terminals of the multiplier circuits 530_{L2}-530_{M-1}, respectively.

In the illustrated example of FIG. 5, the squared envelope generator circuitry 516 determines a squared envelope (e.g., |x(n)|²) of an input signal (e.g., x(n)). For example, the squared envelope generator circuitry 516 determines a squared envelope of an input signal by computing the sum of the squared real and squared imaginary components of x(n) (e.g., |x(n)|²=Re(x(n))²+Im(x(n))²). Also, the squared signal generator circuitry 518 determines a squared version (e.g., x²(n)) of an input signal (e.g., x(n)). In the example of FIG. 5, the delay circuitry 520 generates D₃ delayed versions of the squared envelope of the input signal. For example, the delay circuitry 520 generates the D₃ delayed versions of the squared envelope of the input signal over the range

$$[ \frac{{D}_{3}}{2} - 1 , - \frac{{D}_{3}}{2} ] .$$

Also, the delay circuitry 522 generates D₄ delayed versions of the squared input signal. For example, the delay circuitry 522 generates the D₄ delayed versions of the squared input signal over the range

$$[ \frac{{D}_{4}}{2} - 1 , - \frac{{D}_{4}}{2} ] .$$

In the illustrated example of FIG. 5, each of the multiplexer circuits 524_{L1}-524_{L2-1} selects one of the D₄ delayed versions of the squared input signal based on a programmed value in a respective register associated with each of the multiplexer circuits 524_{L1}-524_{L2-1}. For example, the multiplexer circuit 524_{L1} selects one of the D₄ delayed versions of the squared input signal based on a programmed value in a register associated with the multiplexer circuit 524_{L1}. In the example of FIG. 5, the registers associated with the multiplexer circuits 524_{L1}-524_{L2-1} are programmed at startup of the DPD corrector circuitry 106. For example, the registers associated with the multiplexer circuits 524_{L1}-524_{L2-1} are programmed at startup of the communication system 100 of FIG. 1B. In the example of FIG. 5, each of the multiplexer circuits 524_{L1}-524_{L2-1} provides the respective selected delayed version of the squared input signal to the second input terminals of the multiplier circuits 528_{L1}-528_{L2-1}, respectively.

In the illustrated example of FIG. 5, each of the multiplexer circuits 526_{L2}-526_{M-1} selects one of the D₃ delayed versions of the squared envelope of the input signal based on a programmed value in a respective register associated with each of the multiplexer circuits 526_{L2}-526_{M-1}. For example, the multiplexer circuit 526_{L2} selects one of the D₃ delayed versions of the squared envelope of the input signal based on a programmed value in a register associated with the multiplexer circuit 526_{L2}. In the example of FIG. 5, the registers associated with the multiplexer circuits 526_{L2}-526_{M-1} are programmed at startup of the DPD corrector circuitry 106. For example, the registers associated with the multiplexer circuits 526_{L2}-526_{M-1} are programmed at startup of the communication system 100 of FIG. 1B. In the example of FIG. 5, each of the multiplexer circuits 526_{L2}-526_{M-1} provides the respective selected delayed version of the squared envelope of the input signal to the second input terminals of the multiplier circuits 530_{L2}-530_{M-1}, respectively.

In the illustrated example of FIG. 5, the adder circuitry 532 adds the values from the first portion (e.g., the multiplier circuits 514₀-514_{L1-1}) of the multiplier circuits 514₀-514_{M-1}, the values from the multiplier circuits 528_{L1}-528_{L2-1}, and the values from the multiplier circuits 530_{L2}-530_{M-1}. The adder circuitry 532 also provides the sum to the second input terminal of the adder circuitry 534. The adder circuitry 534 adds the input signal (e.g., x(n+0)) with the value at the output terminal of the adder circuitry 532 and provides the sum at the output terminal of the DPD corrector circuitry 106.

As described above, the DPD corrector circuitry 106 of FIG. 1B is parallelized-by-two. For example, the DPD corrector circuitry 106 can be parallelized-by-two to facilitate operation at a higher sampling rate while also operating at a lower clock rate. Accordingly, another instance of the circuitry of FIG. 5 may be implemented in parallel with the circuitry of FIG. 5 to facilitate such parallelization. That is, the circuitry of FIG. 5 may be duplicated and some of the circuitry of FIG. 5 may be adjusted to implement a parallel instance of the circuitry of FIG. 5. For example, in a parallelized-by-two implementation of the circuitry of FIG. 5, each instance of the delay circuitry 504 generates D₁/2 delayed versions of the envelope of the input signal and the multiplexer circuits 506₀-506_{M-1} in each instance of the circuitry of FIG. 5 receive values from both instances of the delay circuitry 504. Similarly, in a parallelized-by-two implementation of the circuitry of FIG. 5, each instance of the delay circuitry 510 generates D₂/2 delayed versions of the envelope of the input signal and the multiplexer circuits 512₀-512_{M-1} in each instance of the circuitry of FIG. 5 receive values from both instances of the delay circuitry 510. The delay circuitry 520, the delay circuitry 522, the multiplexer circuits 524_{L1}-524_{L2-1}, and the multiplexer circuits 526_{L2}-526_{M-1} can be parallelized similarly. As such, in a first clock cycle of the DPD corrector circuitry 106, a first instance of the circuitry of FIG. 5 processes a first sample of an input signal (e.g., x(n)) in parallel with a second instance of the circuitry of FIG. 5 that processes a second sample of the input signal (e.g., x(n+1)). Additional instances of the circuitry of FIG. 5 may be implemented to support additional parallelization (e.g., three instances of the circuitry of FIG. 5 to support a parallelized-by-three implementation, four instances of the circuitry of FIG. 5 to support a parallelized-by-four implementation, etc.).

In a parallelized-by-two implementation of the DPD corrector circuitry 106, another instance of the LUTs 508₀-508_{M-1} can be implemented in a parallel instance of the circuitry of FIG. 5. Also, the LUTs 508₀-508_{M-1} can be shared between each instance of the circuitry of FIG. 5. For example, the LUTs 508₀-508_{M-1} can be implemented once and accessed by a first instance of the circuitry of FIG. 5 and a second instance of the circuitry of FIG. 5 in the same clock cycle as described further below in connection with FIGS. 12, 13, 14, 15, and 16.

Also, as described above, the non-linearity of PA circuitry can fluctuate based on temperature of the PA circuitry or input signal profile to the PA circuitry. As such, the DPD corrector circuitry 106 includes a spare LUT for each of the LUTs 508₀-508_{M-1} (e.g., main LUTs). For example, the spare LUTs can be updated by the DPD estimator circuitry 124 while the DPD corrector circuitry 106 utilizes the LUTs 508₀-508_{M-1} (e.g., the main LUTs) to perform DPD correction. Then, the DPD corrector circuitry 106 can switch from the LUTs 508₀-508M-1 (e.g., the main LUTs) to the spare LUTs so that the LUTs 508₀-508_{M-1} (e.g., the main LUTs) can be updated with updated values to model PA circuitry non-linearity. After the LUTs 508₀-508_{M-1} (e.g., the main LUTs) have been updated, the DPD corrector circuitry 106 can switch from the spare LUTs to the LUTs 508₀-508_{M-1} (e.g., the main LUTs).

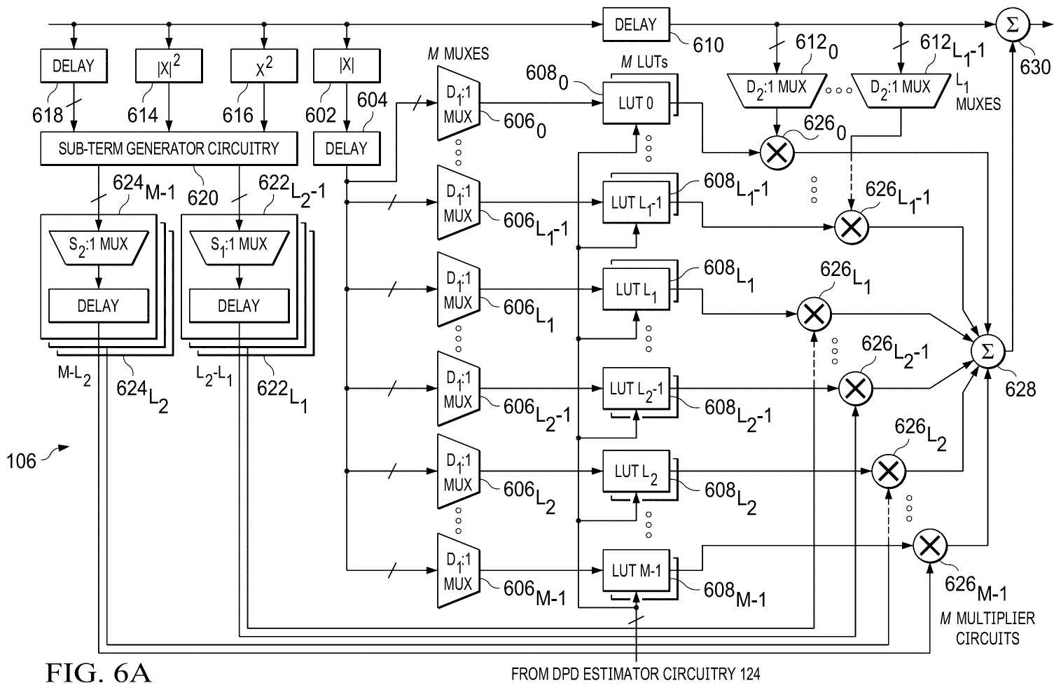

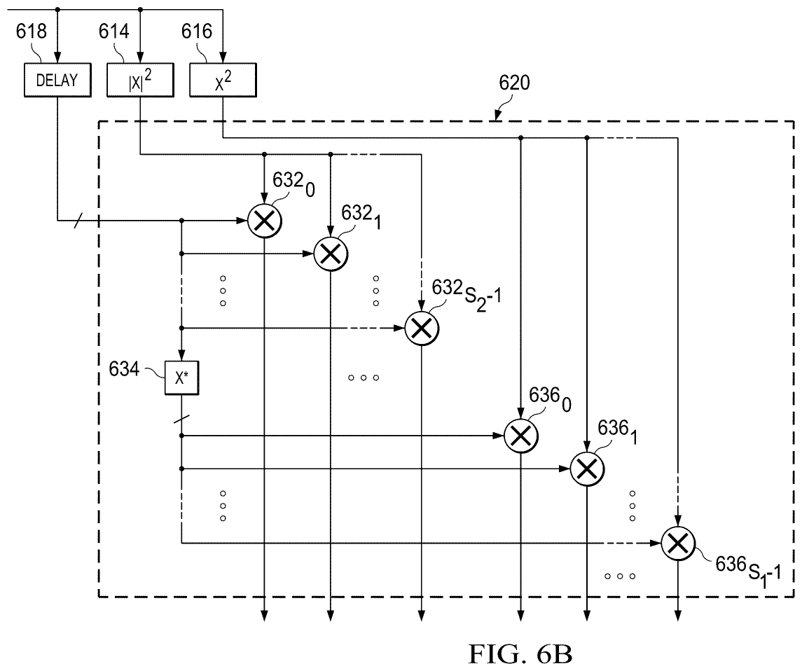

FIG. 6A is a block diagram of a fourth example implementation of the DPD corrector circuitry 106 of FIG. 1B. In the example of FIG. 6A, the DPD corrector circuitry 106 includes example envelope generator circuitry 602, first example delay circuitry 604, first example multiplexer circuits 606₀-606_{M-1}, and example lookup tables (LUTs) 608₀-608_{M-1}, second example delay circuitry 610, and second example multiplexer circuits 612₀-612_{L1-1}. Also, in the example of FIG. 6A, the DPD corrector circuitry 106 includes example squared envelope generator circuitry 614, example squared signal generator circuitry 616, third example delay circuitry 618, example sub-term generator circuitry 620, first example delay and multiplexing circuitry 622_{L1}-622_{L2-1}, second example delay and multiplexing circuitry 624_{L2}-624_{M-1}, example multiplier circuits 626₀-626_{M-1}, first example adder circuitry 628, and second example adder circuitry 630.

In the illustrated example of FIG. 6A, the envelope generator circuitry 602 has an output terminal and an input terminal and the delay circuitry 604 has D₁ output terminals and an input terminal. In the example of FIG. 6A, each of the multiplexer circuits 606₀-606_{M-1} has an output terminal and D₁ input terminals, and each of the LUTs 608₀-608_{M-1} has an output terminal, a first input terminal, and a second input terminal. Also, in the example of FIG. 6A, the delay circuitry 610 has D₂ output terminals and an input terminal and each of the multiplexer circuits 612₀-612_{L1-1} has an output terminal and D₂ input terminals. In the example of FIG. 6A, each of the squared envelope generator circuitry 614 and the squared signal generator circuitry 616 has an output terminal and an input terminal. Also, in the example of FIG. 6A, the delay circuitry 618 has D₃ output terminals and an input terminal.

In the illustrated example of FIG. 6A, the sub-term generator circuitry 620 has S₁ output terminals, S₂ output terminals, a first input terminal, a second input terminal, and D₃ input terminals. In the example of FIG. 6A, each instance of the delay and multiplexing circuitry 622_{L1}-622_{L2-1} has an output terminal and S₁ input terminals. Also, in the example of FIG. 6A, each instance of the delay and multiplexing circuitry 624_{L2}-624_{M-1} has an output terminal and S₂ input terminals. In the example of FIG. 6A, each of the multiplier circuits 626₀-626_{M-1} has an output terminal, a first input terminal, and a second input terminal. Also, in the example of FIG. 6A, the adder circuitry 628 has an output terminal and M input terminals and the adder circuitry 630 has an output terminal, a first input terminal, and a second input terminal.

In the illustrated example of FIG. 6A, the envelope generator circuitry 602 is implemented by digital circuitry. In the example of FIG. 6A, the output terminal of the envelope generator circuitry 602 is coupled to the input terminal of the delay circuitry 604 and the input terminal of the envelope generator circuitry 602 is coupled to the DPD terminal 107 (e.g., is coupled to processor circuitry via the DPD terminal 107 of the pre-DPD interpolator circuitry 104). Also, in the example of FIG. 6A, the delay circuitry 604 is implemented by one or more D flip-flop circuits. In some examples, the delay circuitry 604 is implemented by one or more FIFO queues. In the example of FIG. 6A, the D₁ output terminals of the delay circuitry 604 are coupled to the D₁ input terminals of each of the multiplexer circuits 606₀-606_{M-1} and the input terminal of the delay circuitry 604 is coupled to the output terminal of the envelope generator circuitry 602.

In the illustrated example of FIG. 6A, each of the multiplexer circuits 606₀-606_{M-1} is implemented by digital circuitry. In the example of FIG. 6A, the D₁ input terminals of each of the multiplexer circuits 606₀-606_{M-1} are coupled to the D₁ output terminals of the delay circuitry 604. Also, the output terminals of the multiplexer circuits 606₀-606_{M-1} are coupled to the first input terminals of the LUTs 608₀-608_{M-1}, respectively. For example, the output terminal of the multiplexer circuit 606₀ is coupled to the first input terminal of the LUT 608₀.

In the illustrated example of FIG. 6A, each of the LUTs 608₀-608_{M-1} is implemented by digital circuitry and at least one memory. For example, each of the LUTs 608₀-608_{M-1} is implemented by digital circuitry and one memory. In some examples, each of the LUTs 608₀-608_{M-1} is implemented by digital circuitry and two memories as described further below in connection with FIGS. 12, 13, 14, 15, and 16. In the example of FIG. 6A, each of the LUTs 608₀-608_{M-1} stores 512 entries of 32 bits of data (e.g., each of the LUTs 608₀-608_{M-1} has 512 rows and each row is 32 bits wide). Also, in the example of FIG. 6A, the first input terminals of the LUTs 608₀-608_{M-1} are coupled to the output terminals of the multiplexer circuits 606₀-606_{M-1}, respectively. In the example of FIG. 6A, the second input terminal of each of the LUTs 608₀-608_{M-1} is coupled to the output terminal of the DPD estimator circuitry 124.

In the illustrated example of FIG. 6A, the output terminals of the LUTs 608₀-608_{M-1} are coupled to the first input terminals of the multiplier circuits 626₀-626_{M-1}, respectively. For example, the output terminals of a first portion (e.g., the LUTs 608₀-608_{L2-1}) of the LUTs 608₀-608_{M-1} are coupled to the first input terminals of a first portion (e.g., the multiplier circuits 626₀-626_{L1-1}) of the multiplier circuits 626₀-626_{M-1}, respectively. Also, for example, the output terminals of a second portion (e.g., the LUTs 608_{L1}-608_{L2-1}) of the LUTs 608₀-608_{M-1} are coupled to the first input terminals of a second portion (e.g., the multiplier circuits 626_{L1}-626_{L2-1}) of the multiplier circuits 626₀-626_{M-1}, respectively. Also, for example, the output terminals of a third portion (e.g., the LUTs 608_{L2}-608_{M-1}) of the LUTs 608₀-608_{M-1} are coupled to the first input terminals of a third portion (e.g., the multiplier circuits 626_{L2}-626_{M-1}) of the multiplier circuits 626₀-626_{M-1}, respectively.

In the illustrated example of FIG. 6A, the delay circuitry 610 is implemented by one or more D flip-flop circuits. In some examples, the delay circuitry 610 is implemented by one or more FIFO queues. In the example of FIG. 6A, the D₂ output terminals of the delay circuitry 610 are coupled to the D₂ input terminals of each of the multiplexer circuits 612₀-612_{L1-1} and the input terminal of the delay circuitry 610 is coupled to the DPD terminal 107 (e.g., is coupled to processor circuitry via the DPD terminal 107 of the pre-DPD interpolator circuitry 104). Also, one of the D₂ output terminals of the delay circuitry 610 is coupled to the first input terminal of the adder circuitry 630.

In the illustrated example of FIG. 6A, each of the multiplexer circuits 612₀-612_{L1-1} is implemented by digital circuitry. In the example of FIG. 6A, the output terminals of the multiplexer circuits 612₀-612_{L1-1} are coupled to the second input terminals of the first portion (e.g., the multiplier circuits 626₀-626_{L1-1}) of the multiplier circuits 626₀-626_{M-1}, respectively. Also, in the example of FIG. 6A, the D₂ input terminals of each of the multiplexer circuits 612₀-612_{L1-1} are coupled to the D₂ output terminals of the delay circuitry 610. In the example of FIG. 6A, the squared envelope generator circuitry 614 is implemented by digital circuitry. Also, in the example of FIG. 6A, the output terminal of the squared envelope generator circuitry 614 is coupled to the first input terminal of the sub-term generator circuitry 620 and the input terminal of the squared envelope generator circuitry 614 is coupled to the DPD terminal 107 (e.g., is coupled to processor circuitry via the DPD terminal 107 of the pre-DPD interpolator circuitry 104). In the example of FIG. 6A, the squared signal generator circuitry 616 is implemented by digital circuitry. Also, the output terminal of the squared signal generator circuitry 616 is coupled to the second input terminal of the sub-term generator circuitry 620 and the input terminal of the squared signal generator circuitry 616 is coupled to the DPD terminal 107 (e.g., is coupled to processor circuitry via the DPD terminal 107 of the pre-DPD interpolator circuitry 104).

In the illustrated example of FIG. 6A, the delay circuitry 618 is implemented by one or more D flip-flop circuits. In some examples, the delay circuitry 618 is implemented by one or more FIFO queues. In the example of FIG. 6A, the D₃ output terminals of the delay circuitry 618 are coupled to the D₃ input terminals of the sub-term generator circuitry 620, respectively, and the input terminal of the delay circuitry 618 is coupled to the DPD terminal 107 (e.g., is coupled to processor circuitry via the DPD terminal 107 of the pre-DPD interpolator circuitry 104). In some examples, the delay circuitry 618 is implemented at the output terminal of the squared envelope generator circuitry 614 and the output terminal of the squared signal generator circuitry 616. For example, a first instance of the delay circuitry 618 is implemented at the output terminal of the squared envelope generator circuitry 614 and a second instance of the delay circuitry 618 is implemented at the output terminal of the squared signal generator circuitry 616. In such examples, the D₃ input terminals of the sub-term generator circuitry 620 are coupled to the DPD terminal 107 (e.g., is coupled to processor circuitry via the DPD terminal 107 of the pre-DPD interpolator circuitry 104).

In the illustrated example of FIG. 6A, the sub-term generator circuitry 620 is implemented by two or more multiplier circuits as described further herein. In the example of FIG. 6A, the S₁ output terminals of the sub-term generator circuitry 620 are coupled to the S₁ input terminals of each instance of the delay and multiplexing circuitry 622_{L1}-622_{L2-1} and the S₂ output terminals of the sub-term generator circuitry 620 are coupled to the S₂ input terminals of each instance of the delay and multiplexing circuitry 624_{L2}-624_{M-1}. Also, in the example of FIG. 6A, the first input terminal of the sub-term generator circuitry 620 is coupled to the output terminal of the squared envelope generator circuitry 614, the second input terminal of the sub-term generator circuitry 620 is coupled to the output terminal of the squared signal generator circuitry 616, and the D₃ input terminals of the sub-term generator circuitry 620 are coupled to the D₃ output terminals of the delay circuitry 618, respectively.

In the illustrated example of FIG. 6A, each instance of the delay and multiplexing circuitry 622_{L1}-622_{L2-1} is implemented by a multiplexer circuit having an output terminal and S₁ input terminals and delay circuitry having an output terminal and an input terminal. For example, the output terminal of the multiplexer circuit is coupled to the input terminal of the delay circuitry and the S₁ input terminals of the multiplexer circuit are coupled to the S₁ output terminals of the sub-term generator circuitry 620. Also, the output terminal of the delay circuitry is coupled to the second input terminal of a corresponding one of the second portion (e.g., the multiplier circuits 626_{L1}-626_{L2-1}) of the multiplier circuits 626₀-626_{M-1} and the input terminal of the delay circuitry is coupled to the output terminal of the multiplexer circuit. For example, the output terminal of the delay circuitry of the delay and multiplexing circuitry 622_{L2-1} is coupled to the second input terminal of the multiplier circuit 626_{L2-1} and the input terminal of the delay circuitry is coupled to the output terminal of the multiplexer circuit of the delay and multiplexing circuitry 622_{L2-1}.

In the illustrated example of FIG. 6A, each instance of the delay and multiplexing circuitry 624_{L2}-624_{M-1} is implemented by a multiplexer circuit having an output terminal and S₂ input terminals and delay circuitry having an output terminal and an input terminal. For example, the output terminal of the multiplexer circuit is coupled to the input terminal of the delay circuitry and the S₂ input terminals of the multiplexer circuit are coupled to the S₂ output terminals of the sub-term generator circuitry 620. Also, the output terminal of the delay circuitry is coupled to the second input terminal of a corresponding one of the third portion (e.g., the multiplier circuits 626_{L2}-626_{M-1}) of the multiplier circuits 626₀-626_{M-1} and the input terminal of the delay circuitry is coupled to the output terminal of the multiplexer circuit. For example, the output terminal of the delay circuitry of the delay and multiplexing circuitry 624_{M-1} is coupled to the second input terminal of the multiplier circuit 626_{M-1} and the input terminal of the delay circuitry is coupled to the output terminal of the multiplexer circuit of the delay and multiplexing circuitry 624_{M-1}.

In the illustrated example of FIG. 6A, each of the multiplier circuits 626₀-626_{M-1} is implemented by digital circuitry. In the example of FIG. 6A, the output terminals of the first portion (e.g., the multiplier circuits 626₀-626_{L1-1}) of the multiplier circuits 626₀-626_{M-1} are coupled to a first portion of the M input terminals of the adder circuitry 628, respectively. Also, the first input terminals of the first portion (e.g., the multiplier circuits 626₀-626_{L1-1}) of the multiplier circuits 626₀-626_{M-1} are coupled to the output terminals of the first portion (e.g., the LUTs 608₀-608_{L1-1}) of the LUTs 608₀-608_{M-1}, respectively. In the example of FIG. 6A, the second input terminals of the first portion (e.g., the multiplier circuits 626₀-626_{L1-1}) of the multiplier circuits 626₀-626_{M-1} are coupled to the output terminals of the multiplexer circuits 612₀-612_{L1-1}, respectively.

In the illustrated example of FIG. 6A, the output terminals of the second portion (e.g., the multiplier circuits 626_{L1}-626_{L2-1}) of the multiplier circuits 626₀-626_{M-1} are coupled to a second portion of the M input terminals of the adder circuitry 628, respectively. In the example of FIG. 6A, the first input terminals of the second portion (e.g., the multiplier circuits 626_{L1}-626_{L2-1}) of the multiplier circuits 626₀-626_{M-1} are coupled to the output terminals of the second portion (e.g., the LUTs 608_{L1}-608_{L2-1}) of the LUTs 608₀-608_{M-1}, respectively. Also, in the example of FIG. 6A, the second input terminals of the second portion (e.g., the multiplier circuits 626_{L1}-626_{L2-1}) of the multiplier circuits 626₀-626_{M-1} are coupled to the output terminals of the delay and multiplexing circuitry 622_{L1}-622_{L2-1}, respectively.

In the illustrated example of FIG. 6A, the output terminals of the third portion (e.g., the multiplier circuits 626_{L2}-626_{M-1}) of the multiplier circuits 626₀-626_{M-1} are coupled to a third portion of the M input terminals of the adder circuitry 628, respectively. In the example of FIG. 6A, the first input terminals of the third portion (e.g., the multiplier circuits 626_{L2}-626_{M-1}) of the multiplier circuits 626₀-626_{M-1} are coupled to the output terminals of the third portion (e.g., the LUTs 608_{L2}-608_{M-1}) of the LUTs 608₀-608_{M-1}, respectively. Also, in the example of FIG. 6A, the second input terminals of the third portion (e.g., the multiplier circuits 626_{L2}-626_{M-1}) of the multiplier circuits 626₀-626_{M-1} are coupled to the output terminals of the delay and multiplexing circuitry 624_{L2}-624_{M-1}, respectively.

In the illustrated example of FIG. 6A, each of the adder circuitry 628 and the adder circuitry 630 is implemented by one or more adder circuits (e.g., one or more half adder circuits, one or more full adder circuits, one or more ripple-carry adder circuits, one or more carry-lookahead adder circuits, etc.). In the example of FIG. 6A, the output terminal of the adder circuitry 628 is coupled to the second input terminal of the adder circuitry 630. Also, in the example of FIG. 6A, a first portion of the M input terminals of the adder circuitry 628 are coupled to the output terminals of the first portion (e.g., the multiplier circuits 626₀-626_{L1-1}) of the multiplier circuits 626₀-626_{M-1}, respectively. In the example of FIG. 6A, a second portion of the M input terminals of the adder circuitry 628 are coupled to the output terminals of the second portion (e.g., the multiplier circuits 626_{L1}-626_{L2-1}) of the multiplier circuits 626₀-626_{M-1}, respectively. Also, a third portion of the M input terminals of the adder circuitry 628 are coupled to the output terminals of the third portion (e.g., the multiplier circuits 626_{L2}-626_{M-1}) of the multiplier circuits 626₀-626_{M-1}, respectively. In the example of FIG. 6A, the output terminal of the adder circuitry 630 is coupled to power amplifier circuitry (e.g., the PA circuitry 114 of FIG. 1B via the transmitter circuitry 108, the transmitter DAC circuit 110, and the DSA circuitry 112) and the third input terminal of the DPD estimator circuitry 124. Also, in the example of FIG. 6A, the first input terminal of the adder circuitry 630 is coupled to one of the D₂ output terminals of the delay circuitry 610 and the second input terminal of the adder circuitry 630 is coupled to the output terminal of the adder circuitry 628.

In the illustrated example of FIG. 6A, the DPD corrector circuitry 106 implements Equation 2 described above. By implementing the DPD model of Equation 2, the DPD corrector circuitry 106 improves pre-distortion modeling accuracy at higher bandwidths (e.g., greater than 100 MHZ). In the example of FIG. 6A, the envelope generator circuitry 602 determines an envelope (e.g., |x(n)|) of an input signal (e.g., x(n)). For example, the envelope generator circuitry 602 determines an envelope of an input signal as described above (e.g., |x(n)|={square root over (Re(x(n))²+Im(x(n))²))}. In the example of FIG. 6A, the delay circuitry 604 generates D₁ delayed versions of the envelope of the input signal. For example, the delay circuitry 604 generates the D₁ delayed versions of the envelope of the input signal over the range

$$[ \frac{{D}_{1}}{2} - 1 , - \frac{{D}_{1}}{2} ] .$$

In the illustrated example of FIG. 6A, each of the multiplexer circuits 606₀-606_{M-1} selects one of the D₁ delayed versions of the envelope of the input signal based on a programmed value in a respective register associated with each of the multiplexer circuits 606₀-606_{M-1}. For example, the multiplexer circuit 606₀ selects one of the D₁ delayed versions of the envelope of the input signal based on a programmed value in a register associated with the multiplexer circuit 606₀. In the example of FIG. 6A, the registers associated with the multiplexer circuits 606₀-606_{M-1} are programmed at startup of the DPD corrector circuitry 106. For example, the registers associated with the multiplexer circuits 606₀-606_{M-1} are programmed at startup of the communication system 100 of FIG. 1B. In the example of FIG. 6A, the selected delayed versions of the envelope of the input signal that are output from the multiplexer circuits 606₀-606_{M-1} index the LUTs 608₀-608_{M-1}, respectively. The LUTs 608₀-608_{M-1} output values to the multiplier circuits 626₀-626_{M-1} based on the respective indices.

In the illustrated example of FIG. 6A, the delay circuitry 610 generates D₂ delayed versions of the input signal. For example, the delay circuitry 610 generates the D₂ delayed versions of the input signal over the range

$$[ \frac{{D}_{2}}{2} - 1 , - \frac{{D}_{2}}{2} ] .$$

Also, the delay circuitry 610 provides the input signal (e.g., x(n+0)) to the first input terminal of the adder circuitry 630. In the example of FIG. 6A, each of the multiplexer circuits 612₀-612_{L1-1} selects one of the D₂ delayed versions of the input signal based on a programmed value in a respective register associated with each of the multiplexer circuits 612₀-612_{L1-1}. For example, the multiplexer 612₀ selects one of the D₂ delayed versions of the input signal based on a programmed value in a register associated with the multiplexer 612₀. In the example of FIG. 6A, the registers associated with the multiplexer circuits 612₀-612_{L1-1} are programmed at startup of the DPD corrector circuitry 106. For example, the registers associated with the multiplexer circuits 612₀-612_{L1-1} are programmed at startup of the communication system 100 of FIG. 1B. In the example of FIG. 6A, each of the multiplexer circuits 612₀-612_{L1-1} provides one of the D₂ delayed versions of the input signal to the second input terminals of the first portion (e.g., the multiplier circuits 626₀-626_{L1-1}) of the multiplier circuits 626₀-626_{M-1}, respectively.

In the illustrated example of FIG. 6A, the squared envelope generator circuitry 614 determines a squared envelope (e.g., |x(n)|²) of an input signal (e.g., x(n)). For example, the squared envelope generator circuitry 614 determines a squared envelope of an input signal by computing the sum of the squared real and squared imaginary components of x(n) (e.g., |x(n)|²=Re(x(n))²+Im(x(n))²). Also, the squared signal generator circuitry 616 determines a squared version (e.g., x²(n)) of an input signal (e.g., x(n)). In the example of FIG. 6A, the delay circuitry 618 generates D₃ delayed versions of the input signal. For example, the delay circuitry 618 generates the D₃ delayed versions of the input signal over the range

$$[ \frac{{D}_{3}}{2} - 1 , - \frac{{D}_{3}}{2} ] .$$

In the illustrated example of FIG. 6A, the sub-term generator circuitry 620 generates sub-terms for Equation 2. For example, the sub-term generator circuitry 620 generates sub-terms by (1) multiplying the squared input signal by the conjugate of one or more delayed versions of the input signal and (2) multiplying the squared envelope of the input signal by one or more delayed versions of the input signal. In the example of FIG. 6A, the sub-term generator circuitry 620 generates sub-terms for unique relative delays (e.g., l₁(k)−l₃(k)) of Equation 2. At least one of (1) one or more instances of the delay and multiplexing circuitry 622_{L1}-622_{L2-1} or (2) one or more instances of the delay and multiplexing circuitry 624_{L2}-624_{M-1} can be programmed at startup of the DPD corrector circuitry 106 to add an individual delay to the sub-terms determined by the sub-term generator circuitry 620. For example, M-L₁ registers associated with respective instances of the delay and multiplexing circuitry 622_{L1}-622_{L2-1} and the delay and multiplexing circuitry 624_{L2}-624_{M-1} can be programmed at startup of the DPD corrector circuitry 106 to configure the delays of each instance of the delay and multiplexing circuitry 622_{L1}-622_{L2-1} and the delay and multiplexing circuitry 624_{L2}-624_{M-1} based on at least one of the l₁(k) delay or the l₃(k) delay to be applied to the sub-terms according to Equation 2 above.

In the illustrated example of FIG. 6A, the multiplexer circuit of each instance of the delay and multiplexing circuitry 622_{L1}-622_{L2-1} selects one of the S₁ signals output by the sub-term generator circuitry 620 based on a programmed value in a respective register associated with the multiplexer circuit of each instance of the delay and multiplexing circuitry 622_{L1}-622_{L2-1}. For example, the multiplexer circuit of the delay and multiplexing circuitry 622_{L2-1} selects one of the S₁ signals based on a programmed value in a register associated with the delay and multiplexing circuitry 622_{L2-1}. In the example of FIG. 6A, the respective registers associated with the multiplexer circuit of each instance of the delay and multiplexing circuitry 622_{L1}-622_{L2-1} are programmed at startup of the DPD corrector circuitry 106. For example, the respective registers associated with the multiplexer circuit of each instance of the delay and multiplexing circuitry 622_{L1}-622_{L2-1} are programmed at startup of the communication system 100 of FIG. 1B. In the example of FIG. 6A, the multiplexer circuit of each instance of the delay and multiplexing circuitry 622_{L1}-622_{L2-1} provides the respective selected signal to the input terminals of the delay circuitry of the corresponding instance of the delay and multiplexing circuitry 622_{L1}-622_{L2-1}. As described above, delay circuitry of each the delay and multiplexing circuitry 622_{L1}-622_{L2-1} applies a delay based on a programmed value and provides the delayed version of the signal to the second portion (e.g., the multiplier circuits 626_{L1}-626_{L2-1}) of the multiplier circuits 626₀-626_{M-1}, respectively, based on at least one of the l₁(k) delay or the l₃(k) delay to be applied to the sub-terms according to Equation 2 above.

In the illustrated example of FIG. 6A, the multiplexer circuit of each instance of the delay and multiplexing circuitry 624_{L2}-624_{M-1} selects one of the S₂ signals output by the sub-term generator circuitry 620 based on a programmed value in a respective register associated with the multiplexer circuit of each instance of the delay and multiplexing circuitry 624_{L2}-624_{M-1}. For example, the multiplexer circuit of the delay and multiplexing circuitry 624_{M-1} selects one of the S₂ signals based on a programmed value in a register associated with the delay and multiplexing circuitry 624_{M-1}. In the example of FIG. 6A, the respective registers associated with the multiplexer circuit of each instance of the delay and multiplexing circuitry 624_{L2}-624_{M-1} are programmed at startup of the DPD corrector circuitry 106. For example, the respective registers associated with the multiplexer circuit of each instance of the delay and multiplexing circuitry 624_{L2}-624_{M-1} are programmed at startup of the communication system 100 of FIG. 1B. In the example of FIG. 6A, the multiplexer circuit of each instance of the delay and multiplexing circuitry 624_{L2}-624_{M-1} provides the respective selected signal to the input terminals of the delay circuitry of the corresponding instance of the delay and multiplexing circuitry 624_{L2}-624_{M-1}. As described above, delay circuitry of each the delay and multiplexing circuitry 624_{L2}-624_{M-1} applies a delay based on a programmed value and provides the delayed version of the signal to the third portion (e.g., the multiplier circuits 626_{L2}-626_{M-1}) of the multiplier circuits 626₀-626_{M-1}, respectively, based on at least one of the l₁(k) delay or the l₃(k) delay to be applied to the sub-terms according to Equation 2 above.

In the illustrated example of FIG. 6A, by generating sub-terms outside of the signal path of the values output from the LUTs 608₀-608_{M-1}, the sub-term generator circuitry 620 reduces the number of multiplier circuits to implement Equation 2. For example, generating sub-terms in the signal path of the values output from the LUTs 608₀-608_{M-1} would require more than M-L₁ extra multiplier circuits. In the example of FIG. 6A, the sub-term generator circuitry 620 can generate sub-terms with 9 multiplier circuits for a relative delay range of [2, −2], which would be less multiplier circuits than the M-L₁ multiplier circuits.

In the illustrated example of FIG. 6A, the first portion (e.g., the multiplier circuits 626₀-626_{L1-1}) of the multiplier circuits 626₀-626_{M-1} multiplies the values output from the first portion (e.g., the LUTs 608₀-608_{L1-1}) of the LUTs 608₀-608_{M-1} by the values output from the multiplexer circuits 612₀-612_{L1-1}, respectively. Also, the first portion (e.g., the multiplier circuits 626₀-626_{L1-1}) of the multiplier circuits 626₀-626_{M-1} provides the products to the first portion of the M input terminals of the adder circuitry 628. In the example of FIG. 6A, the second portion (e.g., the multiplier circuits 626_{L1}-626_{L2-1}) of the multiplier circuits 626₀-626_{M-1} multiplies the values output from the second portion (e.g., the LUTs 608_{L1}-608_{L2-1}) of the LUTs 608₀-608_{M-1} by the values output from the delay and multiplexing circuitry 622_{L1}-622_{L2-1}, respectively. Also, the second portion (e.g., the multiplier circuits 626_{L1}-626_{L2-1}) of the multiplier circuits 626₀-626_{M-1} provides the products to the second portion of the M input terminals of the adder circuitry 628. In the example of FIG. 6A, the third portion (e.g., the multiplier circuits 626_{L2}-626_{M-1}) of the multiplier circuits 626₀-626_{M-1} multiplies the values output from the third portion (e.g., the LUTs 608_{L2}-608_{M-1}) of the LUTs 608₀-608_{M-1} by the values output from the delay and multiplexing circuitry 624_{L2}-624_{M-1}, respectively. Also, the third portion (e.g., the multiplier circuits 626_{L2}-626_{M-1}) of the multiplier circuits 626₀-626_{M-1} provides the products to the third portion of the M input terminals of the adder circuitry 628.

In the illustrated example of FIG. 6A, the adder circuitry 628 adds the values from the first portion (e.g., the multiplier circuits 626₀-626_{L1-1}) of the multiplier circuits 626₀-626_{M-1}, the values from the second portion (e.g., the multiplier circuits 626_{L1}-626_{L2-1}) of the multiplier circuits 626₀-626_{M-1}, and the values from the third portion (e.g., the multiplier circuits 626_{L2}-626_{M-1}) of the multiplier circuits 626₀-626_{M-1}. The adder circuitry 628 also provides the sum to the second input terminal of the adder circuitry 630. The adder circuitry 630 adds the input signal (e.g., x(n+0)) with the value at the output terminal of the adder circuitry 628 and provides the sum at the output terminal of the DPD corrector circuitry 106.

As described above, the DPD corrector circuitry 106 of FIG. 1B is parallelized-by-two. For example, the DPD corrector circuitry 106 can be parallelized-by-two to facilitate operation at a higher sampling rate while also operating at a lower clock rate. Accordingly, another instance of the circuitry of FIG. 6A may be implemented in parallel with the circuitry of FIG. 6A to facilitate such parallelization. That is, the circuitry of FIG. 6A may be duplicated and some of the circuitry of FIG. 6A may be adjusted to implement a parallel instance of the circuitry of FIG. 6A. For example, in a parallelized-by-two implementation of the circuitry of FIG. 6A, each instance of the delay circuitry 604 generates D₁/2 delayed versions of the envelope of the input signal and the multiplexer circuits 606₀-606_{M-1} in each instance of the circuitry of FIG. 6A receive values from both instances of the delay circuitry 604. Similarly, in a parallelized-by-two implementation of the circuitry of FIG. 6A, each instance of the delay circuitry 610 generates D₂/2 delayed versions of the envelope of the input signal and the multiplexer circuits 612₀-612_{L1-1} in each instance of the circuitry of FIG. 6A receive values from both instances of the delay circuitry 610. The delay circuitry 618, the delay and multiplexing circuitry 622_{L1}-622_{L2-1}, and the delay and multiplexing circuitry 624_{L2}-624_{M-1} can be parallelized similarly. As such, in a first clock cycle of the DPD corrector circuitry 106, a first instance of the circuitry of FIG. 6A processes a first sample of an input signal (e.g., x(n)) in parallel with a second instance of the circuitry of FIG. 6A that processes a second sample of the input signal (e.g., x(n+1)). Additional instances of the circuitry of FIG. 6A may be implemented to support additional parallelization (e.g., three instances of the circuitry of FIG. 6A to support a parallelized-by-three implementation, four instances of the circuitry of FIG. 6A to support a parallelized-by-four implementation, etc.).

In a parallelized-by-two implementation of the DPD corrector circuitry 106, another instance of the LUTs 608₀-608_{M-1} can be implemented in a parallel instance of the circuitry of FIG. 6A. Also, the LUTs 608₀-608_{M-1} can be shared between each instance of the circuitry of FIG. 6A. For example, the LUTs 608₀-608_{M-1} can be implemented once and accessed by a first instance of the circuitry of FIG. 6A and a second instance of the circuitry of FIG. 6A in the same clock cycle as described further below in connection with FIGS. 12, 13, 14, 15, and 16.

Also, as described above, the non-linearity of PA circuitry can fluctuate based on temperature of the PA circuitry or input signal profile to the PA circuitry. As such, the DPD corrector circuitry 106 includes a spare LUT for each of the LUTs 608₀-608_{M-1} (e.g., main LUTs). For example, the spare LUTs can be updated by the DPD estimator circuitry 124 while the DPD corrector circuitry 106 utilizes the LUTs 608₀-608_{M-1} (e.g., the main LUTs) to perform DPD correction. Then, the DPD corrector circuitry 106 can switch from the LUTs 608₀-608M-1 (e.g., the main LUTs) to the spare LUTs so that the LUTs 608₀-608_{M-1} (e.g., the main LUTs) can be updated with updated values to model PA circuitry non-linearity. After the LUTs 608₀-608_{M-1} (e.g., the main LUTs) have been updated, the DPD corrector circuitry 106 can switch from the spare LUTs to the LUTs 608₀-608_{M-1} (e.g., the main LUTs).

FIG. 6B is a block diagram of an example implementation of the sub-term generator circuitry 620 of FIG. 6A. In the example of FIG. 6B, the sub-term generator circuitry 620 includes first example multiplier circuits 632₀-632_{S2-1}, conjugate generator circuitry 634, and second example multiplier circuits 636₀-636_{S1-1}. In the example of FIG. 6B, each of the multiplier circuits 632₀-632_{S2-1} and the multiplier circuits 636₀-636_{S1-1} has an output terminal, a first input terminal, and an output terminal. Also, in the example of FIG. 6B, the conjugate generator circuitry 634 includes D₃ output terminals and D₃ input terminals.

In the illustrated example of FIG. 6B, each of the multiplier circuits 632₀-632_{S2-1} is implemented by digital circuitry. In the example of FIG. 6B, the output terminals of the multiplier circuits 632₀-632_{S2-1} are coupled to the S₂ input terminals of each instance of the delay and multiplexing circuitry 624_{L2}-624_{M-1}. Also, the first input terminals of the multiplier circuits 632₀-632_{S2-1} are coupled to the D₃ output terminals of the delay circuitry 618, respectively. In the example of FIG. 6B, the second input terminals of the multiplier circuits 632₀-632_{S2-1} are coupled to the output terminal of the squared envelope generator circuitry 614.

In the illustrated example of FIG. 6B, the conjugate generator circuitry 634 is implemented by digital circuitry. In the example of FIG. 6B, the D₃ output terminals of the conjugate generator circuitry 634 are coupled to the first input terminals of the multiplier circuits 636₀-636_{S1-1}, respectively. Also, the D₃ input terminals of the conjugate generator circuitry 634 are coupled to the D₃ output terminals of the delay circuitry 618. In the example of FIG. 6B, the output terminals of the multiplier circuits 636₀-636_{S1-1} are coupled to the S₁ input terminals of each instance of the delay and multiplexing circuitry 622_{L1}-622_{L2-1}. Also, the first input terminals of the multiplier circuits 636₀-636_{S1-1} are coupled to the D₃ output terminals of the conjugate generator circuitry 634, respectively. In the example of FIG. 6B, the second input terminals of the multiplier circuits 636₀-636_{S1-1} are coupled to the output terminal of the squared signal generator circuitry 616.

As described above, the sub-term generator circuitry 620 generates sub-terms for Equation 2. For example, the sub-term generator circuitry 620 generates sub-terms according to Equations 3 and 4 below.

$$Sub - {Term}_{1} = {x}^{*} ( n - ( {l}_{1} ( k ) - {l}_{3} ( k ) ) ) * {x}^{2} ( n ) \qquad Equation 3$$

$$Sub - {Term}_{2} = x ( n - ( {l}_{1} ( k ) - {l}_{3} ( k ) ) ) * {\vert x ( n ) \vert}^{2} \qquad Equation 4$$

In examples described herein, the sub-term generator circuitry 620 generates sub-terms for unique relative delays (e.g., l₁(k)−l₃(k)). By generating sub-terms for unique relative delays and outside of the signal path of the values output from the LUTs 608₀-608_{M-1}, the sub-term generator circuitry 620 reduces the number of multiplier circuits to implement Equation 2. For example, generating sub-terms for all delays and in the signal path of the values output from the LUTs 608₀-608_{M-1} would require more than M-L₁ extra multiplier circuits. In the example of FIGS. 6A and 6B, the sub-term generator circuitry 620 can generate sub-terms with 9 multiplier circuits for a relative delay range of [2, −2], which would be less multiplier circuits than the M-L₁ multiplier circuits.

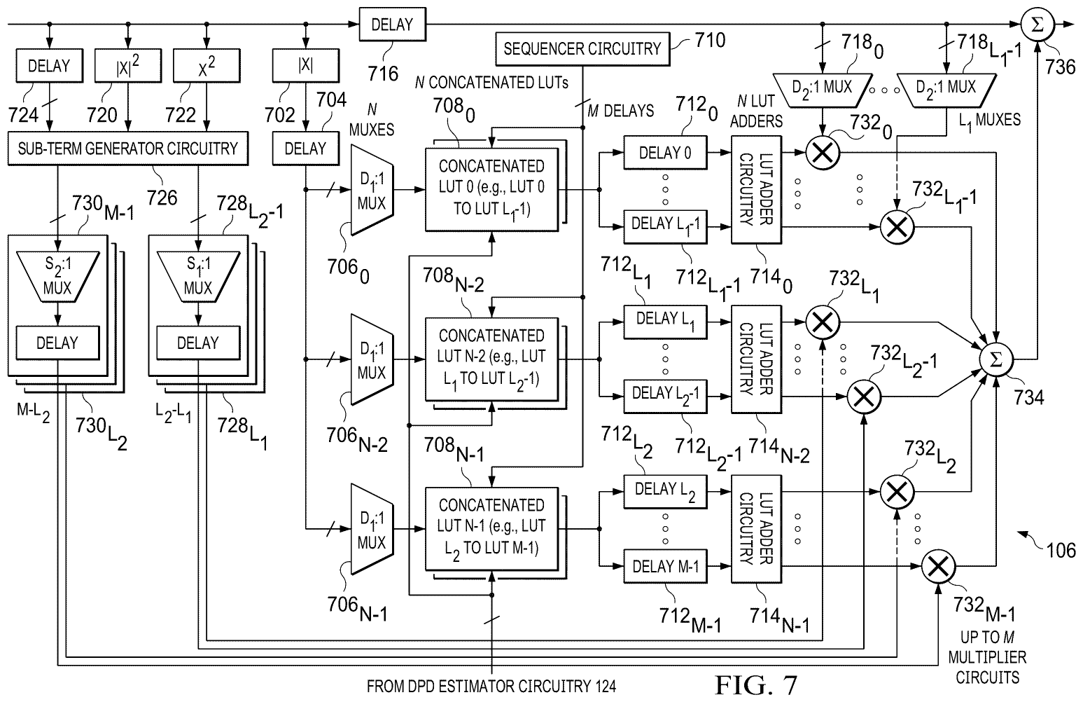

FIG. 7 is a block diagram of a fifth example implementation of the DPD corrector circuitry 106 of FIG. 1B. In the example of FIG. 7, the DPD corrector circuitry 106 includes example envelope generator circuitry 702, first example delay circuitry 704, first example multiplexer circuits 706₀-706_{N-1}, example concatenated lookup tables (LUTs) 708₀-708_{N-1}, example sequencer circuitry 710, second example delay circuitry 712₀-712_{M-1}, and example lookup table (LUT) adder circuitry 714₀-714_{N-1}. In the example of FIG. 7, the DPD corrector circuitry 106 also includes third example delay circuitry 716, second example multiplexer circuits 718₀-718_{L1-1}. Also, in the example of FIG. 7, the DPD corrector circuitry 106 includes example squared envelope generator circuitry 720, example squared signal generator circuitry 722, third example delay circuitry 724, example sub-term generator circuitry 726, first example delay and multiplexing circuitry 728_{L1}-728_{L2-1}, second example delay and multiplexing circuitry 730_{L2}-730_{M-1}, example multiplier circuits 732₀-732_{M-1}, first example adder circuitry 734, and second example adder circuitry 736.

In the illustrated example of FIG. 7, the envelope generator circuitry 702 has an output terminal and an input terminal and the delay circuitry 704 has D₁ output terminals and an input terminal. In the example of FIG. 7, each of the multiplexer circuits 706₀-706_{N-1} has an output terminal and D₁ input terminals. Also, in the example of FIG. 7, each of the concatenated LUTs 708₀-708_{N-1} has one or more output terminals depending on the number of sub-LUTs represented by each of the concatenated LUTs 708₀-708_{N-1}. For example, as the concatenated LUT 708₀ represents L₁ sub-LUTs, the concatenated LUT 708₀ has L₁ output terminals. Also, as the concatenated LUT 708_{N-2} represents L₂-L₁ sub-LUTs, the concatenated LUT 708₀ has L₂-L₁ output terminals. In the example of FIG. 7, as the concatenated LUT 708_{N-1} represents M-L₂ sub-LUTs, the concatenated LUT 708₀ has M-L₂ output terminals. Also, each of the concatenated LUTs 708₀-708_{N-1} has a first input terminal, a second input terminal, and a third input terminal.

In the illustrated example of FIG. 7, the sequencer circuitry 710 has N output terminals and each instance of the delay circuitry 712₀-712_{M-1} has an output terminal and an input terminal. In the example of FIG. 7, each instance of the LUT adder circuitry 714₀-714_{N-1} has one or more output terminals and one or more input terminals depending on the number of sub-LUTs represented by each of the concatenated LUTs 708₀-708_{N-1}. For example, as the concatenated LUT 708₀ represents L₁ sub-LUTs, the LUT adder circuitry 714₀ has up to 1.1 output terminals and L₁ input terminals. Also, as the concatenated LUT 708_{N-2} represents L₂-L₁ sub-LUTs, the LUT adder circuitry 714_{N-2} has up to L₂-L₁ output terminals and L₂-L₁ input terminals. In the example of FIG. 7, as the concatenated LUT 708_{N-1} represents M-L₂ sub-LUTs, the LUT adder circuitry 714_{N-1} has up to M-L₂ output terminals and M-L₂ input terminals. Also, in the example of FIG. 7, the delay circuitry 716 has D₂ output terminals and an input terminal and each of the multiplexer circuits 718₀-718_{L-1} has an output terminal and D₂ input terminals. In the example of FIG. 7, each of the squared envelope generator circuitry 720 and the squared signal generator circuitry 722 has an output terminal and an input terminal. Also, in the example of FIG. 7, the delay circuitry 724 has D₃ output terminals and an input terminal.

In the illustrated example of FIG. 7, the sub-term generator circuitry 726 has S₁ output terminals, S₂ output terminals, a first input terminal, a second input terminal, and D₃ input terminals. In the example of FIG. 7, each instance of the delay and multiplexing circuitry 728_{L1}-728_{L2-1} has an output terminal and S₁ input terminals. Also, in the example of FIG. 7, each instance of the delay and multiplexing circuitry 730_{L2}-730_{M-1} has an output terminal and S₂ input terminals. In the example of FIG. 7, each of the multiplier circuits 732₀-73_{M-1} has an output terminal, a first input terminal, and a second input terminal. Also, in the example of FIG. 7, the adder circuitry 734 has an output terminal and M input terminals and the adder circuitry 736 has an output terminal, a first input terminal, and a second input terminal.

In the illustrated example of FIG. 7, the envelope generator circuitry 702 is implemented by digital circuitry. In the example of FIG. 7, the output terminal of the envelope generator circuitry 702 is coupled to the input terminal of the delay circuitry 704 and the input terminal of the envelope generator circuitry 702 is coupled to the DPD terminal 107 (e.g., is coupled to processor circuitry via the DPD terminal 107 of the pre-DPD interpolator circuitry 104). Also, in the example of FIG. 7, the delay circuitry 704 is implemented by one or more D flip-flop circuits. In some examples, the delay circuitry 704 is implemented by one or more FIFO queues. In the example of FIG. 7, the D₁ output terminals of the delay circuitry 704 are coupled to the D₁ input terminals of each of the multiplexer circuits 706₀-706_{N-1} and the input terminal of the delay circuitry 704 is coupled to the output terminal of the envelope generator circuitry 702.

In the illustrated example of FIG. 7, each of the multiplexer circuits 706₀-706_{N-1} is implemented by digital circuitry. In the example of FIG. 7, the output terminals of the multiplexer circuits 706₀-706_{N-1} are coupled to the first input terminals of the concatenated LUTs 708₀-708_{N-1}, respectively. For example, the output terminal of the multiplexer circuit 706₀ is coupled to the first input terminal of the concatenated LUT 708₀. Also, the D₁ input terminals of each of the multiplexer circuits 706₀-706_{N-1} are coupled to the D₁ output terminals of the delay circuitry 704.

In the illustrated example of FIG. 7, each of the concatenated LUTs 708₀-708_{N-1} is implemented by digital circuitry and at least one memory. For example, each of the concatenated LUTs 708₀-708_{N-1} is implemented by digital circuitry and one memory. In some examples, each of the concatenated LUTs 708₀-708_{N-1} is implemented by digital circuitry and two memories as described further below in connection with FIGS. 12, 13, 14, 15, and 16. In the example of FIG. 7, each of the concatenated LUTs 708₀-708_{N-1} is representative of a group of 32-bit LUTs having 512 entries. For example, if the concatenated LUTs 708₀-708_{N-1} are representative of M 32-bit LUTs having 512 entries, then each of the concatenated LUTs 708₀-708_{N-1} is representative of MIN 32-bit LUTs having 512 entries where MIN is rounded up to the nearest integer. Also, for example, the concatenated LUT 708₀ is structured to store data representative of a first LUT having 512 entries (e.g., U entries) and a first width of 32 bits (e.g., V-bits) and a second LUT having 512 entries (e.g., U entries) and a second width of 32 bits (e.g., V-bits). As such, the concatenated LUT 708₀ will have 512 entries (e.g., U entries) and a width of 64 bits (e.g., 2*V-bits). For example, a first entry of the concatenated LUT 708₀ includes 32 bits representative of (e.g., V-bits representative of) a first 32-bit entry of (e.g., a V-bit entry) the first LUT and 32 bits representative of (e.g., V-bits representative of) a second 32-bit entry of (e.g., a l′-bit entry) the second LUT. As such, each of the concatenated LUTs 708₀-708_{N-1} stores 512 entries of 32*MIN bits of data (e.g., each of the concatenated LUTs 708₀-708_{N-1} has 512 rows and each row is 32*M/N bits wide). Combining multiple 32-bit LUTs into a single concatenated LUT consumes less area on a chip than implementing the multiple 32-bit LUTs individually. For example, the concatenated LUTs 708₀-708_{N-1} stores more bits per unit area than an individual LUT and as such saves on-chip area while storing the same number of bits.

In the illustrated example of FIG. 7, the L₁ output terminals of the concatenated LUT 708₀ are coupled to the input terminals of the delay circuitry 712₀-712_{L1-1}, respectively, the L₂-L₁ output terminals of the concatenated LUT 708_{N-2} are coupled to the input terminals of the delay circuitry 712_{L1}-712_{L2-1}, respectively, and the M-L₂ output terminals of the concatenated LUT 708_{N-1} are coupled to the input terminals of the delay circuitry 712_{L2}-712_{M-1}, respectively. Also, in the example of FIG. 7, the first input terminals of the concatenated LUTs 708₀-708_{N-1} are coupled to the output terminals of the multiplexer circuits 706₀-706_{N-1}, respectively. In the example of FIG. 7, the second input terminal of each of the concatenated LUTs 708₀-708_{N-1} is coupled to the output terminal of the DPD estimator circuitry 124 and the third input terminals of the concatenated LUTs 708₀-708_{N-1} are coupled to the N output terminals of the sequencer circuitry 710, respectively. In the example of FIG. 7, the sequencer circuitry 710 is implemented by digital circuitry. Also, the N output terminals of the sequencer circuitry 710 are coupled to the third input terminals of the concatenated LUTs 708₀-708_{N-1}, respectively.

In the illustrated example of FIG. 7, each instance of the delay circuitry 712₀-712_{M-1} is implemented by one or more D flip-flop circuits. In some examples, each instance of the delay circuitry 712₀-712_{M-1} is implemented by one or more FIFO queues. In the example of FIG. 7, the output terminals of the delay circuitry 712₀-712_{L1-1} are coupled to the L₁ input terminals of the LUT adder circuitry 714₀, respectively, the output terminals of the delay circuitry 712_{L1}-712_{L2-1} are coupled to the L₂-L₁ input terminals of the LUT adder circuitry 714_{N-2}, respectively, and the output terminals of the delay circuitry 712_{L2}-712_{M-1} are coupled to the M-L₂ input terminals of the LUT adder circuitry 714_{N-1}, respectively. Also, in the example of FIG. 7, the input terminals of the delay circuitry 712₀-712_{L1-1} are coupled to the L₁ output terminals of the concatenated LUT 708₀, respectively, the input terminals of the delay circuitry 712_{L1}-712_{L2-1} are coupled to the L₂-L₁ output terminals of the concatenated LUT 708_{N-2}, respectively, and the input terminals of the delay circuitry 712_{L2}-712_{M-1} are coupled to the M-L₂ output terminals of the concatenated LUT 708_{N-1}, respectively.

In the illustrated example of FIG. 7, each instance of the LUT adder circuitry 714₀-714_{N-1} is implemented by digital circuitry and MIN instances of adder circuitry. For example, each instance of the LUT adder circuitry 714₀-714_{N-1} is implemented similarly to the LUT adder circuitry 210 of FIGS. 2 and 3. In the example of FIG. 7, the up to L₁ output terminals of the LUT adder circuitry 714₀ are coupled to the first input terminals of a first portion (e.g., the multiplier circuits 732₀-732_{L1-1}) of the multiplier circuits 732₀-732_{M-1}, respectively. Also, the L₁ input terminals of the LUT adder circuitry 714₀ are coupled to the output terminals of the delay circuitry 712₀-712_{L1-1}, respectively. In the example of FIG. 7, the up to L₂-L₁ output terminals of the LUT adder circuitry 714_{N-2} are coupled to the first input terminals of a second portion (e.g., the multiplier circuits 732_{L1}-732_{L2-1}) of the multiplier circuits 732₀-732_{M-1}, respectively. Also, the L₂-L₁ input terminals of the LUT adder circuitry 714_{N-2} are coupled to the output terminals of the delay circuitry 712_{L1}-712_{L2-1}, respectively. In the example of FIG. 7, the up to M-L₂ output terminals of the LUT adder circuitry 714_{N-1} are coupled to the first input terminals of a third portion (e.g., the multiplier circuits 732_{L2}-732_{M-1}) of the multiplier circuits 732₀-732_{M-1}, respectively. Also, the M-L₂ input terminals of the LUT adder circuitry 714_{N-1} are coupled to the output terminals of the delay circuitry 712_{L2}-712_{M-1}, respectively.

In the illustrated example of FIG. 7, the delay circuitry 716 is implemented by one or more D flip-flop circuits. In some examples, the delay circuitry 716 is implemented by one or more FIFO queues. In the example of FIG. 7, the D₂ output terminals of the delay circuitry 716 are coupled to the D₂ input terminals of each of the multiplexer circuits 718₀-718L-1 and the input terminal of the delay circuitry 716 is coupled to the DPD terminal 107 (e.g., is coupled to processor circuitry via the DPD terminal 107 of the pre-DPD interpolator circuitry 104). Also, one of the D₂ output terminals of the delay circuitry 716 is coupled to the first input terminal of the adder circuitry 736.

In the illustrated example of FIG. 7, each of the multiplexer circuits 718₀-718_{L1-1} is implemented by digital circuitry. In the example of FIG. 7, the output terminals of the multiplexer circuits 718₀-718_{L1-1} are coupled to the second input terminals of the first portion (e.g., the multiplier circuits 732₀-732_{L1-1}) of the multiplier circuits 732₀-732_{M-1}, respectively. Also, in the example of FIG. 7, the D₂ input terminals of each of the multiplexer circuits 718₀-718_{L1-1} are coupled to the D₂ output terminals of the delay circuitry 716. In the example of FIG. 7, the squared envelope generator circuitry 720 is implemented by digital circuitry. Also, in the example of FIG. 7, the output terminal of the squared envelope generator circuitry 720 is coupled to the first input terminal of the sub-term generator circuitry 726 and the input terminal of the squared envelope generator circuitry 720 is coupled to the DPD terminal 107 (e.g., is coupled to processor circuitry via the DPD terminal 107 of the pre-DPD interpolator circuitry 104). In the example of FIG. 7, the squared signal generator circuitry 722 is implemented by digital circuitry. Also, the output terminal of the squared signal generator circuitry 722 is coupled to the second input terminal of the sub-term generator circuitry 726 and the input terminal of the squared signal generator circuitry 722 is coupled to the DPD terminal 107 (e.g., is coupled to processor circuitry via the DPD terminal 107 of the pre-DPD interpolator circuitry 104).

In the illustrated example of FIG. 7, the delay circuitry 724 is implemented by one or more D flip-flop circuits. In some examples, the delay circuitry 724 is implemented by one or more FIFO queues. In the example of FIG. 7, the D₃ output terminals of the delay circuitry 724 are coupled to the D₃ input terminals of the sub-term generator circuitry 726, respectively, and the input terminal of the delay circuitry 724 is coupled to the DPD terminal 107 (e.g., is coupled to processor circuitry via the DPD terminal 107 of the pre-DPD interpolator circuitry 104). Also, in the example of FIG. 7, the sub-term generator circuitry 726 is implemented by two or more multiplier circuits. For example, the sub-term generator circuitry 726 is implemented similarly to the sub-term generator circuitry 620 of FIGS. 6A and 6B. In the example of FIG. 7, the S₁ output terminals of the sub-term generator circuitry 726 are coupled to the S₁ input terminals of each instance of the delay and multiplexing circuitry 728_{L1}-728_{L2-1} and the S₂ output terminals of the sub-term generator circuitry 726 are coupled to the S₂ input terminals of each instance of the delay and multiplexing circuitry 730_{L2}-730_{M-1}. Also, in the example of FIG. 7, the first input terminal of the sub-term generator circuitry 726 is coupled to the output terminal of the squared envelope generator circuitry 720, the second input terminal of the sub-term generator circuitry 726 is coupled to the output terminal of the squared signal generator circuitry 722, and the D₃ input terminals of the sub-term generator circuitry 726 are coupled to the D₃ output terminals of the delay circuitry 724, respectively.

In the illustrated example of FIG. 7, each instance of the delay and multiplexing circuitry 728_{L1}-728_{L2-1} is implemented by a multiplexer circuit having an output terminal and S₁ input terminals and delay circuitry having an output terminal and an input terminal. For example, the output terminal of the multiplexer circuit is coupled to the input terminal of the delay circuitry and the S₁ input terminals of the multiplexer circuit are coupled to the S₁ output terminals of the sub-term generator circuitry 726. Also, the output terminal of the delay circuitry is coupled to the second input terminal of a corresponding one of the second portion (e.g., the multiplier circuits 732_{L1}-732_{L2-1}) of the multiplier circuits 732₀-732_{M-1} and the input terminal of the delay circuitry is coupled to the output terminal of the multiplexer circuit. For example, the output terminal of the delay circuitry of the delay and multiplexing circuitry 728_{L2-1} is coupled to the second input terminal of the multiplier circuit 732_{L2-1} and the input terminal of the delay circuitry is coupled to the output terminal of the multiplexer circuit of the delay and multiplexing circuitry 728_{L2-1}.

In the illustrated example of FIG. 7, each instance of the delay and multiplexing circuitry 730_{L2}-730_{M-1} is implemented by a multiplexer circuit having an output terminal and S₂ input terminals and delay circuitry having an output terminal and an input terminal. For example, the output terminal of the multiplexer circuit is coupled to the input terminal of the delay circuitry and the S₂ input terminals of the multiplexer circuit are coupled to the S₂ output terminals of the sub-term generator circuitry 726. Also, the output terminal of the delay circuitry is coupled to the second input terminal of a corresponding one of the third portion (e.g., the multiplier circuits 732_{L2}-732_{M-1}) of the multiplier circuits 732₀-732_{M-1} and the input terminal of the delay circuitry is coupled to the output terminal of the multiplexer circuit. For example, the output terminal of the delay circuitry of the delay and multiplexing circuitry 730_{M-1} is coupled to the second input terminal of the multiplier circuit 730_{M-1} and the input terminal of the delay circuitry is coupled to the output terminal of the multiplexer circuit of the delay and multiplexing circuitry 730_{M-1}.

In the illustrated example of FIG. 7, each of the multiplier circuits 732₀-732_{M-1} is implemented by digital circuitry. In the example of FIG. 7, the output terminals of the first portion (e.g., the multiplier circuits 732₀-732_{L1-1}) of the multiplier circuits 732₀-732_{M-1} are coupled to a first portion of the up to M input terminals of the adder circuitry 734, respectively. Also, the first input terminals of the first portion (e.g., the multiplier circuits 732₀-732_{L1-1}) of the multiplier circuits 732₀-732_{M-1} are coupled to the up to L₁ output terminals of the LUT adder circuitry 714₀, respectively. In the example of FIG. 7, the second input terminals of the first portion (e.g., the multiplier circuits 732₀-732L-1) of the multiplier circuits 732₀-732_{M-1} are coupled to the output terminals of the multiplexer circuits 718₀-718L-1, respectively.

In the illustrated example of FIG. 7, the output terminals of the second portion (e.g., the multiplier circuits 732_{L1}-732_{L2-1}) of the multiplier circuits 732₀-732_{M-1} are coupled to a second portion of the M input terminals of the adder circuitry 734, respectively. In the example of FIG. 7, the first input terminals of the second portion (e.g., the multiplier circuits 732_{L1}-732_{L2-1}) of the multiplier circuits 732₀-732_{M-1} are coupled to the up to L₂-L₁ output terminals of the LUT adder circuitry 714_{N-2}, respectively. Also, in the example of FIG. 7, the second input terminals of the second portion (e.g., the multiplier circuits 732_{L1}-732_{L2-1}) of the multiplier circuits 732₀-732_{M-1} are coupled to the output terminals of the delay and multiplexing circuitry 728_{L1}-728_{L2-1}, respectively.

In the illustrated example of FIG. 7, the output terminals of the third portion (e.g., the multiplier circuits 732_{L2}-732_{M-1}) of the multiplier circuits 732₀-732_{M-1} are coupled to a third portion of the M input terminals of the adder circuitry 734, respectively. In the example of FIG. 7, the first input terminals of the third portion (e.g., the multiplier circuits 732_{L2}-732_{M-1}) of the multiplier circuits 732₀-732_{M-1} are coupled to the up to M-L₂ output terminals of the LUT adder circuitry 714_{N-1}, respectively. Also, in the example of FIG. 7, the second input terminals of the third portion (e.g., the multiplier circuits 732_{L2}-732_{M-1}) of the multiplier circuits 732₀-732_{M-1} are coupled to the output terminals of the delay and multiplexing circuitry 730_{L2}-730_{M-1}, respectively.

In the illustrated example of FIG. 7, each of the adder circuitry 734 and the adder circuitry 736 is implemented by one or more adder circuits (e.g., one or more half adder circuits, one or more full adder circuits, one or more ripple-carry adder circuits, one or more carry-lookahead adder circuits, etc.). In the example of FIG. 7, the output terminal of the adder circuitry 734 is coupled to the second input terminal of the adder circuitry 736. Also, in the example of FIG. 7, a first portion of the M input terminals of the adder circuitry 734 are coupled to the output terminals of the first portion (e.g., the multiplier circuits 732₀-732_{L1-1}) of the multiplier circuits 732₀-732_{M-1}, respectively. In the example of FIG. 7, a second portion of the M input terminals of the adder circuitry 734 are coupled to the output terminals of the second portion (e.g., the multiplier circuits 732_{L1}-732_{L2-1}) of the multiplier circuits 732₀-732_{M-1}, respectively. Also, a third portion of the M input terminals of the adder circuitry 734 are coupled to the output terminals of the third portion (e.g., the multiplier circuits 732_{L2}-732_{M-1}) of the multiplier circuits 732₀-732_{M-1}, respectively. In the example of FIG. 7, the output terminal of the adder circuitry 736 is coupled to power amplifier circuitry (e.g., the PA circuitry 114 of FIG. 1B via the transmitter circuitry 108, the transmitter DAC circuit 110, and the DSA circuitry 112) and the third input terminal of the DPD estimator circuitry 124. Also, in the example of FIG. 7, the first input terminal of the adder circuitry 736 is coupled to one of the D₂ output terminals of the delay circuitry 716 and the second input terminal of the adder circuitry 736 is coupled to the output terminal of the adder circuitry 734.

In the illustrated example of FIG. 7, the DPD corrector circuitry 106 implements Equation 2 described above. By implementing the DPD model of Equation 2, the DPD corrector circuitry 106 improves pre-distortion modeling accuracy at higher bandwidths (e.g., greater than 100 MHZ). In the example of FIG. 7, the envelope generator circuitry 702 determines an envelope (e.g., |x(n)|) of an input signal (e.g., x(n)). For example, the envelope generator circuitry 702 determines an envelope of an input signal as described above (e.g., |x(n)|={square root over (Re(x(n))²+Im(x(n))²))}. In the example of FIG. 7, the delay circuitry 704 generates D₁ delayed versions of the envelope of the input signal. For example, the delay circuitry 704 generates the D₁ delayed versions of the envelope of the input signal over the range

$$[ \frac{{D}_{1}}{2} - 1 , - \frac{{D}_{1}}{2} ] .$$

In the illustrated example of FIG. 7, as the D₁ delayed versions of the envelope of the input signal are utilized to index the concatenated LUTs 708₀-708_{N-1}, the delay circuitry 704 generates the D₁ delayed versions of the envelope of the input signal such that each of the concatenated LUTs 708₀-708_{N-1} is indexed by a signal having a common delay shared between the group of 32-bit LUTs represented by the concatenated LUTs 708₀-708_{N-1}, respectively. For example, the delay circuitry 704 generates (1) a first delayed version of the envelope of the input signal delayed by a first common delay shared between the group of 32-bit LUTs represented by the concatenated LUT 708₀, (2) a second delayed version of the envelope of the input signal delayed by a second common delay shared between the group of 32-bit LUTs represented by the concatenated LUT 708_{N-2}, and (3) a third delayed version of the envelope of the input signal delayed with a third common delay shared between the group of 32-bit LUTs represented by the concatenated LUT 708_{N-1}. As such, a single concatenated LUT can be used to represent a group of 32-bit LUTs. As described below, each instance of the delay circuitry 712₀-712_{M-1} applies a delay to a respective value output by the concatenated LUTs 708₀-708_{N-1}. As such, the respective values output from the delay circuitry 712₀-712_{M-1} correspond to the respective l₂(k) delays to be applied to the envelope of the input signal according to Equation 2 above.

In the illustrated example of FIG. 7, each of the multiplexer circuits 706₀-706_{N-1} selects one of the D₁ delayed versions of the envelope of the input signal based on a programmed value in a respective register associated with each of the multiplexer circuits 706₀-706_{N-1}. For example, the multiplexer circuit 706₀ selects one of the D₁ delayed versions of the envelope of the input signal based on a programmed value in a register associated with the multiplexer circuit 706₀. In the example of FIG. 7, the registers associated with the multiplexer circuits 706₀-706_{N-1} are programmed at startup of the DPD corrector circuitry 106. For example, the registers associated with the multiplexer circuits 706₀-706_{N-1} are programmed at startup of the communication system 100 of FIG. 1B.

In the illustrated example of FIG. 7, the selected delayed versions of the envelope of the input signal that are output from the multiplexer circuits 706₀-706_{N-1} index the concatenated LUTs 708₀-708_{N-1}, respectively. As described above, the delay circuitry 704 generates the D₁ delayed versions of the envelope of the input signal such that each of the concatenated LUTs 708₀-708_{N-1} is indexed by a signal having a common delay shared between the group of 32-bit LUTs represented by the concatenated LUTs 708₀-708_{N-1}, respectively. As such, the respective values output by each of the concatenated LUTs 708₀-708_{N-1} correspond to a common delay with which each of the concatenated LUTs 708₀-708_{N-1} was indexed. In the example of FIG. 7, each instance of the delay circuitry 712₀-712_{M-1} applies a delay to a respective value output by the concatenated LUTs 708₀-708_{N-1}. For example, M registers associated with respective instances of the delay circuitry 712₀-712_{M-1} can be programmed at startup of the DPD corrector circuitry 106 to configure the delays of each instance of the delay circuitry 712₀-712_{M-1} based on the l₂(k) delay to be applied to the envelope of the input signal according to Equation 2 above.

In the illustrated example of FIG. 7, the delay circuitry 712₀-712_{L1-1} outputs values to the LUT adder circuitry 714₀, the delay circuitry 712_{L1}-712_{L2-1} outputs values to the LUT adder circuitry 714_{N-2}, and the delay circuitry 712_{L2}-712_{M-1} outputs values to the LUT adder circuitry 714_{N-1}. In the example of FIG. 7, depending on the complexity of the DPD model implemented by the DPD corrector circuitry 106, the LUT adder circuitry 714₀ can add one or more values output from the delay circuitry 712₀-712_{L1-1}. Also, depending on the complexity of the DPD model implemented by the DPD corrector circuitry 106, the LUT adder circuitry 714N-2 can add one or more values output from the delay circuitry 712_{L1}-712_{L2-1}. In the example of FIG. 7, depending on the complexity of the DPD model implemented by the DPD corrector circuitry 106, the LUT adder circuitry 714_{N-1} can add one or more values output from the delay circuitry 712_{L2}-712_{M-1}.

In the illustrated example of FIG. 7, if the values output from the concatenated LUTs 708₀-708_{N-1} and delayed by the delay circuitry 712₀-712_{M-1} are to be multiplied by at least one of the same delayed version of the input signal or the same delayed version of the squared envelope of the signal, then the LUT adder circuitry 714₀-714_{N-1} can be configured at startup of the DPD corrector circuitry 106 to add the two values and provide the sum of the two values to one or more of the multiplier circuits 732₀-732_{M-1} to be multiplied by at least one of the delayed versions of the input signal or a sub-term generated by the sub-term generator circuitry 726 and at least one of the delay and multiplexing circuitry 728_{L1}-728_{L2-1} or the delay and multiplexing circuitry 730_{L2}-730_{M-1}. For example, as x(n−1)*|x(n−3)|²*LUT(|x(n−1)|) and x(n−1)*|x(n−3)|²*LUT(|x(n−2)|) are both multiplied by x(n−1)*|x(n−3)|², the LUT adder circuitry 714₀-714_{N-1} can be configured at startup of the DPD corrector circuitry 106 to add LUT(|x(n−1)|) and LUT(|x(n−2)|) and provide the sum of the two values to the second portion (e.g., the multiplier circuits 732_{L1}-732_{L2-1}) of the multiplier circuits 732₀-732_{M-1} to be multiplied by the sub-term, x(n−1)*|x(n−3)|², generated by the sub-term generator circuitry 726 and at least one of the delay and multiplexing circuitry 728_{L1}-728_{L2-1} or the delay and multiplexing circuitry 730_{L2}-730_{M-1}. In this manner, at startup of the DPD corrector circuitry 106, some of the multiplier circuits 732₀-732_{M-1}, some of the multiplexer circuits 718₀-718_{L1-1}, some of the delay and multiplexing circuitry 728_{L1}-728_{L2-1}, and some of the delay and multiplexing circuitry 730_{L2}-730_{M-1} can remain disabled thereby reducing power consumption of the DPD corrector circuitry 106. If none of the values output from the concatenated LUTs 708₀-708_{N-1} and delayed by the delay circuitry 712₀-712_{M-1} are to be multiplied by at least one of the same delayed version of the input signal or the same delayed version of the squared envelope of the signal, then the LUT adder circuitry 714₀-714_{N-1} acts as passthrough circuitry and provides the values output from the LUTs 208₀-208_{M-1} to the multiplier circuits 216₀-216_{M-1}.

In the illustrated example of FIG. 7, the delay circuitry 716 generates D₂ delayed versions of the input signal. For example, the delay circuitry 716 generates the D₂ delayed versions of the input signal over the range

$$[ \frac{{D}_{2}}{2} - 1 , - \frac{{D}_{2}}{2} ] .$$

Also, the delay circuitry 716 provides the input signal (e.g., x(n+0)) to the first input terminal of the adder circuitry 736. In the example of FIG. 7, each of the multiplexer circuits 718₀-718_{L1-1} selects one of the D₂ delayed versions of the input signal based on a programmed value in a respective register associated with each of the multiplexer circuits 718₀-718_{L1-1}. For example, the multiplexer 718₀ selects one of the D₂ delayed versions of the input signal based on a programmed value in a register associated with the multiplexer 718₀. In the example of FIG. 7, the registers associated with the multiplexer circuits 718₀-718_{L1-1} are programmed at startup of the DPD corrector circuitry 106. For example, the registers associated with the multiplexer circuits 718₀-718_{L1-1} are programmed at startup of the communication system 100 of FIG. 1B. In the example of FIG. 7, each of the multiplexer circuits 718₀-718_{L1-1} provides one of the D₂ delayed versions of the input signal to the second input terminals of the first portion (e.g., the multiplier circuits 732₀-732_{L1-1}) of the multiplier circuits 732₀-732_{M-1}, respectively.

In the illustrated example of FIG. 7, the squared envelope generator circuitry 720 determines a squared envelope (e.g., |x(n)|²) of an input signal (e.g., x(n)). For example, the squared envelope generator circuitry 720 determines a squared envelope of an input signal by computing the sum of the squared real and squared imaginary components of x(n) (e.g., |x(n)|²=Re(x(n))²+Im(x(n))²). Also, the squared signal generator circuitry 722 determines a squared version (e.g., x²(n)) of an input signal (e.g., x(n)). In the example of FIG. 7, the delay circuitry 724 generates D₃ delayed versions of the input signal. For example, the delay circuitry 724 generates the D₃ delayed versions of the input signal over the range

$$[ \frac{{D}_{3}}{2} - 1 , - \frac{{D}_{3}}{2} ] .$$

In the illustrated example of FIG. 7, the sub-term generator circuitry 726 generates sub-terms for Equation 2. For example, the sub-term generator circuitry 726 generates sub-terms by (1) multiplying the squared input signal by the conjugate of one or more delayed versions of the input signal and (2) multiplying the squared envelope of the input signal by one or more delayed versions of the input signal. In the example of FIG. 7, the sub-term generator circuitry 726 generates sub-terms for unique relative delays (e.g., l₁(k)−l₃(k)) of Equation 2. At least one of (1) one or more instances of the delay and multiplexing circuitry 728_{L1}-728_{L2-1} or (2) one or more instances of the delay and multiplexing circuitry 730_{L2}-730_{M-1} can be programmed at startup of the DPD corrector circuitry 106 to add an individual delay to the sub-terms determined by the sub-term generator circuitry 726. For example, M-L₁ registers associated with respective instances of the delay and multiplexing circuitry 728_{L1}-728_{L2-1} and the delay and multiplexing circuitry 730_{L2}-730_{M-1} can be programmed at startup of the DPD corrector circuitry 106 to configure the delays of each instance of the delay and multiplexing circuitry 728_{L1}-728_{L2-1} and the delay and multiplexing circuitry 730_{L2}-730_{M-1} based on at least one of the l₁(k) delay or the l₃(k) delay to be applied to the sub-terms according to Equation 2 above.

In the illustrated example of FIG. 7, the multiplexer circuit of each instance of the delay and multiplexing circuitry 728_{L1}-728_{L2-1} selects one of the S₁ signals output by the sub-term generator circuitry 726 based on a programmed value in a respective register associated with the multiplexer circuit of each instance of the delay and multiplexing circuitry 728_{L1}-728_{L2-1}. For example, the multiplexer circuit of the delay and multiplexing circuitry 728_{L2-1} selects one of the S₁ signals based on a programmed value in a register associated with the delay and multiplexing circuitry 728_{L2-1}. In the example of FIG. 7, the respective registers associated with the multiplexer circuit of each instance of the delay and multiplexing circuitry 728_{L1}-728_{L2-1} are programmed at startup of the DPD corrector circuitry 106. For example, the respective registers associated with the multiplexer circuit of each instance of the delay and multiplexing circuitry 728_{L1}-728_{L2-1} are programmed at startup of the communication system 100 of FIG. 1B. In the example of FIG. 7, the multiplexer circuit of each instance of the delay and multiplexing circuitry 728_{L1}-728_{L2-1} provides the respective selected signal to the input terminals of the delay circuitry of the corresponding instance of the delay and multiplexing circuitry 728_{L1}-728_{L2-1}. As described above, delay circuitry of each the delay and multiplexing circuitry 728_{L1}-728_{L2-1} applies a delay based on a programmed value and provides the delayed version of the signal to the second portion (e.g., the multiplier circuits 732_{L1}-732_{L2-1}) of the multiplier circuits 732₀-732_{M-1}, respectively, based on at least one of the l₁(k) delay or the l₃(k) delay to be applied to the sub-terms according to Equation 2 above.

In the illustrated example of FIG. 7, the multiplexer circuit of each instance of the delay and multiplexing circuitry 730_{L2}-730_{M-1} selects one of the S₂ signals output by the sub-term generator circuitry 726 based on a programmed value in a respective register associated with the multiplexer circuit of each instance of the delay and multiplexing circuitry 730₂-730_{M-1}. For example, the multiplexer circuit of the delay and multiplexing circuitry 730_{M-1} selects one of the S₂ signals based on a programmed value in a register associated with the delay and multiplexing circuitry 730_{M-1}. In the example of FIG. 7, the respective registers associated with the multiplexer circuit of each instance of the delay and multiplexing circuitry 730_{L2}-730_{M-1} are programmed at startup of the DPD corrector circuitry 106. For example, the respective registers associated with the multiplexer circuit of each instance of the delay and multiplexing circuitry 730_{L2}-730_{M-1} are programmed at startup of the communication system 100 of FIG. 1B. In the example of FIG. 7, the multiplexer circuit of each instance of the delay and multiplexing circuitry 730_{L2}-730_{M-1} provides the respective selected signal to the input terminals of the delay circuitry of the corresponding instance of the delay and multiplexing circuitry 730_{L2}-730_{M-1}. As described above, delay circuitry of each the delay and multiplexing circuitry 730_{L2}-730_{M-1} applies a delay based on a programmed value and provides the delayed version of the signal to the third portion (e.g., the multiplier circuits 732_{L2}-732_{M-1}) of the multiplier circuits 732₀-732_{M-1}, respectively, based on at least one of the l₁(k) delay or the l₃(k) delay to be applied to the sub-terms according to Equation 2 above.

In the illustrated example of FIG. 7, by generating sub-terms outside of the signal path of the values output from the concatenated LUTs 708₀-708_{N-1}, the sub-term generator circuitry 726 reduces the number of multiplier circuits to implement Equation 2. For example, generating sub-terms in the signal path of the values output from the concatenated LUTs 708₀-708_{N-1} would require more than M-L₁ extra multiplier circuits. In the example of FIG. 7, the sub-term generator circuitry 726 can generate sub-terms with 9 multiplier circuits for a relative delay range of [2, −2], which would be less multiplier circuits than the M-L₁ multiplier circuits.

In the illustrated example of FIG. 7, the first portion (e.g., the multiplier circuits 732₀-732_{L1-1}) of the multiplier circuits 732₀-732_{M-1} multiplies the values output from the LUT adder circuitry 714₀ by the values output from the multiplexer circuits 718₀-718_{L1-1}, respectively. Also, the first portion (e.g., the multiplier circuits 732₀-732_{L1-1}) of the multiplier circuits 732₀-732_{M-1} provides the products to the first portion of the up to M input terminals of the adder circuitry 734. In the example of FIG. 7, the second portion (e.g., the multiplier circuits 732_{L1}-732_{L2-1}) of the multiplier circuits 732₀-732_{M-1} multiplies the values output from the LUT adder circuitry 714_{N-2} by the values output from the delay and multiplexing circuitry 728_{L1}-728_{L2-1}, respectively. Also, the second portion (e.g., the multiplier circuits 732_{L1}-732_{L2-1}) of the multiplier circuits 732₀-732_{M-1} provides the products to the second portion of the up to M input terminals of the adder circuitry 734. In the example of FIG. 7, the third portion (e.g., the multiplier circuits 732_{L2}-732_{M-1}) of the multiplier circuits 732₀-732_{M-1} multiplies the values output from the LUT adder circuitry 714_{N-1} by the values output from the delay and multiplexing circuitry 730_{L2}-730_{M-1}, respectively. Also, the third portion (e.g., the multiplier circuits 732_{L2}-732_{M-1}) of the multiplier circuits 732₀-732_{M-1} provides the products to the third portion of the up to M input terminals of the adder circuitry 734.

In the illustrated example of FIG. 7, the adder circuitry 734 adds the values from the first portion (e.g., the multiplier circuits 732₀-732_{L1-1}) of the multiplier circuits 732₀-732_{M-1}, the values from the second portion (e.g., the multiplier circuits 732_{L1}-732_{L2-1}) of the multiplier circuits 732₀-732_{M-1}, and the values from the third portion (e.g., the multiplier circuits 732_{L2}-732_{M-1}) of the multiplier circuits 732₀-732_{M-1}. The adder circuitry 734 also provides the sum to the second input terminal of the adder circuitry 736. The adder circuitry 736 adds the input signal (e.g., x(n±0)) with the value at the output terminal of the adder circuitry 734 and provides the sum at the output terminal of the DPD corrector circuitry 106.

As described above, the DPD corrector circuitry 106 of FIG. 1B is parallelized-by-two. For example, the DPD corrector circuitry 106 can be parallelized-by-two to facilitate operation at a higher sampling rate while also operating at a lower clock rate. Accordingly, another instance of the circuitry of FIG. 7 may be implemented in parallel with the circuitry of FIG. 7 to facilitate such parallelization. That is, the circuitry of FIG. 7 may be duplicated and some of the circuitry of FIG. 7 may be adjusted to implement a parallel instance of the circuitry of FIG. 7. For example, in a parallelized-by-two implementation of the circuitry of FIG. 7, each instance of the delay circuitry 704 generates D₁/2 delayed versions of the envelope of the input signal and the multiplexer circuits 706₀-706_{N-1} in each instance of the circuitry of FIG. 7 receive values from both instances of the delay circuitry 704. Similarly, in a parallelized-by-two implementation of the circuitry of FIG. 7, each instance of the delay circuitry 716 generates D₂/2 delayed versions of the envelope of the input signal and the multiplexer circuits 718₀-718_{L1-1} in each instance of the circuitry of FIG. 7 receive values from both instances of the delay circuitry 716. The delay circuitry 724, the delay and multiplexing circuitry 728_{L1}-728_{L2-1}, and the delay and multiplexing circuitry 730_{L2}-730_{M-1} can be parallelized similarly. Also, the programmed delay values of each of the delay circuitry 712₀-712_{M-1} may be adjusted to implement a parallel instance of the circuitry of FIG. 7. As such, in a first clock cycle of the DPD corrector circuitry 106, a first instance of the circuitry of FIG. 7 processes a first sample of an input signal (e.g., x(n)) in parallel with a second instance of the circuitry of FIG. 7 that processes a second sample of the input signal (e.g., x(n+1)). Additional instances of the circuitry of FIG. 7 may be implemented to support additional parallelization (e.g., three instances of the circuitry of FIG. 7 to support a parallelized-by-three implementation, four instances of the circuitry of FIG. 7 to support a parallelized-by-four implementation, etc.).

In a parallelized-by-two implementation of the DPD corrector circuitry 106, another instance of the concatenated LUTs 708₀-708_{N-1} can be implemented in a parallel instance of the circuitry of FIG. 7. Also, the concatenated LUTs 708₀-708_{N-1} can be shared between each instance of the circuitry of FIG. 7. For example, the concatenated LUTs 708₀-708_{N-1} can be implemented once and accessed by a first instance of the circuitry of FIG. 7 and a second instance of the circuitry of FIG. 7 in the same clock cycle as described further below in connection with FIGS. 12, 13, 14, 15, and 16.

Also, as described above, the non-linearity of PA circuitry can fluctuate based on temperature of the PA circuitry or input signal profile to the PA circuitry. As such, the DPD corrector circuitry 106 includes a spare concatenated LUT for each of the concatenated LUTs 708₀-708_{N-1} (e.g., main concatenated LUTs). For example, the spare concatenated LUTs can be updated by the DPD estimator circuitry 124 while the DPD corrector circuitry 106 utilizes the concatenated LUTs 708₀-708_{N-1} (e.g., the main concatenated LUTs) to perform DPD correction. Because the values output from the concatenated LUTs 708₀-708_{N-1} (e.g., the main concatenated LUTs) may be delayed by different amounts, the sequencer circuitry 710 sequences the switch from the concatenated LUTs 708₀-708_{N-1} (e.g., the main concatenated LUTs) to the spare concatenated LUTs.

For example, the sequencer circuitry 710 sequences the switch of the delay circuitry 712₀-712_{M-1} from the concatenated LUTs 708₀-708_{N-1} (e.g., the main concatenated LUTs) to the spare concatenated LUTs such that the values output from each instance of the delay circuitry 712₀-712_{M-1} switch to updated values from the DPD estimator circuitry 124 in the same clock cycle. In the example of FIG. 7, once the sequencer circuitry 710 has switched the DPD corrector circuitry 106 from the concatenated LUTs 708₀-708_{N-1} (e.g., the main concatenated LUTs) to the spare concatenated LUTs, the sequencer circuitry 710 facilitates updating of the concatenated LUTs 708₀-708_{N-1} (e.g., the main concatenated LUTs) with updated values to model PA circuitry non-linearity. After the concatenated LUTs 708₀-708_{N-1} (e.g., the main concatenated LUTs) have been updated, the sequencer circuitry 710 switches the DPD corrector circuitry 106 from the spare concatenated LUTs to the concatenated LUTs 708₀-708_{N-1} (e.g., the main concatenated LUTs).

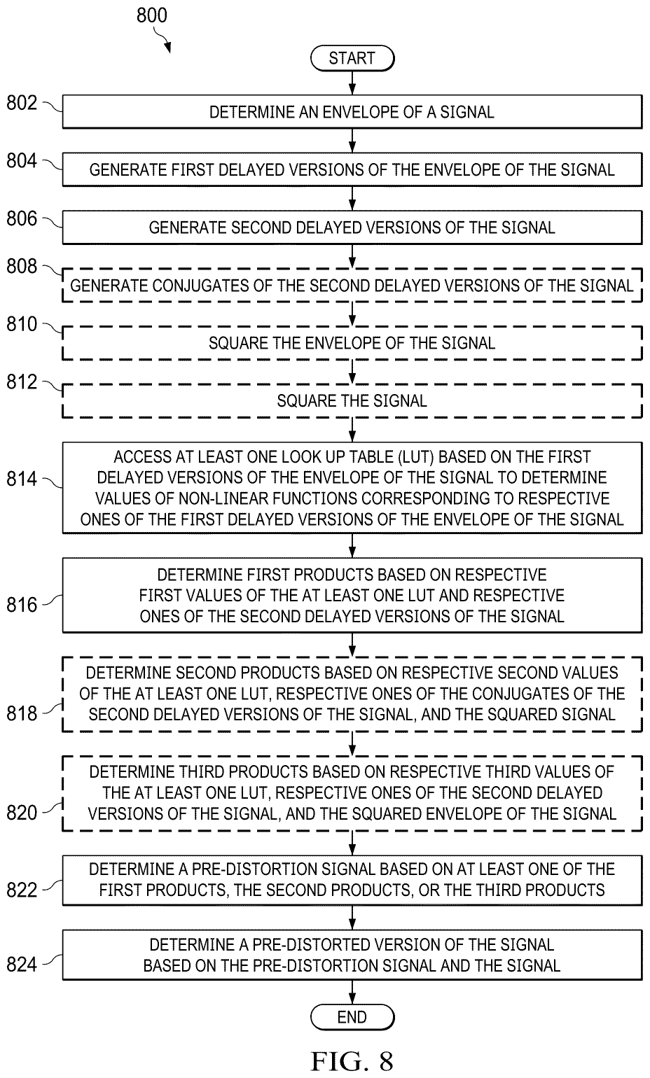

FIG. 8 is a flowchart representative of at least one of example machine-readable instructions or example operations 800 that may be at least one of executed, instantiated, or performed using an example programmable circuitry implementation of the DPD corrector circuitry 106 of any of FIG. 1, 2, 4, 5, 6A, or 7. The at least one of example machine-readable instructions or example operations 800 of FIG. 8 begin at block 802, at which envelope generator circuitry determines an envelope of a signal. For example, any of the envelope generator circuitry 202 of FIG. 2, the envelope generator circuitry 402 of FIG. 4, the envelope generator circuitry 502 of FIG. 5, the envelope generator circuitry 602 of FIG. 6A, or the envelope generator circuitry 702 of FIG. 7 can perform block 802.

In the illustrated example of FIG. 8, at block 804, delay circuitry generates first delayed versions of the envelope of the signal. For example, any of the delay circuitry 204 of FIG. 2, the delay circuitry 404 of FIG. 4, the delay circuitry 504 of FIG. 5, the delay circuitry 604 of FIG. 6A, or the delay circuitry 704 of FIG. 7 can perform block 804. At block 806, delay circuitry generates second delayed versions of the signal. For example, any of the delay circuitry 212 of FIG. 2, the delay circuitry 414 of FIG. 4, the delay circuitry 510 of FIG. 5, the delay circuitry 610 or the delay circuitry 618 of FIG. 6A, or the delay circuitry 716 or the delay circuitry 724 of FIG. 7 can perform block 806.

In some examples, the at least one of machine-readable instructions or operations 800 include block 808. At block 808, conjugate generator circuitry generates conjugates of the second delayed versions the signal. For example, any of the conjugate generator circuitry 513_{L1}-513_{L2-1} of FIG. 5, the sub-term generator circuitry 620 (which includes conjugate generator circuitry) of FIG. 6A, or the sub-term generator circuitry 726 (which includes conjugate generator circuitry) of FIG. 7 can perform block 808. In some examples, the at least one of machine-readable instructions or operations 800 include block 810. At block 810, squared envelope generator circuitry squares the envelope of the signal. For example, any of the squared envelope generator circuitry 516 of FIG. 5, the squared envelope generator circuitry 614 of FIG. 6A, or the squared envelope generator circuitry 720 of FIG. 7 can perform block 810.

In some examples, the at least one of machine-readable instructions or operations 800 include block 812. At block 812, squared signal generator circuitry squares the signal. For example, any of the squared signal generator circuitry 518 of FIG. 5, the squared signal generator circuitry 616 of FIG. 6A, or the squared signal generator circuitry 722 of FIG. 7 can perform block 812. In the example of FIG. 8, at block 814, multiplexer circuits access at least one LUT based on the first delayed versions of the envelope of the signal to determine values of non-linear functions corresponding to respective ones of the first delayed versions of the envelope of the signal. For example, any of the multiplexer circuits 206₀-206_{M-1} of FIG. 2, the multiplexer circuits 406₀-406_{N-1} of FIG. 4, the multiplexer circuits 506₀-506_{M-1} of FIG. 5, the multiplexer circuits 606₀-606_{M-1} of FIG. 6, or the multiplexer circuits 706₀-706_{N-1} of FIG. 7 can perform block 814.

In the illustrated example of FIG. 8, at block 816, multiplier circuits determine first products based on respective first values of the at least one LUT and respective ones of the second delayed versions of the signal. For example, any of the multiplier circuits 216₀-216_{M-1} of FIG. 2, the multiplier circuits 418₀-418_{M-1} of FIG. 4, the first portion (e.g., the multiplier circuits 514₀-514_{L1-1}) of the multiplier circuits 514₀-514_{M-1} of FIG. 5, the first portion (e.g., the multiplier circuits 626₀-626_{L1-1}) of the multiplier circuits 626₀-626_{M-1} of FIG. 6, or the first portion (e.g., the multiplier circuits 732₀-732_{L1-1}) of the multiplier circuits 732₀-732_{M-1} of FIG. 7 can perform block 816. In some examples, the at least one of machine-readable instructions or operations 800 include block 818.

For example, at block 818, multiplier circuits determine second products based on respective second values of the at least one LUT, respective ones of the conjugates of the second delayed versions of the signal, and the squared signal. For example, any of the second portion (e.g., the multiplier circuits 514_{L1}-514_{L2-1}) of the multiplier circuits 514₀-514_{M-1} of FIG. 5, the second portion (e.g., the multiplier circuits 626_{L1}-626_{L2-1}) of the multiplier circuits 626₀-626_{M-1} of FIG. 6, or the second portion (e.g., the multiplier circuits 732_{L1}-732_{L2-1}) of the multiplier circuits 732₀-732_{M-1} of FIG. 7 can perform block 818. In some examples, the at least one of machine-readable instructions or operations 800 include block 820. At block 820, multiplier circuits determine third products based on respective third values of the at least one LUT, respective ones of the second delayed versions of the signal, and the squared envelope of the signal. For example, any of the third portion (e.g., the multiplier circuits 514_{L2}-514_{M-1}) of the multiplier circuits 514₀-514_{M-1} of FIG. 5, the third portion (e.g., the multiplier circuits 626_{L2}-626_{M-1}) of the multiplier circuits 626₀-626_{M-1} of FIG. 6, or the third portion (e.g., the multiplier circuits 732_{L2}-732_{M-1}) of the multiplier circuits 732₀-732_{M-1} of FIG. 7 can perform block 820.

In the illustrated example of FIG. 8, at block 822, adder circuitry determines a pre-distortion signal based on at least one of the first products, the second products, or the third products. For example, any of the adder circuitry 218 of FIG. 2, the adder circuitry 420 of FIG. 4, the adder circuitry 532 of FIG. 5, the adder circuitry 628 of FIG. 6A, or the adder circuitry 734 of FIG. 7 can perform block 822. At block 824, adder circuitry determines a pre-distorted version of the signal based on the pre-distortion signal and the signal. For example, any of the adder circuitry 220 of FIG. 2, the adder circuitry 422 of FIG. 4, the adder circuitry 534 of FIG. 5, the adder circuitry 630 of FIG. 6A, or the adder circuitry 736 of FIG. 7 can perform block 824.

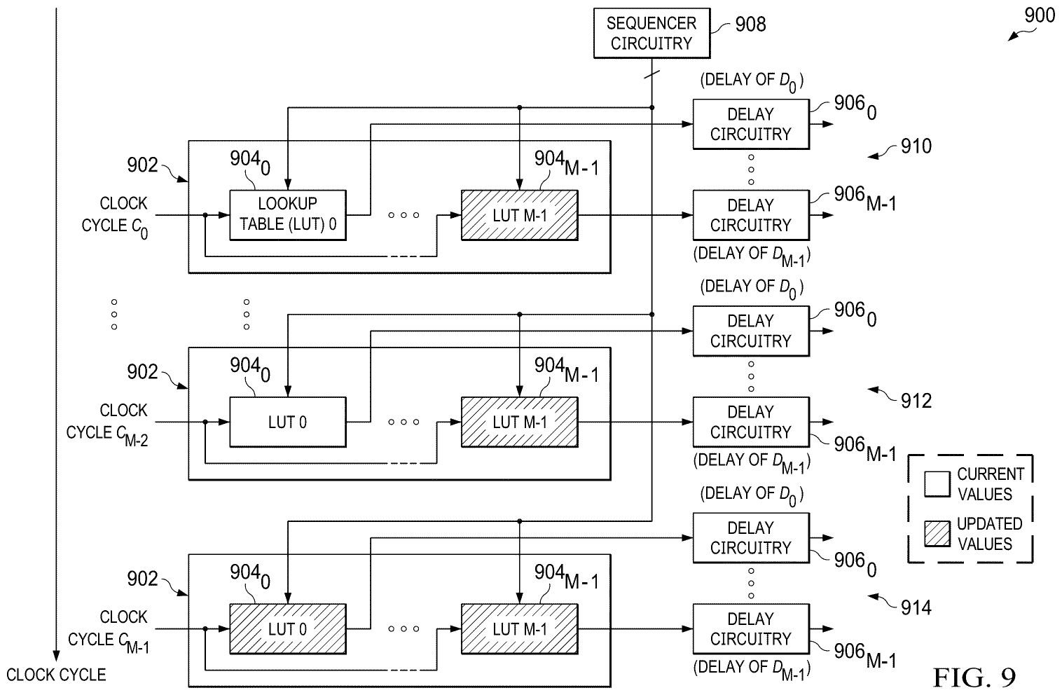

FIG. 9 is a sequence diagram 900 representative of example operations to update an example concatenated LUT 902. In the example of FIG. 9, the concatenated LUT 902 is representative of example sub-LUTs 904₀-904_{M-1}. As described above, the concatenated LUT 902 is indexed by a version of an envelope of an input signal that is delayed by a common delay shared between the sub-LUTs 904₀-904_{M-1}. As such, the values output by each of the sub-LUTs 904₀-904_{M-1} correspond to the common delay with which the concatenated LUT 902 was indexed. In the example of FIG. 9, example delay circuitry 906₀-906_{M-1} applies respective delays to the values output by the sub-LUTs 904₀-904_{M-1} to realize the delays specified by at least one of Equation 1 or Equation 2 above.

In the illustrated example of FIG. 9, each instance of the delay circuitry 906₀-906_{M-1} applies a delay to a value output by the sub-LUTs 904₀-904_{M-1}, respectively. For example, M registers associated with respective instances of the delay circuitry 906₀-906_{M-1} can be programmed at startup of the DPD corrector circuitry 106 to configure the delays of each instance of the delay circuitry 906₀-906_{M-1} based on the l₂(k) delay to be applied to the envelope of the input signal according to at least one of Equation 1 or Equation 2 above. As such, respective instances of the delay circuitry 906₀-906_{M-1} may apply different delays to values output by the sub-LUTs 904₀-904_{M-1}.

As described above, the DPD corrector circuitry 106 includes a spare concatenated LUT for each concatenated LUT of the DPD corrector circuitry 106. For example, the spare concatenated LUT can be updated by the DPD estimator circuitry 124 while the DPD corrector circuitry 106 utilizes the concatenated LUT to perform DPD correction. In the example of FIG. 9, because the values output from concatenated LUT 902 may be delayed by different amounts, example sequencer circuitry 908 sequences the switch from the concatenated LUT 902 to the spare concatenated LUT. For example, the sequencer circuitry 908 may implement any of the sequencer circuitry 410 of FIG. 4 or the sequencer circuitry 710 of FIG. 7.

In the illustrated example of FIG. 9, the sequencer circuitry 908 switches the values output from each of the sub-LUTs 904₀-904_{M-1} from currently used values stored in the sub-LUTs 904₀-904_{M-1} to updated values stored in the sub-LUTs of the spare concatenated LUT in a manner that accounts for the variable delays at the output terminals of each of the sub-LUTs 904₀-904_{M-1}. To handle variable delays at the output terminals of each of the sub-LUTs 904₀-904_{M-1}, the sequencer circuitry 908 varies when each of the sub-LUTs 904₀-904_{M-1} are switched to the updated values stored in the sub-LUTs of the spare concatenated LUT so that the updated values arrive at the output terminals of the delay circuitry 906₀-906_{M-1} in the same clock cycle.

For example, if the value output by the sub-LUT 904_{M-1} is delayed by two samples with respect to the value output by the sub-LUT 904₀, then the sequencer circuitry 908 switches the sub-LUT 904_{M-1} to updated values during a first clock cycle 910, waits for a second clock cycle 912, and switches the sub-LUT 904₀ to updated values during a third clock cycle 914. In other words, the sequencer circuitry 908 switches the sub-LUT 904_{M-1} to updated values from the spare concatenated LUT two clock cycles before the sequencer circuitry 908 switches the sub-LUT 904₀ to updated values from the spare concatenated LUT.

As such, the sequencer circuitry 908 facilitates the updating of the sub-LUTs 904₀-904_{M-1} such that updated values arrive at the output terminals of the delay circuitry 906₀-906_{M-1} in the same clock cycle. In the example of FIG. 9, any variable delays before the concatenated LUT 902 do not affect the timing of switching performed by the sequencer circuitry 908. For example, the time at which the updated LUT contents arrive at the output terminals of the delay circuitry 906₀-906_{M-1} is not affected by variable delays before concatenated LUT 902.

While the example of FIG. 9 describes example operation of the sequencer circuitry 908 with respect to updating an instance of transmitter circuitry including one concatenated LUT (e.g., the concatenated LUT 902), the example operation of the sequencer circuitry 908 is likewise applicable to an instance of transmitter circuitry including any number of concatenated LUTs. For example, the sequencer circuitry 908 sequences the switch of delay circuitry (e.g., the delay circuitry 906₀-906_{M-1}) from main concatenated LUTs to spare concatenated LUTs such that the values output from each instance of the delay circuitry (e.g., the delay circuitry 906₀-906_{M-1}) switch to updated values from DPD estimator circuitry (e.g., the DPD estimator circuitry 124) in the same clock cycle.

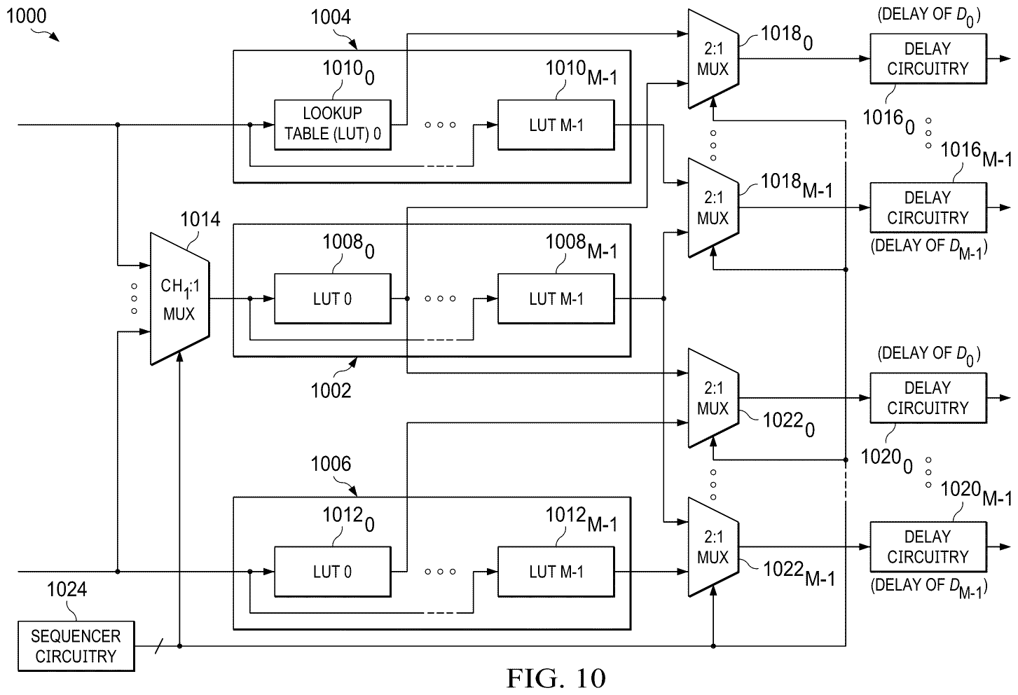

FIG. 10 is a block diagram of an example implementation of an example spare concatenated LUT 1002 shared between at least two instances of transmitter circuitry of example transceiver circuitry 1000. For example, the transceiver circuitry 1000 includes the functionality to operate as and may be implemented by two or more instances of transmitter circuitry and one or more instances of receiver circuitry. In the example of FIG. 10, a first instance of transmitter circuitry of the transceiver circuitry 1000 includes a first example concatenated LUT 1004 and a second instance of transmitter circuitry of the transceiver circuitry 1000 includes a second example concatenated LUT 1006. As described above, an example frequency band may be divided into one or more channels where a channel refers to a frequency range within the frequency band. In the example of FIG. 10, the first instance of transmitter circuitry is to perform transmission in a first channel of a frequency band and the second instance of transmitter circuitry is to perform transmission in a second channel of the frequency band (e.g., where the second channel is at least one of the same as or different than the first channel).

In the illustrated example of FIG. 10, the spare concatenated LUT 1002 includes first example sub-LUTs 1008₀-1008_{M-1}. In the example of FIG. 10, the concatenated LUT 1004 includes second example sub-LUTs 1010₀-1010_{M-1}. Also, in the example of FIG. 10, the concatenated LUT 1006 includes third example sub-LUTs 1012₀-1012_{M-1}. In the example of FIG. 10, the transceiver circuitry 1000 also includes a first example multiplexer circuit 1014 to facilitate choosing between indexing the spare concatenated LUT 1002 with a signal from the first instance of transmitter circuitry and indexing the spare concatenated LUT 1002 with a signal from the second instance of transmitter circuitry.

In the illustrated example of FIG. 10, the first instance of transmitter circuitry includes first example delay circuitry 1016₀-1016_{M-1} and second example multiplexer circuits 1018₀-1018_{M-1} to facilitate switching respective instances of the delay circuitry 1016₀-1016_{M-1} between the concatenated LUT 1004 and the spare concatenated LUT 1002. In the example of FIG. 10, the second instance of transmitter circuitry includes second example delay circuitry 1020₀-1020_{M-1} and third example multiplexer circuits 1022₀-1022_{M-1} to facilitate switching respective instances of the delay circuitry 1020₀-1020_{M-1} between the concatenated LUT 1006 and the spare concatenated LUT 1002. Also, the transceiver circuitry 1000 includes example sequencer circuitry 1024.

In the illustrated example of FIG. 10, each of the sub-LUTs 1008₀-1008_{M-1}, the sub-LUTs 1010₀-1010_{M-1}, and the sub-LUTs 1012₀-1012_{M-1} has an output terminal and an input terminal. In the example of FIG. 10, the multiplexer circuit 1014 has an output terminal, a control terminal, and CH₁ input terminals corresponding to the number of instances of transmitter circuitry of the transceiver circuitry 1000 between which the spare concatenated LUT 1002 is shared. For example, the multiplexer circuit 1014 has a first input terminal and a second input terminal. In the example of FIG. 10, each instance of the delay circuitry 1016₀-1016_{M-1} and each instance of the delay circuitry 1020₀-1020_{M-1} includes an output terminal and an input terminal. Also, each of the multiplexer circuits 1018₀-1018_{M-1} and each of the multiplexer circuits 1022₀-1022_{M-1} has an output terminal, a control terminal, a first input terminal, and a second input terminal.

In the illustrated example of FIG. 10, the sequencer circuitry 1024 has at least M*CH₁+1 output terminals. In the example of FIG. 10, the sequencer circuitry 1024 has M output terminals to control the multiplexer circuits of each instance of transmitter circuitry that shares the spare concatenated LUT 1002. For example, the sequencer circuitry 1024 has 2*M output terminals to control the multiplexer circuits 1018₀-1018_{M-1} and the multiplexer circuits 1022₀-1022_{M-1}. The sequencer circuitry 1024 also has at least one output terminal to control the multiplexer circuit 1014.

In the illustrated example of FIG. 10, each of the spare concatenated LUT 1002, the concatenated LUT 1004, and the concatenated LUT 1006 is implemented by digital circuitry and at least one memory. For example, each of the spare concatenated LUT 1002, the concatenated LUT 1004, and the concatenated LUT 1006 is implemented by digital circuitry and one memory. In some examples, each of the spare concatenated LUT 1002, the concatenated LUT 1004, and the concatenated LUT 1006 is implemented by digital circuitry and two memories as described further below in connection with FIGS. 12, 13, 14, 15, and 16. In the example of FIG. 10, each of the spare concatenated LUT 1002, the concatenated LUT 1004, and the concatenated LUT 1006 is representative of a group of 32-bit LUTs having 512 entries. For example, the spare concatenated LUT 1002 is representative of M 32-bit LUTs (e.g., the sub-LUTs 1008₀-1008_{M-1}) having 512 entries. Also, the concatenated LUT 1004 is representative of M 32-bit LUTs (e.g., the sub-LUTs 1010₀-1010_{M-1}) having 512 entries. In the example of FIG. 10, the concatenated LUT 1006 is representative of M 32-bit LUTs (e.g., the sub-LUTs 1012₀-1012_{M-1}) having 512 entries. As such, each of the spare concatenated LUT 1002, the concatenated LUT 1004, and the concatenated LUT 1006 stores 512 entries of 32*M bits of data (e.g., each of the spare concatenated LUT 1002, the concatenated LUT 1004, and the concatenated LUT 1006 has 512 rows and each row is 32*M bits wide).

In the illustrated example of FIG. 10, the output terminals of the sub-LUTs 1008₀-1008_{M-1} are coupled to the second input terminals of the multiplexer circuits 1018₀-1018_{M-1}, respectively. Also, the output terminals of the sub-LUTs 1008₀-1008_{M-1} are coupled to the first input terminals of the multiplexer circuits 1022₀-1022_{M-1}, respectively. In the example of FIG. 10, the input terminals of the sub-LUTs 1008₀-1008_{M-1} are coupled to the output terminal of the multiplexer circuit 1014.

In the illustrated example of FIG. 10, the output terminals of the sub-LUTs 1010₀-1010_{M-1} are coupled to the first input terminals of the multiplexer circuits 1018₀-1018_{M-1}, respectively. Also, the input terminals of the sub-LUTs 1010₀-1010_{M-1} are coupled to the output terminal of a multiplexer circuit of the first instance of transmitter circuitry (e.g., one of the multiplexer circuits 406₀-406_{N-1} of FIG. 4, one of the multiplexer circuits 706₀-706_{N-1} of FIG. 7, etc.). In the example of FIG. 10, the output terminals of the sub-LUTs 1012₀-1012_{M-1} are coupled to the second input terminals of the multiplexer circuits 1022₀-1022_{M-1}, respectively. Also, the input terminals of the sub-LUTs 1012₀-1012_{M-1} are coupled to the output terminal of a multiplexer circuit of the second instance of transmitter circuitry (e.g., one of the multiplexer circuits 406₀-406_{N-1} of FIG. 4, one of the multiplexer circuits 706₀-706_{N-1} of FIG. 7, etc.).

In the illustrated example of FIG. 10, the multiplexer circuit 1014 is implemented by digital circuitry. In the example of FIG. 10, the output terminal of the multiplexer circuit 1014 is coupled to the input terminals of the sub-LUTs 1008₀-1008_{M-1}. Also, the control terminal of the multiplexer circuit 1014 is coupled to an output terminal of the sequencer circuitry 1024. In the example of FIG. 10, the CH₁ input terminals of the multiplexer circuit 1014 are coupled to the output terminal of a multiplexer circuit of each instance of transmitter circuitry of the transceiver circuitry 1000 between which the spare concatenated LUT 1002 is shared. For example, the spare concatenated LUT 1002 is shared between two instances of transmitter circuitry of the transceiver circuitry 1000. As such, a first input terminal of the multiplexer circuit 1014 is coupled to the output terminal of a multiplexer circuit of the first instance of transmitter circuitry and a second input terminal of the multiplexer circuit 1014 is coupled to the output terminal of a multiplexer circuit of the second instance of transmitter circuitry.

In the illustrated example of FIG. 10, each instance of the delay circuitry 1016₀-1016_{M-1} and each instance of the delay circuitry 1020₀-1010_{M-1} is implemented by one or more D flip-flop circuits. In some examples, each instance of the delay circuitry 1016₀-1016_{M-1} and each instance of the delay circuitry 1020₀-1010_{M-1} is implemented by one or more FIFO queues. In the example of FIG. 10, the output terminals of the delay circuitry 1016₀-1016_{M-1} are coupled to the first input terminals of multiplier circuits (e.g., the multiplier circuits 418₀-418_{M-1}) or the input terminals of LUT adder circuitry (e.g., one or more instances of the LUT adder circuitry 714₀-714_{N-1}), respectively. Also, the input terminals of the delay circuitry 1016₀-1016_{M-1} are coupled to the output terminals of the multiplexer circuits 1018₀-1018_{M-1}, respectively. In the example of FIG. 10, the output terminals of the delay circuitry 1020₀-1020_{M-1} are coupled to the first input terminals of multiplier circuits (e.g., the multiplier circuits 418₀-418_{M-1}) or the input terminals of LUT adder circuitry (e.g., one or more instances of the LUT adder circuitry 714₀-714_{N-1}), respectively. Also, the input terminals the delay circuitry 1020₀-1020_{M-1} are coupled to the output terminals of the multiplexer circuits 1022₀-1022_{M-1}, respectively.

In the illustrated example of FIG. 10, each of the multiplexer circuits 1018₀-1018_{M-1} and each of the multiplexer circuits 1022₀-1022_{M-1} is implemented by digital circuitry. In the example of FIG. 10, the output terminals of the multiplexer circuits 1018₀-1018_{M-1} are coupled to the input terminals of the delay circuitry 1016₀-1016_{M-1}, respectively. Also, the control terminals of the multiplexer circuits 1018₀-1018_{M-1} are coupled to M output terminals of the sequencer circuitry 1024, respectively. In the example of FIG. 10, the first input terminals of the multiplexer circuits 1018₀-1018_{M-1} are coupled to the output terminals of the sub-LUTs 1010₀-1010_{M-1}, respectively, and the second input terminals of the multiplexer circuits 1018₀-1018_{M-1} are coupled to the output terminals of the sub-LUTs 1008₀-1008_{M-1}, respectively.

In the illustrated example of FIG. 10, the output terminals of the multiplexer circuits 1022₀-1022_{M-1} are coupled to the input terminals of the delay circuitry 1020₀-1020_{M-1}, respectively. Also, the control terminals of the multiplexer circuits 1022₀-1022_{M-1} are coupled to M output terminals of the sequencer circuitry 1024, respectively. In the example of FIG. 10, the first input terminals of the multiplexer circuits 1022₀-1022_{M-1} are coupled to the output terminals of the sub-LUTs 1008₀-1008_{M-1}, respectively, and the second input terminals of the multiplexer circuits 1022₀-1022_{M-1} are coupled to the output terminals of the sub-LUTs 1012₀-1012_{M-1}, respectively.

In the illustrated example of FIG. 10, the sequencer circuitry 1024 is implemented by digital circuitry. In the example of FIG. 10, an output terminal of the sequencer circuitry 1024 is coupled to the control terminal of the multiplexer circuit 1014. Also, M output terminals of the sequencer circuitry 1024 are coupled to the control terminals of the multiplexer circuits 1018₀-1018_{M-1}, respectively. In the example of FIG. 10, M output terminals of the sequencer circuitry 1024 are coupled to the control terminals of the multiplexer circuits 1022₀-1022_{M-1}, respectively.

As described above, the concatenated LUT 1004 is indexed by a version of an envelope of an input signal that is delayed by a common delay shared between the sub-LUTs 1010₀-1010_{M-1}. As such, the values output by each of the sub-LUTs 1010₀-1010_{M-1} correspond to the common delay with which the concatenated LUT 1004 was indexed. In the example of FIG. 10, example delay circuitry 1016₀-1016_{M-1} applies respective delays to the values output by the sub-LUTs 1010₀-1010_{M-1} to realize the delays specified by at least one of Equation 1 or Equation 2 above. In the example of FIG. 10, each instance of the delay circuitry 1016₀-1016_{M-1} applies a delay to a value output by the sub-LUTs 1010₀-1010_{M-1}, respectively. For example, M registers associated with respective instances of the delay circuitry 1016₀-1016_{M-1} can be programmed at startup of the transceiver circuitry 1000 to configure the delays of each instance of the delay circuitry 1016₀-1016_{M-1} based on the l₂(k) delay to be applied to the envelope of the input signal according to at least one of Equation 1 or Equation 2 above. As such, respective instances of the delay circuitry 1016₀-1016_{M-1} may apply different delays to values output by the sub-LUTs 1010₀-1010_{M-1}.

Similarly, the concatenated LUT 1006 is indexed by a version of an envelope of an input signal that is delayed by a common delay shared between the sub-LUTs 1012₀-1012_{M-1}. As such, the values output by each of the sub-LUTs 1012₀-1012_{M-1} correspond to the common delay with which the concatenated LUT 1006 was indexed. In the example of FIG. 10, example delay circuitry 1020₀-1020_{M-1} applies respective delays to the values output by the sub-LUTs 1012₀-1012_{M-1} to realize the delays specified by at least one of Equation 1 or Equation 2 above. In the example of FIG. 10, each instance of the delay circuitry 1020₀-1020_{M-1} applies a delay to a value output by the sub-LUTs 1012₀-1012_{M-1}, respectively. For example, M registers associated with respective instances of the delay circuitry 1020₀-1020_{M-1} can be programmed at startup of the transceiver circuitry 1000 to configure the delays of each instance of the delay circuitry 1020₀-1020_{M-1} based on the l₂(k) delay to be applied to the envelope of the input signal according to at least one of Equation 1 or Equation 2 above. As such, respective instances of the delay circuitry 1020₀-1020_{M-1} may apply different delays to values output by the sub-LUTs 1012₀-1012_{M-1}.

In the illustrated example of FIG. 10, the spare concatenated LUT 1002 facilitates updating of at least one of the concatenated LUT 1004 or the concatenated LUT 1006. For example, DPD estimator circuitry (e.g., the DPD estimator circuitry 124 of FIG. 1B) can update the sub-LUTs 1008₀-1008_{M-1} of the spare concatenated LUT 1002 while the transceiver circuitry 1000 utilizes at least one of the concatenated LUT 1004 to perform DPD correction in the first instance of transmitter circuitry of the transceiver circuitry 1000 or the concatenated LUT 1006 to perform DPD correction in the second instance of transmitter circuitry of the transceiver circuitry 1000. In the example of FIG. 10, because the values output from concatenated LUT 1004 and the concatenated LUT 1006 may be delayed by different amounts, the sequencer circuitry 1024 sequences at least one of the switch from the concatenated LUT 1004 to the spare concatenated LUT 1002 or the switch from the concatenated LUT 1006 to the spare concatenated LUT 1002. For example, the sequencer circuitry 1024 may implement any of the sequencer circuitry 410 of FIG. 4, the sequencer circuitry 710 of FIG. 7, or the sequencer circuitry 908 of FIG. 9.

In the illustrated example of FIG. 10, after DPD estimator circuitry (e.g., the DPD estimator circuitry 124 of FIG. 1B) updates the spare concatenated LUT 1002 with updated values to compensate for non-linearity of PA circuitry, the sequencer circuitry 1024 switches at least one of the concatenated LUT 1004 or the concatenated LUT 1006 to the spare concatenated LUT 1002. In the example of FIG. 10, the sequencer circuitry 1024 selects a first sub-LUT of the concatenated LUT 1004 that is associated with first delay circuitry having a largest delay. For example, the sequencer circuitry selects the sub-LUT 1010₀ as the delay circuitry 1016₀ has a largest delay of the instances of the delay circuitry 1016₀-1016_{M-1}.

In the illustrated example of FIG. 10, the sequencer circuitry 1024 switches a multiplexer circuit associated with the first delay circuitry from (a) the first sub-LUT to (b) a corresponding sub-LUT of the spare concatenated LUT 1002. For example, the sequencer circuitry 1024 switches the multiplexer circuit 1018₀ from the sub-LUT 1010₀ to the sub-LUT 1008₀ of the spare concatenated LUT 1002. As such, some of the multiplexer circuits 1018₀-1018_{M-1} read from the concatenated LUT 1004 and the spare concatenated LUT 1002 during the switching sequence. In the example of FIG. 10, after the sequencer circuitry 1024 switches the multiplexer circuit associated with the first delay circuitry from (a) the first sub-LUT to (b) the corresponding sub-LUT of the spare concatenated LUT 1002, the sequencer circuitry 1024 determines whether there is an additional sub-LUT of the concatenated LUT 1004 to be updated.

In the illustrated example of FIG. 10, responsive to (e.g., based on) the sequencer circuitry 1024 determining that there is an additional sub-LUT of the concatenated LUT 1004 to be updated, the sequencer circuitry 1024 increments a counter. For example, the sequencer circuitry 1024 maintains a counter to track the number of clock cycles that have elapsed since switching a multiplexer from the concatenated LUT 1004 to the spare concatenated LUT 1002. In the example of FIG. 10, the sequencer circuitry 1024 determines whether a value of the counter is equal to a difference between (a) the delay of the first delay circuitry and (b) a next largest delay. For example, the sequencer circuitry 1024 determines whether a value of the counter is equal to a difference between (a) the delay of the delay circuitry 1016₀ and (b) a next largest delay of the instances of the delay circuitry 1016₀-1016_{M-1} (e.g., the delay of the delay circuitry 1016₁).

Responsive to (e.g., based on) the sequencer circuitry 1024 determining that the value of the counter is not equal to the difference between (a) the delay of the first delay circuitry and (b) the next largest delay, the sequencer circuitry 1024 increments the counter. Responsive to (e.g., based on) the sequencer circuitry 1024 determining that the value of the counter is equal to the difference between (a) the delay of the first delay circuitry and (b) the next largest delay, the sequencer circuitry 1024 selects a next sub-LUT of the concatenated LUT 1004 that is associated with next delay circuitry having the next largest delay. For example, the sequencer circuitry selects the sub-LUT 1010₁ as the delay circuitry 1016₁ has the next largest delay of the instances of the delay circuitry 1016₀-1016_{M-1} after the delay circuitry 1016₀.

In the illustrated example of FIG. 10, the sequencer circuitry 1024 switches a multiplexer circuit associated with the next delay circuitry from (a) the next sub-LUT to (b) a corresponding sub-LUT of the spare concatenated LUT 1002. For example, the sequencer circuitry 1024 switches the multiplexer circuit 1018₁ from the sub-LUT 1010₁ to the sub-LUT 1008₁ of the spare concatenated LUT 1002. The sequencer circuitry 1024 repeats the above-described process until there are no additional sub-LUTs of the concatenated LUT 1004 to be updated. After the sub-LUTs of the concatenated LUT 1004 have been updated by the sequencer circuitry 1024, DPD estimator circuitry (e.g., the DPD estimator circuitry 124) loads the concatenated LUT 1004 with the updated values from the spare concatenated LUT 1002. Also, the sequencer circuitry 1024 switches the multiplexer circuits 1018₀-1018_{M-1} from (a) the spare concatenated LUT 1002 to (b) the concatenated LUT 1004.

In the illustrated example of FIG. 10, the sequencer circuitry 1024 determines if there is an additional instance of transmitter circuitry corresponding to the spare concatenated LUT 1002. Responsive to (e.g., based on) the sequencer circuitry 1024 determining that there is an additional instance of transmitter circuitry corresponding to the spare concatenated LUT 1002 (e.g., the second instance of transmitter circuitry), the sequencer circuitry 1024 repeats the above-described process until there are no additional instances of transmitter circuitry corresponding to the spare concatenated LUT 1002.

Accordingly, the sequencer circuitry 1024 performs seamless switching between current and updated values for the concatenated LUT 1004 and the concatenated LUT 1006. As described above, the spare concatenated LUT 1002 is time-shared across multiple instances of DPD corrector circuitry of the transceiver circuitry 1000 (e.g., across multiple instance of transmitter circuitry of the transceiver circuitry 1000). As such, the amount of area to implement spare LUTs is reduced as a smaller number of spare LUTs can be utilized. For example, assuming that the two instances of transmitter circuitry are updated at the same time. To facilitate staggered updates of concatenated LUTs in instances of transmitter circuitry, DPD estimator circuitry (e.g., the DPD estimator circuitry 124 of FIG. 1B) can estimate updated values at a time interval that is greater than the time interval at which the sequencer circuitry 1024 updates the LUTs (e.g., the DPD estimator circuitry 124 can estimate updated values every 100 milliseconds (ms) and the sequencer circuitry 1024 can update the LUTs every 5 ms).

While the example of FIG. 10 describes example operation of the sequencer circuitry 1024 with respect to updating an instance of transmitter circuitry including one concatenated LUT (e.g., the concatenated LUT 1004 of the first instance of transmitter circuitry, the concatenated LUT 1006 of the second instance of transmitter circuitry), the example operation of the sequencer circuitry 1024 is likewise applicable to an instance of transmitter circuitry including any number of concatenated LUTs. For example, the sequencer circuitry 1024 sequences the switch of delay circuitry (e.g., the delay circuitry 1016₀-1016_{M-1}, the delay circuitry 1016₀-1016_{M-1}, etc.) from main concatenated LUTs to spare concatenated LUTs such that the values output from each instance of the delay circuitry (e.g., the delay circuitry 1016₀-1016_{M-1}, the delay circuitry 1016₀-1016_{M-1}, etc.) switch to updated values from DPD estimator circuitry (e.g., the DPD estimator circuitry 124) in the same clock cycle.

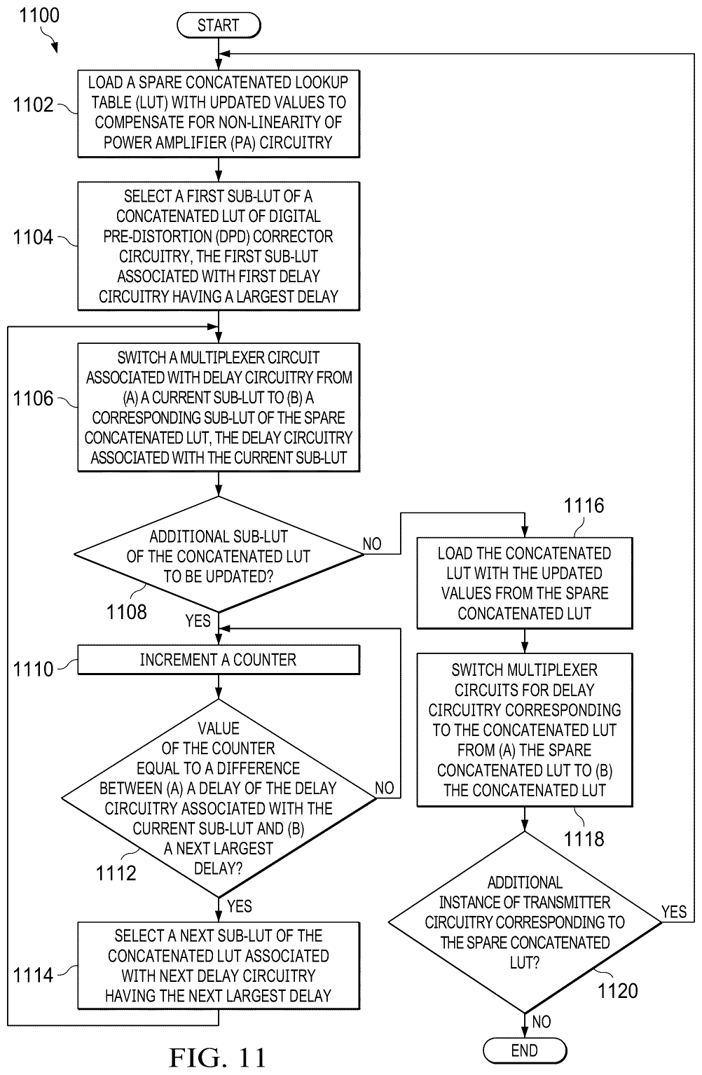

FIG. 11 is a flowchart representative of at least one of example machine-readable instructions or example operations 1100 that may be at least one of executed, instantiated, or performed using example programmable circuitry to update one or more concatenated LUTs. The at least one of example machine-readable instructions or example operations 1100 of FIG. 11 begin at block 1102, at which DPD estimator circuitry (e.g., the DPD estimator circuitry 124 of FIG. 1B) updates a spare concatenated LUT with updated values to compensate for non-linearity of PA circuitry. At block 1104, sequencer circuitry selects a first sub-LUT of a concatenated LUT of DPD corrector circuitry, the first sub-LUT associated with first delay circuitry having a largest delay. For example, any of the sequencer circuitry 410 of FIG. 4, the sequencer circuitry 710 of FIG. 7, the sequencer circuitry 908 of FIG. 9, or the sequencer circuitry 1024 of FIG. 10 can perform block 1104.

In the illustrated example of FIG. 11, at block 1106, the sequencer circuitry switches a multiplexer circuit associated with delay circuitry from (a) a current sub-LUT (e.g., a current sub-lookup table) to (b) a corresponding sub-LUT of the spare concatenated LUT, the delay circuitry associated with the current sub-LUT. For example, any of the sequencer circuitry 410 of FIG. 4, the sequencer circuitry 710 of FIG. 7, the sequencer circuitry 908 of FIG. 9, or the sequencer circuitry 1024 of FIG. 10 can perform block 1106. At block 1108, the sequencer circuitry determines whether there is an additional sub-LUT of the concatenated LUT to be updated. For example, any of the sequencer circuitry 410 of FIG. 4, the sequencer circuitry 710 of FIG. 7, the sequencer circuitry 908 of FIG. 9, or the sequencer circuitry 1024 of FIG. 10 can perform block 1108.

Responsive to (e.g., based on) the sequencer circuitry determining that there is not an additional sub-LUT of the concatenated LUT to be updated (block 1108: NO), the at least one of machine-readable instructions or operations 1100 proceed to block 1116. Responsive to (e.g., based on) the sequencer circuitry determining that there is an additional sub-LUT of the concatenated LUT to be updated (block 1108: YES), the at least one of machine-readable instructions or operations 1100 proceed to block 1110. At block 1110, the sequencer circuitry increments a counter. For example, any of the sequencer circuitry 410 of FIG. 4, the sequencer circuitry 710 of FIG. 7, the sequencer circuitry 908 of FIG. 9, or the sequencer circuitry 1024 of FIG. 10 can perform block 1110.

In the illustrated example of FIG. 11, at block 1112, the sequencer circuitry determines whether a value of the counter is equal to a difference between (a) a delay of the delay circuitry associated with the current sub-LUT and (b) a next largest delay. For example, any of the sequencer circuitry 410 of FIG. 4, the sequencer circuitry 710 of FIG. 7, the sequencer circuitry 908 of FIG. 9, or the sequencer circuitry 1024 of FIG. 10 can perform block 1112. Responsive to (e.g., based on) the sequencer circuitry determining that the value of the counter is not equal to the difference between (a) the delay of the delay circuitry associated with the current sub-LUT and (b) the next largest delay (block 1112: NO), the at least one of machine-readable instructions or operations 1100 return to block 1110. Responsive to (e.g., based on) the sequencer circuitry determining that the value of the counter is equal to the difference between (a) the delay of the delay circuitry associated with the current sub-LUT and (b) the next largest delay (block 1112: YES), the at least one of machine-readable instructions or operations 1100 proceed to block 1114.

In the illustrated example of FIG. 11, at block 1114, the sequencer circuitry selects a next sub-LUT of the concatenated LUT of associated with next delay circuitry having the next largest delay and the at least one of machine-readable instructions or operations 1100 return to block 1106. For example, any of the sequencer circuitry 410 of FIG. 4, the sequencer circuitry 710 of FIG. 7, the sequencer circuitry 908 of FIG. 9, or the sequencer circuitry 1024 of FIG. 10 can perform block 1114. At block 1116, the DPD estimator circuitry (e.g., the DPD estimator circuitry 124) loads the concatenated LUT with the updated values from the spare concatenated LUT. At block 1118, the sequencer circuitry switches the multiplexer circuits for delay circuitry corresponding to the concatenated LUT from (a) the spare concatenated LUT to (b) the concatenated LUT. For example, any of the sequencer circuitry 410 of FIG. 4, the sequencer circuitry 710 of FIG. 7, the sequencer circuitry 908 of FIG. 9, or the sequencer circuitry 1024 of FIG. 10 can perform block 1118.

In the illustrated example of FIG. 11, at block 1120, the sequencer circuitry determines if there is an additional instance of transmitter circuitry corresponding to the spare concatenated LUT. For example, any of the sequencer circuitry 410 of FIG. 4, the sequencer circuitry 710 of FIG. 7, the sequencer circuitry 908 of FIG. 9, or the sequencer circuitry 1024 of FIG. 10 can perform block 1120. Responsive to (e.g., based on) the sequencer circuitry determining that there is an additional instance of transmitter circuitry corresponding to the spare concatenated LUT (block 1120: YES), the at least one of machine-readable instructions or operations 1100 return to block 1102. Responsive to (e.g., based on) the sequencer circuitry determining that there is not an additional instance of transmitter circuitry corresponding to the spare concatenated LUT (block 1120: NO), the at least one of machine-readable instructions or operations 1100 terminate.

While the example of FIG. 11 describes example operation of the sequencer circuitry of any of FIG. 4, 7, 9, or 10 with respect to updating an instance of transmitter circuitry including one concatenated LUT, the example operation of the sequencer circuitry of any of FIG. 4, 7, 9, or 10 is likewise applicable to an instance of transmitter circuitry including any number of concatenated LUTs. For example, the sequencer circuitry of any of FIG. 4, 7, 9, or 10 sequences the switch of delay circuitry (e.g., the delay circuitry 906₀-906_{M-1}, the delay circuitry 1016₀-1016_{M-1}, the delay circuitry 1016₀-1016_{M-1}, etc.) from main concatenated LUTs to spare concatenated LUTs such that the values output from each instance of the delay circuitry (e.g., the delay circuitry 906₀-906_{M-1}, the delay circuitry 1016₀-1016_{M-1}, the delay circuitry 1016₀-1016_{M-1}, etc.) switch to updated values from DPD estimator circuitry (e.g., the DPD estimator circuitry 124) in the same clock cycle.

FIG. 12 is a block diagram of a first example implementation of an example LUT 1200 that supports parallelization. As described above, the DPD corrector circuitry 106 of any of FIG. 2, 4, 5, 6A, or 7 is parallelized-by-two. For example, the DPD corrector circuitry 106 can be parallelized-by-two to facilitate operation at a higher sampling rate while also operating at a lower clock rate. As such, the LUT 1200 supports access from a first instance of the circuitry of any one of FIG. 2, 4, 5, 6A, or 7 and access from a second instance of the circuitry of FIG. 2, 4, 5, 6A, or 7 in the same clock cycle. Additional instances of the circuitry of any one of FIG. 2, 4, 5, 6A, or 7 may be implemented to support additional parallelization (e.g., three instances of the circuitry of any one of FIG. 2, 4, 5, 6A, or 7 to support a parallelized-by-three implementation, four instances of the circuitry of any one of FIG. 2, 4, 5, 6A, or 7 to support a parallelized-by-four implementation, etc.).

In the illustrated example of FIG. 12, the LUT 1200 includes example input mapping circuitry 1202, first example memory 1204, second example memory 1206, and example output mapping circuitry 1208. In the example of FIG. 12, the LUT 1200 is an R-entry memory that stores data representative of non-linear base-band functions ƒₖ( ). For example, the LUT 1200 is structured to store 512 entries of data (e.g., 512 32-bit values). In the example of FIG. 12, the input mapping circuitry 1202 has a first output terminal, a second output terminal, a third output terminal, a first input terminal, and a second input terminal. Also, each of the memory 1204 and the memory 1206 has an output terminal and an input terminal. In the example of FIG. 12, the output mapping circuitry 1208 includes a first output terminal, a second output terminal, a control terminal, a first input terminal, and a second input terminal.

In the illustrated example of FIG. 12, the input mapping circuitry 1202 is implemented by digital circuitry. In the example of FIG. 12, the first output terminal of the input mapping circuitry 1202 is coupled to the input terminal of the memory 1204. Also, the second output terminal of the input mapping circuitry 1202 is coupled to the input terminal of the memory 1206. In the example of FIG. 12, the third output terminal of the input mapping circuitry 1202 is coupled to the control terminal of the output mapping circuitry 1208. In the example of FIG. 12, the first input terminal of the input mapping circuitry 1202 is coupled to a first instance of the circuitry of any one of FIG. 2, 4, 5, 6A, or 7 and the second input terminal of the input mapping circuitry 1202 is coupled to a second instance of the circuitry of FIG. 2, 4, 5, 6A, or 7.

In the illustrated example of FIG. 12, the memory 1204 is implemented by an R/2-entry memory that stores even indexed entries (e.g., is to store even indexed entries) of the non-linear base-band functions ƒₖ( ) stored in the LUT 1200. For example, the memory 1204 stores 256 entries of data (e.g., 256 32-bit values). In the example of FIG. 12, the output terminal of the memory 1204 is coupled to the first input terminal of the output mapping circuitry 1208. Also, the input terminal of the memory 1204 is coupled to the first output terminal of the input mapping circuitry 1202.

In the illustrated example of FIG. 12, the memory 1206 is implemented by an R/2-entry memory that stores odd indexed entries (e.g., is to store odd indexed entries) of the non-linear base-band functions ƒₖ( ) stored in the LUT 1200. For example, the memory 1206 stores 256 entries of data (e.g., 256 32-bit values). In the example of FIG. 12, the output terminal of the memory 1206 is coupled to the second input terminal of the output mapping circuitry 1208. Also, the input terminal of the memory 1206 is coupled to the second output terminal of the input mapping circuitry 1202.

In the illustrated example of FIG. 12, the output mapping circuitry 1208 is implemented by one or more multiplexer circuits. In the example of FIG. 12, the first output terminal of the output mapping circuitry 1208 is coupled to a first instance of the circuitry of any one of FIG. 2, 4, 5, 6A, or 7 and the second output terminal of the output mapping circuitry 1208 is coupled to a second instance of the circuitry of FIG. 2, 4, 5, 6A, or 7. In the example of FIG. 12, the first input terminal of the output mapping circuitry 1208 is coupled to the output terminal of the memory 1204 and the second input terminal of the output mapping circuitry 1208 is coupled to the output terminal of the memory 1206. Also, the control terminal of the output mapping circuitry 1208 is coupled to the third output terminal of the input mapping circuitry 1202.

In the illustrated example of FIG. 12, the input mapping circuitry 1202 indexes both of the memory 1204 and the memory 1206 each clock cycle to generate two values for the non-linear base-band functions in the same clock cycle. In the example of FIG. 12, the memory 1204 and the memory 1206 are indexed using (R_{ind}−1) bit values, where R_{ind}=log₂R. For example, the memory 1204 and the memory 1206 are indexed using 8-bit values (e.g., R_{ind}=log₂(512)=9, R_{ind}−1=9−1=8). To convert a first sample of an input signal (e.g., |x(n)|) and a second sample of the input signal (e.g., |x(n+1)|) to Ring bit values, the input mapping circuitry 1202 quantizes the first sample (e.g., |x(n)|) and the second sample (e.g., |x(n+1)|). As described above, the input mapping circuitry 1202 indexes both of the memory 1204 and the memory 1206 each clock cycle to generate two values for the non-linear base-band functions in the same clock cycle. As such, n sample index (e.g., n) of the input signal (e.g., |x(n)|) is incremented by two every clock cycle.

In the illustrated example of FIG. 12, the input mapping circuitry 1202 determines if a first quantized sample (e.g., |x_{q}(n)|) and a second quantized sample (e.g., |x_{q}(n+1)|) are both even or both odd. For example, because of the quantization, there is a 50% probability that the least significant bits (LSBs) of the first quantized sample (e.g., |x_{q}(n)|) and the second quantized sample (e.g., |x_{q}(n+1)|) would be different. If the LSBs of the first quantized sample (e.g., |x_{q}(n)|) and the second quantized sample (e.g., |x_{q}(n+1)|) are the same (e.g., indicating that the values are either both odd or both even), then the input mapping circuitry 1202 perturbs (e.g., increments or decrements by one), the LSB of one of the first quantized sample (e.g., |x_{q}(n)|) or the second quantized sample (e.g., |x_{w}(n+1)|).

For example, if both the first quantized sample (e.g., |x_{q}(n)|) and the second quantized sample (e.g., |x_{q}(n+1)|) are even or both the first quantized sample (e.g., |x_{q}(n)|) and the second quantized sample (e.g., |x_{q}(n+1)|) are odd, then the input mapping circuitry 1202 perturbs one of the first quantized sample (e.g., |x_{q}(n)|) or the second quantized sample (e.g., |x_{q}(n+1)|). In the example of FIG. 12, the input mapping circuitry 1202 perturbs one of the first quantized sample (e.g., |x_{q}(n)|) or the second quantized sample (e.g., |x_{q}(n+1)|) such that one of the first quantized sample (e.g., |x_{q}(n)|) or the second quantized sample (e.g., |x_{q}(n+1)|) is mapped to an even index m₀, while the other one of the first quantized sample (e.g., |x_{q}(n)|) or the second quantized sample (e.g., |x_{q}(n+1)|) is mapped to an odd index m₁. For example, the input mapping circuitry 1202 perturbs one of the first quantized sample (e.g., |x_{q} (n)|) or the second quantized sample (e.g., |x_{q}(n+1)|) that has a larger quantization error as compared to the first sample (e.g., |x(n)|) and the second sample (e.g., |x(n+1)|), respectively.

In the illustrated example of FIG. 12, after the input mapping circuitry 1202 perturbs one of the first quantized sample (e.g., |x_{q}(n)|) or the second quantized sample (e.g., |x_{q}(n+1)|), the input mapping circuitry 1202 indexes the memory 1204 and the memory 1206 using R_{ind}−1 bit versions of the first quantized sample (e.g., |x_{q} (n)|) and the second quantized sample (e.g., |x_{q}(n+1)|). For example, the input mapping circuitry 1202 drops the LSB of the first quantized sample (e.g., |x_{q}(n)|) and the second quantized sample (e.g., |x_{q}(n+1)|) before indexing the memory 1204 and the memory 1206. In the example of FIG. 12, if, after perturbing one of the first quantized sample (e.g., |x_{q}(n)|) or the second quantized sample (e.g., |x_{q}(n+1)|), the first quantized sample (e.g., |x_{q}(n)|) is even, then the input mapping circuitry 1202 indexes the memory 1204 with the first quantized sample (e.g., |x_{q}(n)|) and indexes the memory 1206 with the second quantized sample (e.g., |x_{q} (n+1)|). Alternatively, if, after perturbing one of the first quantized sample (e.g., |x_{q} (n)|) or the second quantized sample (e.g., |x_{q}(n+1)|), the first quantized sample (e.g., |x_{q} (n)|) is odd, then the input mapping circuitry 1202 indexes the memory 1204 with the first quantized sample (e.g., |x_{q}(n)|) and indexes the memory 1206 with the second quantized sample (e.g., |x_{q} (n+1)|).

As such, the input mapping circuitry 1202 indexes both the memory 1204 and the memory 1206 every clock cycle regardless of whether the first quantized sample (e.g., |x_{q}(n)|) and the second quantized sample (e.g., x_{q}(n+1)|) are both even or both odd. Also, because the memory 1204 stores even indexed non-linear entries of the LUT 1200, the memory 1206 stores odd indexed non-linear entries of the LUT 1200, and the input mapping circuitry 1202 indexes both the memory 1204 and the memory 1206 every clock cycle, the LUT 1200 supports parallelization with less (e.g., 50% less) memory than other techniques. For example, the LUT 1200 supports parallelized access to 512 entries of 32-bit values by splitting the 512 entries between two 256 entry memories whereas other techniques support parallelized access to 512 entries of 32-bit values by duplicating 512 entries of 32-bit values across two memories (e.g., for a total of 1024 entries of 32-bits of data).

In the illustrated example of FIG. 12, the output mapping circuitry 1208 generates a first output (e.g., y(n)) corresponding to the first sample of the input signal (e.g., |x(n)|) and a second output (e.g., y(n+1)) corresponding to the second sample of the input signal (e.g., |x(n+1)|). In the example of FIG. 12, the output mapping circuitry 1208 operates based on a control signal from the input mapping circuitry 1202. For example, based on the control signal, the output mapping circuitry 1208 either passes the values output the memory 1204 and the memory 1206 as the first output (e.g., y(n)) and the second output (e.g., y(n+1)), or swaps the values to provide the first output (e.g., y(n)) and the second output (e.g., y(n+1)). For example, if the input mapping circuitry 1202 indexes the memory 1204 with the first quantized sample (e.g., |x_{q}(n)|), then the output mapping circuitry 1208 provides the output of the memory 1204 (e.g., LUT(m₀)) and the output of the memory 1206 (e.g., LUT(m₁)) as the first output (e.g., y(n)) and the second output (e.g., y(n+1)), respectively. Alternatively, if the input mapping circuitry 1202 indexes the memory 1204 with the second quantized sample (e.g., |x_{q}(n+1)|), then the output mapping circuitry 1208 provides the output of the memory 1206 (e.g., LUT(m₁)) and the output of the memory 1204 (e.g., LUT(m₀)) as the first output (e.g., y(n)) and the second output (e.g., y(n+1)), respectively.

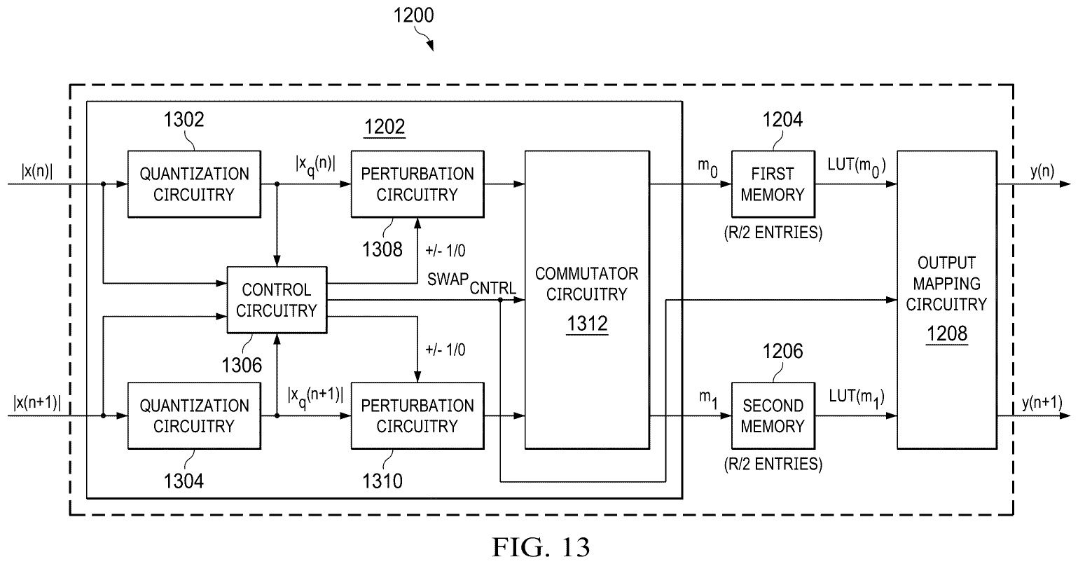

FIG. 13 is a block diagram of an example implementation of the input mapping circuitry 1202 of FIG. 12. In the example of FIG. 13, the input mapping circuitry 1202 includes first example quantization circuitry 1302, second example quantization circuitry 1304, example control circuitry 1306, first example perturbation circuitry 1308, second example perturbation circuitry 1310, and example commutator circuitry 1312. In the example of FIG. 13, each of the quantization circuitry 1302 and the quantization circuitry 1304 has an output terminal and an input terminal.

In the illustrated example of FIG. 13, the control circuitry 1306 has a first output terminal, a second output terminal, a third output terminal, a first input terminal, a second input terminal, a third input terminal, and a fourth input terminal. In the example of FIG. 13, each of the perturbation circuitry 1308 and the perturbation circuitry 1310 has an output terminal, a first input terminal, and a second input terminal. Also, the commutator circuitry 1312 has a first output terminal, a second output terminal, a control terminal, a first input terminal, and a second input terminal.

In the illustrated example of FIG. 13, each of the quantization circuitry 1302 and the quantization circuitry 1304 is implemented by digital circuitry. In the example of FIG. 13, the output terminal of the quantization circuitry 1302 is coupled to the first input terminal of the control circuitry 1306 and the first input terminal of the perturbation circuitry 1308. Also, the input terminal of the quantization circuitry 1302 is coupled to a first instance of the circuitry of any one of FIG. 2, 4, 5, 6A, or 7. In the example of FIG. 13, the output terminal of the quantization circuitry 1304 is coupled to the fourth input terminal of the control circuitry 1306 and the first input terminal of the perturbation circuitry 1310. Also, the input terminal of the quantization circuitry 1304 is coupled to a second instance of the circuitry of any one of FIG. 2, 4, 5, 6A, or 7.

In the illustrated example of FIG. 13, the control circuitry 1306 is implemented by digital circuitry. In the example of FIG. 13, the first output terminal of the control circuitry 1306 is coupled to the second input terminal of the perturbation circuitry 1308. Also, the second output terminal of the control circuitry 1306 is coupled to the second input terminal of the perturbation circuitry 1310. In the example of FIG. 13, the third output terminal of the control circuitry 1306 is coupled to the control terminal of the output mapping circuitry 1208 and the control terminal of the commutator circuitry 1312.

In the illustrated example of FIG. 13, the first input terminal of the control circuitry 1306 is coupled to the output terminal of the quantization circuitry 1302. In the example of FIG. 13, the second input terminal of the control circuitry 1306 is coupled to a first instance of the circuitry of any one of FIG. 2, 4, 5, 6A, or 7. Also, the third input terminal of the control circuitry 1306 is coupled to a second instance of the circuitry of any one of FIG. 2, 4, 5, 6A, or 7. In the example of FIG. 13, the fourth input terminal of the control circuitry 1306 is coupled to the output terminal of the quantization circuitry 1304.

In the illustrated example of FIG. 13, each of the perturbation circuitry 1308 and the perturbation circuitry 1310 is implemented by digital circuitry. In the example of FIG. 13, the output terminal of the perturbation circuitry 1308 is coupled to the first input terminal of the commutator circuitry 1312. Also, the first input terminal of the perturbation circuitry 1308 is coupled to the output terminal of the quantization circuitry 1302 and the second input terminal of the perturbation circuitry 1308 is coupled to the first output terminal of the control circuitry 1306. In the example of FIG. 13, the output terminal of the perturbation circuitry 1310 is coupled to the second input terminal of the commutator circuitry 1312. Also, the first input terminal of the perturbation circuitry 1310 is coupled to the output terminal of the quantization circuitry 1304 and the second input terminal of the perturbation circuitry 1310 is coupled to the second output terminal of the control circuitry 1306.

In the illustrated example of FIG. 13, the commutator circuitry 1312 is implemented by one or more multiplexer circuits. In the example of FIG. 13, the first output terminal of the commutator circuitry 1312 is coupled to the input terminal of the memory 1204 and the second output terminal of the commutator circuitry 1312 is coupled to the input terminal of the memory 1206. Also, the control terminal of the commutator circuitry 1312 is coupled to the third output terminal of the control circuitry 1306. In the example of FIG. 13, the first input terminal of the commutator circuitry 1312 is coupled to the output terminal of the perturbation circuitry 1308 and the second input terminal of the commutator circuitry 1312 is coupled to the output terminal of the perturbation circuitry 1310.

In the illustrated example of FIG. 13, the quantization circuitry 1302 quantizes a first sample of an input signal (e.g., |x(n)|) to an R_{ind} bit value. Also, the quantization circuitry 1304 quantizes a second sample of an input signal (e.g., |x(n+1)|) to an R_{ind} bit value. In the example of FIG. 13, the control circuitry 1306 determines if a first quantized sample (e.g., |x_{q}(n)|) and a second quantized sample (e.g., |x_{q}(n+1)|) are both even or both odd. For example, the control circuitry 1306 implements Equation 5 below to determine the remainder of the first quantized sample (e.g., |x_{q} (n)|) and the second quantized sample (e.g., |x_{q}(n+1)|) when divided by two.

$$I ( n ) = mod \{ \vert {x}_{q} ( n ) \vert , 2 \} \qquad Equation 5$$

In the illustrated example of FIG. 13, if the remainder of the first quantized sample (e.g., |x_{q}(n)|) and the remainder of the second quantized sample (e.g., |x_{q}(n+1)|) are equal (e.g., I(n)=I(n+1)), then the control circuitry 1306 determines the error between the input samples and the quantized versions of the input samples. For example, the control circuitry 1306 determines (1) a first error between the first sample (e.g., |x(n)|) and the first quantized sample (e.g., |x_{q}(n)|) and (2) a second error between the second sample (e.g., |x(n+1)|) and the second quantized sample (e.g., |x_{q} (n+1)|) according to Equation 6 below.

$$e ( n ) = \vert x ( n ) \vert - \frac{\vert {x}_{q} ( n ) \vert}{R} \qquad Equation 6$$

In the illustrated example of FIG. 13, if the absolute value of the first error is greater than the absolute value of the second error (e.g., abs(e(n))>abs(e(n−1))), then the control circuitry 1306 instructs (1) the perturbation circuitry 1308 to perturb the first quantized sample (e.g., |x_{q}(n)|) according to Equation 7 below and (2) the perturbation circuitry 1310 to perturb the second quantized sample (e.g., |x_{q}(n+1)|) according to Equation 8 below.

$$\vert {x}_{q}^{′} ( n ) \vert = \vert {x}_{q} ( n ) \vert + sign \{ e ( n ) \} \qquad Equation 7$$

$$\vert {x}_{q}^{′} ( n + 1 ) \vert = \vert {x}_{q} ( n + 1 ) \vert \qquad Equation 8$$

In the illustrated example of FIG. 13, if the absolute value of the first error is less than or equal to the absolute value of the second error (e.g., abs(e(n))≤abs(e(n−1))), then the control circuitry 1306 instructs (1) the perturbation circuitry 1308 to perturb the first quantized sample (e.g., |x_{q} (n)|) according to Equation 9 below and (2) the perturbation circuitry 1310 to perturb the second quantized sample (e.g., |x_{q}(n+1)|) according to Equation 10 below.

$$\vert {x}_{q}^{′} ( n ) \vert = \vert {x}_{q} ( n ) \vert \qquad Equation 9$$

$$\vert {x}_{q}^{′} ( n + 1 ) \vert = \vert {x}_{q} ( n + 1 ) \vert + sign \{ e ( n + 1 ) \} \qquad Equation 10$$

In Equations 7 and 10, the sign( ) function returns a value of one if the input to the sign( ) function is a positive value. Also, the sign( ) function returns a value of negative one if the input to the sign( ) function is a non-positive value (e.g., a negative value, a zero value, etc.).

In the illustrated example of FIG. 13, the control circuitry 1306 also determines the remainder of the first perturbed quantized sample (e.g., |x′_{q}(n)|) when divided by two according to Equation 5 above. If the remainder of the first perturbed quantized sample (e.g., |x_{q}′(n) is zero, then the control circuitry 1306 generates a control signal (e.g., SWAP_{CTRL}) at the third output terminal of the control circuitry 1306 as a logic low value (e.g., a “0”). As such, if the remainder of the first perturbed quantized sample (e.g., |x_{q}′(n)|) is zero, then the control circuitry 1306 causes the commutator circuitry 1312 to index the memory 1204 and the memory 1206 according to Equations 11 and 12 below.

$${m}_{0} = \vert {x}_{q}^{′} ( n ) \vert \qquad Equation 11$$

$${m}_{1} = \vert {x}_{q}^{′} ( n + 1 ) \vert \qquad Equation 12$$

In the illustrated example of FIG. 13, if the remainder of the first perturbed quantized sample (e.g., |x_{q}′(n)|) is not zero, then the control circuitry 1306 generates the control signal (e.g., SWAP_{CTRL}) at the third output terminal of the control circuitry 1306 as a logic high value (e.g., a “1”). As such, if the remainder of the first perturbed quantized sample (e.g., |x_{q}′(n)|) is not zero, then the control circuitry 1306 causes the commutator circuitry 1312 to index the memory 1204 and the memory 1206 according to Equation 13 and 14 below.

$${m}_{0} = \vert {x}_{q}^{′} ( n + 1 ) \vert \qquad Equation 13$$

$${m}_{1} = \vert {x}_{q}^{′} ( n ) \vert \qquad Equation 14$$

In the illustrated example of FIG. 13, if the control signal (e.g., SWAP_{CTRL}) at the third output terminal of the control circuitry 1306 is a logic low value (e.g., a “0”), then the output mapping circuitry 1208 provides the output of the memory 1204 (e.g., LUT(m₀)) and the output of the memory 1206 (e.g., LUT(m₁)) as the first output (e.g., y(n)) and the second output (e.g., y(n+1)), respectively. Alternatively, if the control signal (e.g., SWAP_{CTRL}) at the third output terminal of the control circuitry 1306 is a logic high value (e.g., a “1”), then then the output mapping circuitry 1208 provides the output of the memory 1206 (e.g., LUT(m₁)) and the output of the memory 1204 (e.g., LUT(m₀)) as the first output (e.g., y(n)) and the second output (e.g., y(n+1)), respectively.

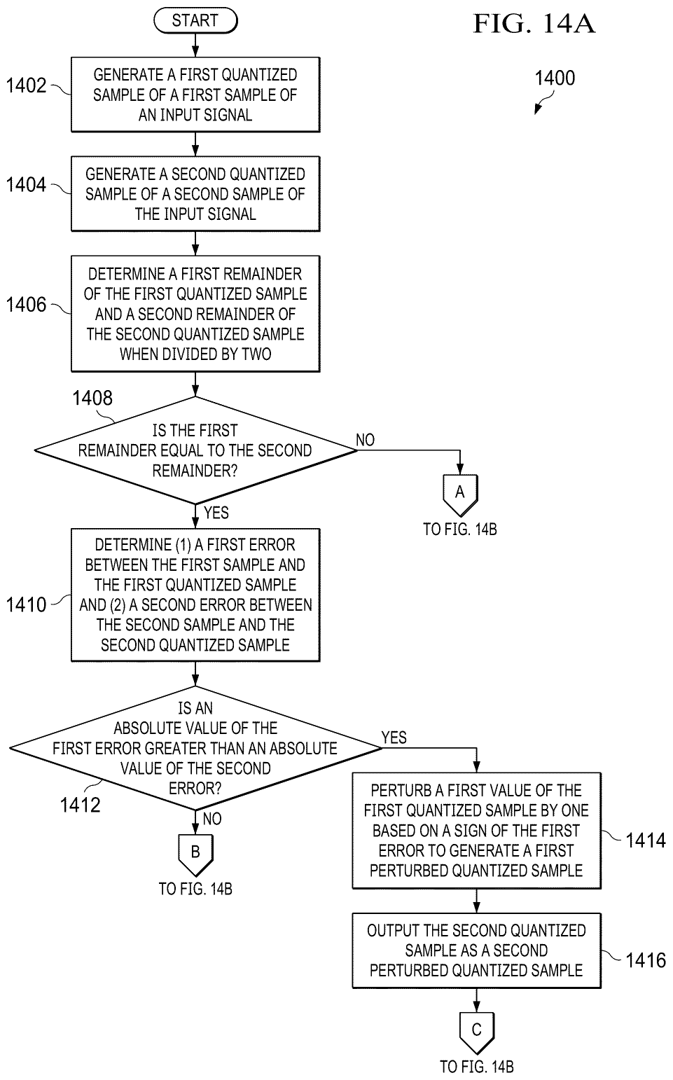

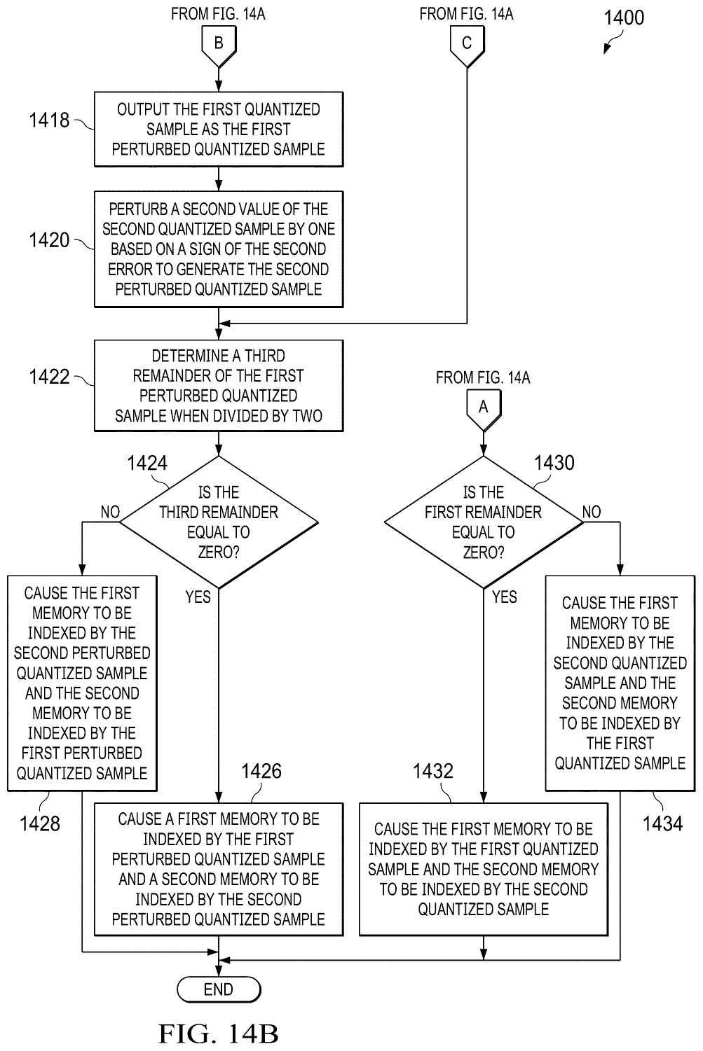

FIG. 14 is a flowchart representative of at least one of example machine-readable instructions or example operations 1400 that may be at least one of executed, instantiated, or performed using an example programmable circuitry implementation of the input mapping circuitry 1202 of any of FIG. 12 or 13. The at least one of example machine-readable instructions or example operations 1400 of FIG. 14 begin at block 1402, at which the quantization circuitry 1302 generates a first quantized sample (e.g., |x_{q}(n)|) of a first sample of an input signal (e.g., |x(n)|). At block 1404 the quantization circuitry 1304 generates a second quantized sample (e.g., |x_{q}(n+1)|) of a second sample of the input signal (e.g., |x(n+1)|).

In the illustrated example of FIG. 14, at block 1406, the control circuitry 1306 determines a first remainder of the first quantized sample (e.g., |x_{q}(n)|) and a second remainder of the second quantized sample (e.g., |x_{q}(n+1)|) when divided by two. For example, the control circuitry 1306 implements Equation 5 above to determine a first remainder of the first quantized sample (e.g., |x_{q}(n)|) and a second remainder of the second quantized sample (e.g., |x_{q}(n+1)|) when divided by two. At block 1408, the control circuitry 1306 determines if the first remainder is equal to the second remainder.

In the illustrated example of FIG. 14, responsive to (e.g., based on) the control circuitry 1306 determining that the first remainder is not equal to the second remainder (block 1408: NO), the at least one of machine-readable instructions or operations 1400 proceed to block 1430. Responsive to (e.g., based on) the control circuitry 1306 determining that the first remainder is equal to the second remainder (block 1408: YES), the at least one of machine-readable instructions or operations 1400 proceed to block 1410. At block 1410, the control circuitry 1306 determines (1) a first error between the first sample (e.g., |x(n)|) and the first quantized sample (e.g., |x_{q}(n)|) and (2) a second error between the second sample (e.g., |x(n+1)|) and the second quantized sample (e.g., |x_{q}(n+1)|). For example, the control circuitry 1306 determines the first error and the second error according to Equation 6 above.

In the illustrated example of FIG. 14, at block 1412, the control circuitry 1306 determines if the absolute value of the first error is greater than the absolute value of the second error. Responsive to (e.g., based on) the control circuitry 1306 determining that the absolute value of the first error is not greater than the absolute value of the second error (block 1412: NO), the at least one of machine-readable instructions or operations 1400 proceed to block 1418. Responsive to (e.g., based on) the control circuitry 1306 determining that the absolute value of the first error is greater than the absolute value of the second error (block 1412: YES), the at least one of machine-readable instructions or operations 1400 proceed to block 1414.

In the illustrated example of FIG. 14, at block 1414, the perturbation circuitry 1308 perturbs a first value of the first quantized sample (e.g., |x_{q}(n)|) by one based on a sign of the first error to generate a first perturbed quantized sample (e.g., |x_{q}′(n)|). For example, the perturbation circuitry 1308 perturbs the first quantized sample (e.g., |x_{q}(n)|) according to Equation 7 above. At block 1416 the perturbation circuitry 1310 outputs the second quantized sample (e.g., |x_{q}(n+1)|) as a second perturbed quantized sample (e.g., |x_{q}′(n+1)|). For example, the perturbation circuitry 1310 outputs the second quantized sample (e.g., |x_{q}(n+1)|) as a second perturbed quantized sample (e.g., |x_{q}′(n+1)|) according to Equation 8 above.

In the illustrated example of FIG. 14, at block 1418, the perturbation circuitry 1308 outputs the first quantized sample (e.g., x_{q} (n)) as the first perturbed quantized sample (e.g., |x_{q}′(n)|). For example, the perturbation circuitry 1308 outputs the first quantized sample (e.g., |x_{q}(n)|) as the first perturbed quantized sample (e.g., |x_{q}′(n)|) according to Equation 9 above. At block 1420, the perturbation circuitry 1310 perturbs a second value of the second quantized sample (e.g., |x_{q}(n+1)|) by one based on a sign of the second error to generate the second perturbed quantized sample (e.g., |x_{q}′(n+1)|). For example, the perturbation circuitry 1310 perturbs the second quantized sample (e.g., |x_{q}(n+1)|) according to Equation 10 above.

In the illustrated example of FIG. 14, at block 1422, the control circuitry 1306 determines a third remainder of the first perturbed quantized sample (e.g., |x_{q}′(n)|) when divided by two. For example, the control circuitry 1306 determines a third remainder of the first perturbed quantized sample (e.g., |x_{q}′(n)) when divided by two according to Equation 5 above. At block 1424, the control circuitry 1306 determines if the third remainder is equal to zero. Responsive to (e.g., based on) the control circuitry 1306 determining that the third remainder is not equal to zero (block 1424: NO), the at least one of machine-readable instructions or operations 1400 proceed to block 1428. Responsive to (e.g., based on) the control circuitry 1306 determining that the third remainder is equal to zero (block 1424: YES), the at least one of machine-readable instructions or operations 1400 proceed to block 1426.

In the illustrated example of FIG. 14, at block 1426, the control circuitry 1306 causes a first memory to be indexed by the first perturbed quantized sample (e.g., |x_{q}′(n)|) and a second memory to be indexed by the second perturbed quantized sample (e.g., |x_{q}′(n+1)|). At block 1428, the control circuitry 1306 causes the first memory to be indexed by the second perturbed quantized sample (e.g., |x_{q}′(n+1)|) and the second memory to be indexed by the first perturbed quantized sample (e.g., |x_{q}′(n)|). Returning to block 1408, responsive to (e.g., based on) the control circuitry 1306 determining that the first remainder is not equal to the second remainder (block 1408: NO), the at least one of machine-readable instructions or operations 1400 proceed to block 1430.

In the illustrated example of FIG. 14, at block 1430, the control circuitry 1306 determines if the first remainder is equal to zero. Responsive to (e.g., based on) the control circuitry 1306 determining that the first remainder is not equal to zero (block 1430: NO), the at least one of machine-readable instructions or operations 1400 proceed to block 1434. Responsive to (e.g., based on) the control circuitry 1306 determining that the first remainder is equal to zero (block 1430: YES), the at least one of machine-readable instructions or operations 1400 proceed to block 1432. At block 1432, the control circuitry 1306 causes the first memory to be indexed by the first quantized sample (e.g., |x_{q} (n)|) and the second memory to be indexed by the second quantized sample (e.g., |x_{q}(n+1)|). At block 1434, the control circuitry 1306 causes the first memory to be indexed by the second quantized sample (e.g., |x_{q} (n+1)|) and the second memory to be indexed by the first quantized sample (e.g., |x_{q} (n)|).

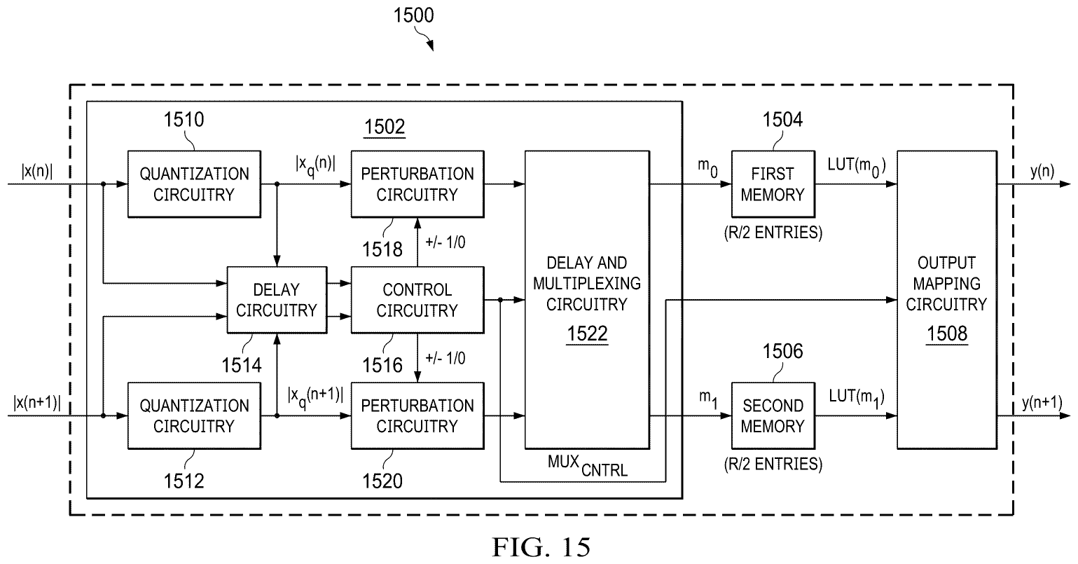

FIG. 15 is a block diagram of a second example implementation of an example LUT 1500 that supports parallelization. As described above, the DPD corrector circuitry 106 of any of FIG. 2, 4, 5, 6A, or 7 is parallelized-by-two. For example, the DPD corrector circuitry 106 can be parallelized-by-two to facilitate operation at a higher sampling rate while also operating at a lower clock rate. As such, the LUT 1500 supports access from a first instance of the circuitry of any one of FIG. 2, 4, 5, 6A, or 7 and access from a second instance of the circuitry of FIG. 2, 4, 5, 6A, or 7 in the same clock cycle. Additional instances of the circuitry of any one of FIG. 2, 4, 5, 6A, or 7 may be implemented to support additional parallelization (e.g., three instances of the circuitry of any one of FIG. 2, 4, 5, 6A, or 7 to support a parallelized-by-three implementation, four instances of the circuitry of any one of FIG. 2, 4, 5, 6A, or 7 to support a parallelized-by-four implementation, etc.).

In the illustrated example of FIG. 15, the LUT 1500 includes example input mapping circuitry 1502, first example memory 1504, second example memory 1506, and example output mapping circuitry 1508. Also, in the example of FIG. 15, the input mapping circuitry 1502 includes first example quantization circuitry 1510, second example quantization circuitry 1512, example delay circuitry 1514, example control circuitry 1516, first example perturbation circuitry 1518, second example perturbation circuitry 1520, and example delay and multiplexing circuitry 1522. In the example of FIG. 15, the LUT 1500 is an R-entry memory that stores data representative of non-linear base-band functions ƒₖ( ). For example, the LUT 1500 is structured to store 512 entries of data (e.g., 512 32-bit values).

In the illustrated example of FIG. 15, each of the memory 1504 and the memory 1506 has an output terminal and an input terminal. In the example of FIG. 15, the output mapping circuitry 1508 includes a first output terminal, a second output terminal, a control terminal, a first input terminal, and a second input terminal. Also, in the example of FIG. 15, each of the quantization circuitry 1510 and the quantization circuitry 1512 has an output terminal and an input terminal. In the example of FIG. 15, the delay circuitry 1514 has a first output terminal, a second output terminal, a first input terminal, a second input terminal, a third input terminal, and a fourth input terminal.

In the illustrated example of FIG. 15, the control circuitry 1516 has a first output terminal, a second output terminal, a third output terminal, a first input terminal, and a second input terminal. In the example of FIG. 15, each of the perturbation circuitry 1518 and the perturbation circuitry 1520 has an output terminal, a first input terminal, and a second input terminal. Also, the delay and multiplexing circuitry 1522 has a first output terminal, a second output terminal, a control terminal, a first input terminal, and a second input terminal.

In the illustrated example of FIG. 15, each of the quantization circuitry 1510 and the quantization circuitry 1512 is implemented by digital circuitry. In the example of FIG. 15, the output terminal of the quantization circuitry 1510 is coupled to the first input terminal of the delay circuitry 1514 and the first input terminal of the perturbation circuitry 1518. Also, the input terminal of the quantization circuitry 1510 is coupled to a first instance of the circuitry of any one of FIG. 2, 4, 5, 6A, or 7. In the example of FIG. 15, the output terminal of the quantization circuitry 1512 is coupled to the fourth input terminal of the delay circuitry 1514 and the first input terminal of the perturbation circuitry 1520. Also, the input terminal of the quantization circuitry 1512 is coupled to a second instance of the circuitry of any one of FIG. 2, 4, 5, 6A, or 7.

In the illustrated example of FIG. 15, the delay circuitry 1514 is implemented by one or more D flip-flop circuits. In some examples, the delay circuitry 1514 is implemented by one or more FIFO queues. In the example of FIG. 15, the first output terminal of the delay circuitry 1514 is coupled to the first input terminal of the control circuitry 1516 and the second output terminal of the delay circuitry 1514 is coupled to the second input terminal of the control circuitry 1516. Also, the first input terminal of the delay circuitry 1514 is coupled to the output terminal of the quantization circuitry 1510. In the example of FIG. 15, the second input terminal of the delay circuitry 1514 is coupled to a first instance of the circuitry of any one of FIG. 2, 4, 5, 6A, or 7. Also, the third input terminal of the delay circuitry 1514 is coupled to a second instance of the circuitry of any one of FIG. 2, 4, 5, 6A, or 7. In the example of FIG. 15, the fourth input terminal of the delay circuitry 1514 is coupled to the output terminal of the quantization circuitry 1512.

Also, in the example of FIG. 15, the control circuitry 1516 is implemented by digital circuitry. In the example of FIG. 15, the first output terminal of the control circuitry 1516 is coupled to the second input terminal of the perturbation circuitry 1518. Also, the second output terminal of the control circuitry 1516 is coupled to the second input terminal of the perturbation circuitry 1520. In the example of FIG. 15, the third output terminal of the control circuitry 1516 is coupled to the control terminal of the output mapping circuitry 1508 and the control terminal of the delay and multiplexing circuitry 1522. Also, the first input terminal of the control circuitry 1516 is coupled to the first output terminal of the delay circuitry 1514. In the example of FIG. 15, the second input terminal of the control circuitry 1516 is coupled to the second output terminal of the delay circuitry 1514.

In the illustrated example of FIG. 15, each of the perturbation circuitry 1518 and the perturbation circuitry 1520 is implemented by digital circuitry. In the example of FIG. 15, the output terminal of the perturbation circuitry 1518 is coupled to the first input terminal of the delay and multiplexing circuitry 1522. Also, the first input terminal of the perturbation circuitry 1518 is coupled to the output terminal of the quantization circuitry 1510 and the second input terminal of the perturbation circuitry 1518 is coupled to the first output terminal of the control circuitry 1516. In the example of FIG. 15, the output terminal of the perturbation circuitry 1520 is coupled to the second input terminal of the delay and multiplexing circuitry 1522. Also, the first input terminal of the perturbation circuitry 1520 is coupled to the output terminal of the quantization circuitry 1512 and the second input terminal of the perturbation circuitry 1520 is coupled to the second output terminal of the control circuitry 1516.

In the illustrated example of FIG. 15, the delay and multiplexing circuitry 1522 is implemented by one or more D flip-flop circuits and one or more multiplexer circuits. In the example of FIG. 15, the first output terminal of the delay and multiplexing circuitry 1522 is coupled to the input terminal of the memory 1504 and the second output terminal of the delay and multiplexing circuitry 1522 is coupled to the input terminal of the memory 1506. Also, the control terminal of the delay and multiplexing circuitry 1522 is coupled to the third output terminal of the control circuitry 1516. In the example of FIG. 15, the first input terminal of the delay and multiplexing circuitry 1522 is coupled to the output terminal of the perturbation circuitry 1518 and the second input terminal of the delay and multiplexing circuitry 1522 is coupled to the output terminal of the perturbation circuitry 1520.

In the illustrated example of FIG. 15, the memory 1504 is implemented by an R/2-entry memory that stores even indexed entries of the non-linear base-band functions ƒₖ( ) stored in the LUT 1500. For example, the memory 1504 stores 256 entries of data (e.g., 256 32-bit values). In the example of FIG. 15, the output terminal of the memory 1504 is coupled to the first input terminal of the output mapping circuitry 1508. Also, the input terminal of the memory 1504 is coupled to the first output terminal of the delay and multiplexing circuitry 1522.

In the illustrated example of FIG. 15, the memory 1506 is implemented by an R/2-entry memory that stores odd indexed entries of the non-linear base-band functions ƒₖ( ) stored in the LUT 1500. For example, the memory 1506 stores 256 entries of data (e.g., 256 32-bit values). In the example of FIG. 15, the output terminal of the memory 1506 is coupled to the second input terminal of the output mapping circuitry 1508. Also, the input terminal of the memory 1506 is coupled to the second output terminal of the delay and multiplexing circuitry 1522.

In the illustrated example of FIG. 15, the output mapping circuitry 1508 is implemented by one or more D flip-flop circuits and one or more multiplexer circuits. In the example of FIG. 15, the first output terminal of the output mapping circuitry 1508 is coupled to a first instance of the circuitry of any one of FIG. 2, 4, 5, 6A, or 7 and the second output terminal of the output mapping circuitry 1508 is coupled to a second instance of the circuitry of FIG. 2, 4, 5, 6A, or 7. In the example of FIG. 15, the first input terminal of the output mapping circuitry 1508 is coupled to the output terminal of the memory 1504 and the second input terminal of the output mapping circuitry 1508 is coupled to the output terminal of the memory 1506. Also, the control terminal of the output mapping circuitry 1508 is coupled to the third output terminal of the control circuitry 1516.

As described above in FIG. 12, if the LSBs of the first quantized sample (e.g., |x_{q}(n)|) and the second quantized sample (e.g., |x_{q}(n+1)|) are the same (e.g., indicating that the values are either both odd or both even), then the input mapping circuitry 1202 perturbs (e.g., increments or decrements by one), the LSB of one of the first quantized sample (e.g., |x_{q}(n)|) or the second quantized sample (e.g., |x_{q}(n+1)|). Such perturbation occurs in about 25% of samples. Also, such perturbation increases the quantization error (e.g., Equation 6 above) of the perturbed one of the first quantized sample (e.g., |x_{q}(n)|) or the second quantized sample (e.g., |x_{q}(n+1)|). As such, the quantization error of the perturbed one of the first quantized sample (e.g., |x_{q}(n)|) or the second quantized sample (e.g., |x_{q}(n+1)|) is increased in 25% of samples.

In the illustrated example of FIG. 15, to reduce the impact of such perturbation, the input mapping circuitry 1502 performs index mapping over up to two clock cycles. For example, the input mapping circuitry 1502 performs index mapping on a first sample of an input signal (e.g., |x(n)|), a second sample of the input signal (e.g., |x(n+1)|), a third sample of the input signal (e.g., |x(n+2)|), and a fourth sample of the input signal (e.g., |x(n+3)|). In the example of FIG. 15, the quantization circuitry 1510 quantizes the first sample (e.g., |x(n)|) and the third sample (e.g., |x(n+2)|) to R_{ind} bit values. Also, the quantization circuitry 1512 quantizes the second sample (e.g., |x(n+1)|) and the fourth sample (e.g., |x(n+3)|) to Ring bit values. Also, in the example of FIG. 15, the delay circuitry 1514 queues the first quantized sample (e.g., |x_{q}(n)|), the second quantized sample (e.g., |x_{q}(n+1)|), the third quantized sample (e.g., |x_{q}(n+2)|), and the fourth quantized sample (e.g., |x_{q} (n+3)|) for analysis by the control circuitry 1516.

For example, the control circuitry 1516 determines if LSB of the first quantized sample (e.g., |x_{q}(n)|) and the second quantized sample (e.g., |x_{q}(n+1)|), namely I(n) and I(n+1), are different. If the control circuitry 1516 determines that I(n) and I(n+1) are different for the first quantized sample (e.g., |x_{q}(n)|) and the second quantized sample (e.g., |x_{q}(n+1)|), then the control circuitry 1516 utilizes the first quantized sample (e.g., x_{q} (n) and the second quantized sample (e.g., |x_{q}(n+1)|), to derive the indices for the memory 1504 (e.g., m₀) and the memory 1506 (e.g., m₁) in the

$$\frac{n}{2}$$

clock cycle corresponding to sample instant n.

Also, if the control circuitry 1516 determines that I(n) and I(n+1) are equal for the first quantized sample (e.g., |x_{q}(n)|) and the second quantized sample (e.g., |x_{q}(n+1)|), then the control circuitry 1516 utilizes the first quantized sample (e.g., |x_{q}(n)|), the second quantized sample (e.g., |x_{q}(n+1)|), the third quantized sample (e.g., |x_{q} (n+2)|), and the fourth quantized sample (e.g., |x_{q}(n+3)|) to determine the quantized samples to be perturbed. For example, the input mapping circuitry 1502 perturbs the LSBs of up to two quantized of the four quantized samples queued by the delay circuitry 1514. As such, the input mapping circuitry 1502 generates four perturbed quantized values such that two are even and two are odd.

In the illustrated example of FIG. 15, the control circuitry 1516 generates a control signal (e.g., MUX_{CTRL}) at the third output terminal of the control circuitry 1516 to control the delay and multiplexing circuitry 1522. For example, the control circuitry 1516 generates the control signal (e.g., MUX_{CTRL}) such that the delay and multiplexing circuitry 1522 indexes the memory 1504 and the memory 1506 with a pair of even and odd values each clock cycle. In the example of FIG. 15, the one or more D flip-flop circuits of the output mapping circuitry 1508 store the four values output from the memory 1504 and the memory 1506 over the two clock cycles. Also, the one or more multiplexer circuits of the output mapping circuitry 1508 select the two output values corresponding to the input values (e.g., |x_{q} (n)|, |x_{q}(n+1)|, |x_{q}(n+2)|, and |x_{q} (n+3)|) based on the control signal (e.g., MUX_{CTRL}) at the third output terminal of the control circuitry 1516.

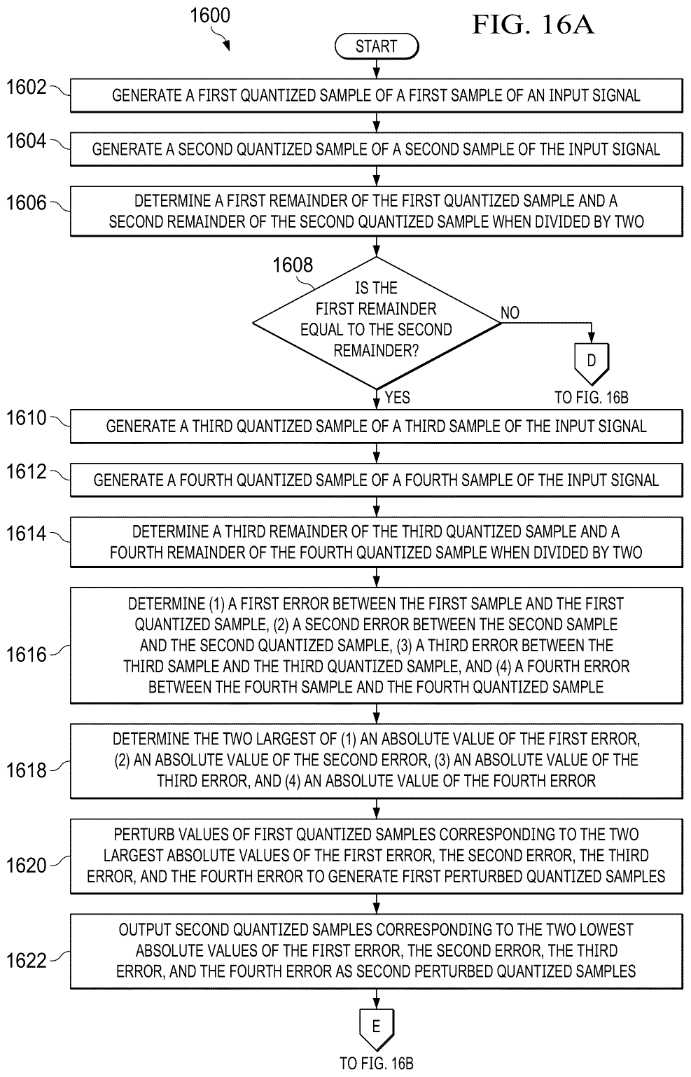

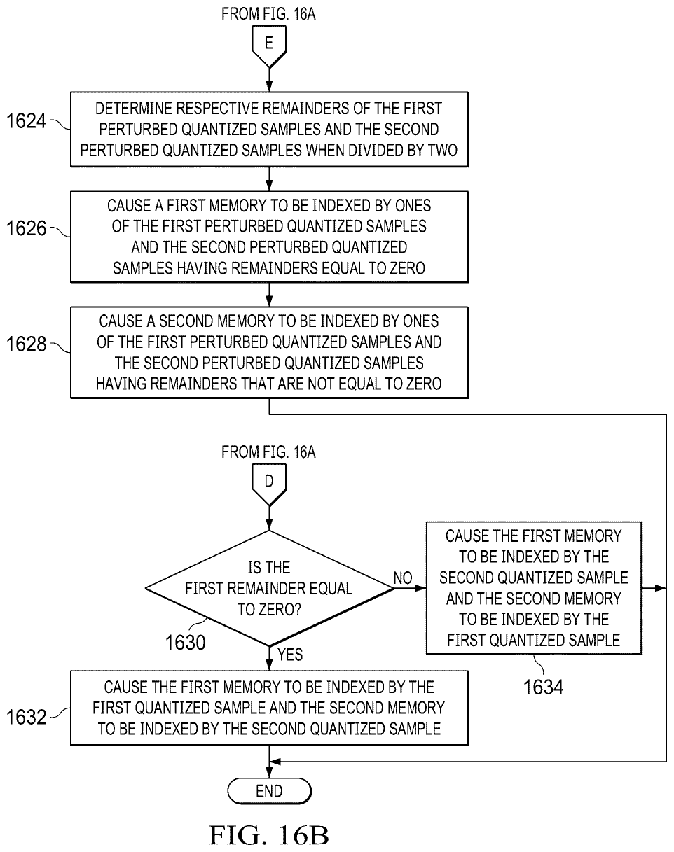

FIG. 16 is a flowchart representative of at least one of example machine-readable instructions or example operations 1600 that may be at least one of executed, instantiated, or performed using an example programmable circuitry implementation of the input mapping circuitry 1502 of FIG. 15. The at least one of example machine-readable instructions or example operations 1600 of FIG. 16 begin at block 1602, at which the quantization circuitry 1510 generates a first quantized sample (e.g., |x_{q}(n)|) of a first sample of an input signal (e.g., |x(n)|). At block 1604 the quantization circuitry 1512 generates a second quantized sample (e.g., |x_{q} (n+1)|) of a second sample of the input signal (e.g., |x(n+1)|).

In the illustrated example of FIG. 16, at block 1606, the control circuitry 1516 determines a first remainder of the first quantized sample (e.g., |x_{q}(n)|) and a second remainder of the second quantized sample (e.g., |x_{q}(n+1)|) when divided by two. For example, the control circuitry 1516 implements Equation 5 above to determine the first remainder of the first quantized sample (e.g., |x_{q}(n)|) and the second remainder of the second quantized sample (e.g., |x_{q}(n+1)|) when divided by two. At block 1608, the control circuitry 1516 determines if the first remainder is equal to the second remainder.

In the illustrated example of FIG. 16, responsive to (e.g., based on) the control circuitry 1516 determining that the first remainder is not equal to the second remainder (block 1608: NO), the at least one of machine-readable instructions or operations 1600 proceed to block 1632. Responsive to (e.g., based on) the control circuitry 1516 determining that the first remainder is equal to the second remainder (block 1608: YES), the at least one of machine-readable instructions or operations 1600 proceed to block 1610. At block 1610, the quantization circuitry 1510 generates a third quantized sample (e.g., |x_{q}(n+2)|) of a third sample of the input signal (e.g., |x(n+2)|). At block 1612 the quantization circuitry 1512 generates a fourth quantized sample (e.g., |x_{q}(n+3)|) of a fourth sample of the input signal (e.g., |x(n+3)|).

In the illustrated example of FIG. 16, at block 1614, the control circuitry 1516 determines a third remainder of the third quantized sample (e.g., |x_{q} (n+2)|) and a fourth remainder of the fourth quantized sample (e.g., |x_{q}(n+3)|) when divided by two. For example, the control circuitry 1516 implements Equation 5 above to determine the third remainder of the third quantized sample (e.g., |x_{q} (n+2)|) and the fourth remainder of the fourth quantized sample (e.g., |x_{q}(n+3)|) when divided by two. At block 1616, the control circuitry 1516 determines (1) a first error between the first sample (e.g., |x(n)|) and the first quantized sample (e.g., |x_{q}(n)|), (2) a second error between the second sample (e.g., |x(n+1)|) and the second quantized sample (e.g., |x_{q}(n+1)|), (3) a third error between the third sample (e.g., |x_{q}(n+2)|) and the third quantized sample (e.g., |x_{q} (n+3)|), and (4) a fourth error between the fourth sample (e.g., |x(n+3)|) and the fourth quantized sample (e.g., |x_{q}(n+3)). For example, the control circuitry 1516 determines the first error, the second error, the third error, and the fourth error according to Equation 6 above.

In the illustrated example of FIG. 16, at block 1618, the control circuitry 1516 determines the two largest of (1)) an absolute value of the first error, (2) an absolute value of the second error, (3) an absolute value of the third error, and (4) an absolute value of the fourth error. At block 1620, at least one of the perturbation circuitry 1518 or the perturbation circuitry 1520 perturbs values of first quantized samples corresponding to the two largest absolute values of the first error, the second error, the third error, and the fourth error to generate first perturbed quantized samples. For example, at least one of the perturbation circuitry 1518 or the perturbation circuitry 1520 implements at least one of Equation 7 or Equation 10 above to perturb the values of the first quantized samples corresponding to the two largest absolute values.

In the illustrated example of FIG. 16, at block 1622, at least one of the perturbation circuitry 1518 or the perturbation circuitry 1520 outputs second quantized samples corresponding to the two lowest absolute values of the first error, the second error, the third error, and the fourth error as second perturbed quantized samples. For example, at least one of the perturbation circuitry 1518 or the perturbation circuitry 1520 outputs the second quantized samples corresponding to the two lowest absolute values according to at least one of Equation 8 or Equation 9 above. At block 1624, the control circuitry 1516 determines respective remainders of the first perturbed quantized samples and the second perturbed quantized samples when divided by two. For example, the control circuitry 1516 determines the respective remainders of the first perturbed quantized samples and the second perturbed quantized samples when divided by two according to Equation 5 above.

In the illustrated example of FIG. 16, at block 1626, the control circuitry 1516 causes a first memory to be indexed by ones of the first perturbed quantized samples and the second perturbed quantized samples having remainders equal to zero. At block 1628, the control circuitry 1516 causes a second memory to be indexed by ones of the first perturbed quantized samples and the second perturbed quantized samples having remainders that are not equal to zero. Returning to block 1608, responsive to (e.g., based on) the control circuitry 1516 determining that the first remainder is not equal to the second remainder (block 1608: NO), the at least one of machine-readable instructions or operations 1600 proceed to block 1630.

In the illustrated example of FIG. 16, at block 1632, the control circuitry 1516 determines if the first remainder is equal to zero. Responsive to (e.g., based on) the control circuitry 1516 determining that the first remainder is not equal to zero (block 1630: NO), the at least one of machine-readable instructions or operations 1600 proceed to block 1634. Responsive to (e.g., based on) the control circuitry 1516 determining that the first remainder is equal to zero (block 1630: YES), the at least one of machine-readable instructions or operations 1600 proceed to block 1632. At block 1632, the control circuitry 1516 causes the first memory to be indexed by the first quantized sample (e.g., |x_{q} (n)|) and the second memory to be indexed by the second quantized sample (e.g., |x_{q}(n+1)|). At block 1634, the control circuitry 1516 causes the first memory to be indexed by the second quantized sample (e.g., |x_{q} (n+1)|) and the second memory to be indexed by the first quantized sample (e.g., |x_{q} (n)|).

While the examples of FIGS. 12, 13, 14, 15, and 16 describe example LUT architectures that support parallelization-by-two, the example LUT architectures described with respect to any of FIG. 12, 13, 14, 15, or 16 can likewise support additional parallelization. For example, to support parallelization-by-three, the example LUT architectures described with respect to any of FIG. 12, 13, 14, 15, or 16 can be adjusted to include three memories where each memory stores R/3 entries. In a parallelized-by-three implementation, a first memory would store every 3k^{th} index of the LUT, a second memory would store every 3(k+1)^{th} index of the LUT, and a third memory would store every 3(k+2)^{th} index of the LUT.

Likewise, to support parallelization-by-four, the example LUT architectures described with respect to any of FIG. 12, 13, 14, 15, or 16 can be adjusted to include four memories. In one example of a parallelized-by-four LUT architecture, a LUT includes four memories where each memory stores R/2 entries, a first memory stores every 2k^{th} index of the LUT, a second memory stores every 2(k+1)th index of the LUT, a third memory stores every 2k^{th} index of the LUT, and a fourth memory stores every 2(k+1)^{th} index of the LUT. In another example of a parallelized-by-four LUT architecture, a LUT includes four memories where each memory stores R/4 entries, a first memory stores every 2k^{th} index of the LUT, a second memory stores every 2(k+1)^{th} index of the LUT, a third memory stores every 2k^{th} index of the LUT, and a fourth memory stores every 2(k+1)^{th} index of the LUT.

Also, indexing of the example LUT architectures described with respect to any of FIG. 12, 13, 14, 15, or 16 can likewise support additional parallelization. In such examples, perturbation of input samples would also be adjusted for additional parallelization. For example, when indexing a parallelized-by-three LUT, example input mapping circuitry would perturb one of a first sample of an input signal, a second sample of the input signal, or a third sample of the input signal that has a largest quantization error when performing index mapping over one clock cycle. Also, for example, when indexing a parallelized-by-three LUT, example input mapping circuitry would perturb one of a first sample of an input signal, a second sample of the input signal, a third sample of the input signal, a fourth sample of the input signal, a fifth sample of the input signal, or a sixth sample of the input signal that has a largest quantization error when performing index mapping over two clock cycle.

While an example manner of implementing the DPD corrector circuitry 106 of FIG. 1B is illustrated in FIGS. 2, 4, 5, 6A, and 7, one or more of the elements, processes, or devices illustrated in FIGS. 2, 4, 5, 6A, and 7 may be at least one of combined, divided, re-arranged, omitted, eliminated, or implemented in any other way. Further, the DPD corrector circuitry 106 of any of FIG. 2, 4, 5, 6A, or 7, may be implemented by hardware alone or by hardware in combination with at least one of software or firmware. Thus, for example, the DPD corrector circuitry 106 of any of FIG. 2, 4, 5, 6A, or 7, could be implemented by at least one of programmable circuitry in combination with machine-readable instructions (e.g., firmware or software), processor circuitry, analog circuit(s), digital circuit(s), logic circuit(s), programmable processor(s), programmable microcontroller(s), graphics processor unit(s) (GPU(s)), digital signal processor(s) (DSP(s)), ASIC(s), programmable logic device(s) (PLD(s)), or field programmable logic device(s) (FPLD(s)) such as FPGAs. Further still, the example the DPD corrector circuitry 106 of any of FIG. 2, 4, 5, 6A, or 7 may at least one of include one or more elements, processes, or devices in addition to, or instead of, those illustrated in FIG. 2, 4, 5, 6A, and 7, or include more than one of any or all of the illustrated elements, processes, and devices.

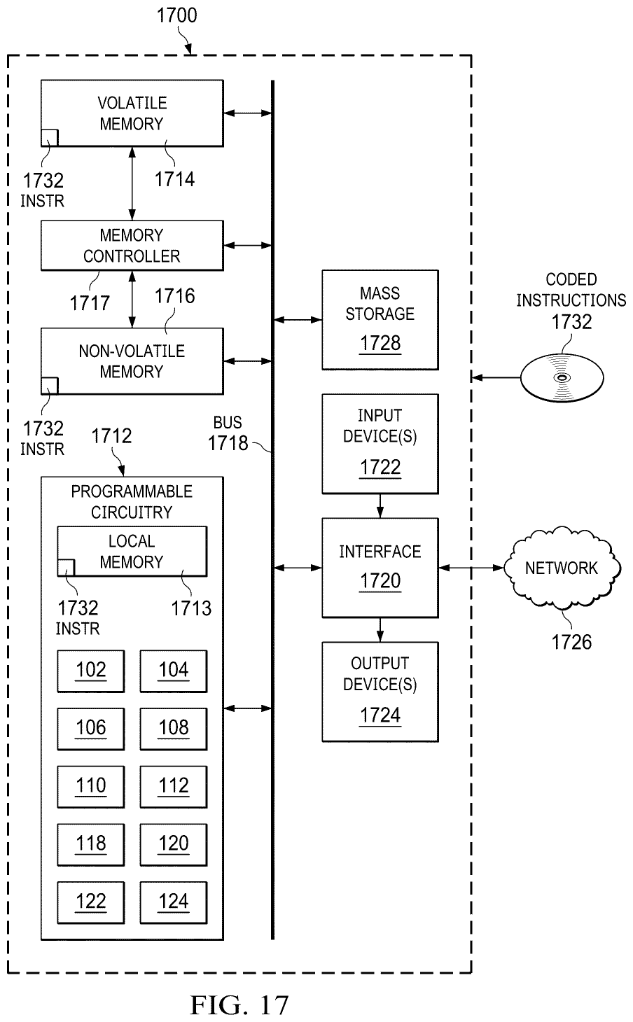

Flowchart(s) representative of at least one of example machine-readable instructions, which may be executed by programmable circuitry to at least one of implement or instantiate the DPD corrector circuitry 106 of any of FIG. 2, 4, 5, 6A, or 7 or example operations which may be performed by programmable circuitry to at least one of implement or instantiate the DPD corrector circuitry 106 of any of FIG. 2, 4, 5, 6A, or 7, are shown in FIGS. 8, 11, 14, and 16. The machine-readable instructions may be at least one of one or more executable programs or portion(s) of one or more executable programs for execution by programmable circuitry such as the programmable circuitry 1712 shown in the example programmable circuitry platform 1700 described below in connection with FIG. 17 or one or more function(s) or portion(s) of functions to be performed by example programmable circuitry (e.g., an FPGA). In some examples, the machine-readable instructions cause an operation, a task, etc., to be at least one of carried out or performed in an automated manner in the real world. As used herein, “automated” means without human involvement.

The program may be embodied in instructions (e.g., at least one of software or firmware) stored on at least one of one or more non-transitory computer-readable mediums or one or more non-transitory machine-readable storage mediums such as at least one of cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), or any other storage device or storage disk. The instructions of the at least one of non-transitory computer-readable or non-transitory machine-readable medium may at least one of program or be executed by programmable circuitry located in one or more hardware devices, but at least one of the entire program or parts thereof could alternatively be at least one of one or more of executed or instantiated by one or more hardware devices other than the programmable circuitry or embodied in dedicated hardware. The machine-readable instructions may be at least one of distributed across multiple hardware devices or executed by two or more hardware devices (e.g., a server and a client hardware device). For example, the client hardware device may be implemented by an endpoint client hardware device (e.g., a hardware device associated with at least one of a human user or a machine user) or an intermediate client hardware device gateway (e.g., a radio access network (RAN)) that may facilitate communication between a server and an endpoint client hardware device. Similarly, the non-transitory computer-readable storage medium may include one or more mediums. Further, although the example program is described with reference to the flowchart(s) illustrated in FIGS. 8, 11, 14, and 16, many other methods of implementing the example DPD corrector circuitry 106 may alternatively be used. For example, at least one of the order of execution of the blocks of the flowchart(s) may be changed, or some of the blocks described may be changed, eliminated, or combined. Also or alternatively, any or all of the blocks of the flow chart may be implemented by one or more hardware circuits (e.g., processor circuitry, discrete analog circuitry, discrete digital circuitry, integrated analog circuitry, integrated digital circuitry, an FPGA, an ASIC, a comparator, an operational-amplifier (op-amp), a logic circuit, etc.) structured to perform the corresponding operation without executing software or firmware. The programmable circuitry may be at least one of distributed in different network locations or local to one or more hardware devices (e.g., a single-core processor (e.g., a single core CPU), a multi-core processor (e.g., a multi-core CPU, an XPU, etc.)). For example, the programmable circuitry may be at least one of one or more of a CPU or an FPGA located in the same package (e.g., the same integrated circuit (IC) package or in two or more separate housings), one or more processors in a single machine, multiple processors distributed across multiple servers of a server rack, multiple processors distributed across one or more server racks, etc., or any combination(s) thereof.

The machine-readable instructions described herein may be stored in one or more of a compressed format, an encrypted format, a fragmented format, a compiled format, an executable format, a packaged format, etc. Machine-readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to at least one of create, manufacture, or produce machine-executable instructions. For example, the machine-readable instructions may be fragmented and stored on at least one of one or more storage devices, one or more disks or one or more computing devices (e.g., servers) located at the same or different locations of a network or collection of networks (e.g., in the cloud, in edge devices, etc.). The machine-readable instructions may require one or more of installation, modification, adaptation, updating, combining, supplementing, configuring, decryption, decompression, unpacking, distribution, reassignment, compilation, etc., in order to render them at least one of directly readable, directly interpretable, or directly executable by at least one of a computing device or other machine. For example, the machine-readable instructions may be stored in multiple parts, which are at least one of individually compressed, individually encrypted, or individually stored on separate computing devices, where the parts when at least one of decrypted, decompressed, or combined form at least one of a set of computer-executable instructions or a set of machine-executable instructions that implement at least one of one or more functions or operations that may together form a program such as that described herein.

In another example, the machine-readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine-readable instructions may need to be configured (e.g., settings stored, data input, network addresses recorded, etc.) before at least one of the machine-readable instructions or the corresponding program(s) can be executed in whole or in part. Thus, at least one of machine-readable, computer-readable, or machine-readable media, as used herein, may include at least one of instructions or program(s) regardless of the particular format or state of at least one of the machine-readable instructions or program(s).

The machine-readable instructions described herein can be represented by any past, present, or future instruction language, scripting language, programming language, etc. For example, the machine-readable instructions may be represented using any of the following languages: C, C++, Java, C#, Perl, Python, JavaScript, HyperText Markup Language (HTML), Structured Query Language (SQL), Swift, etc.

As mentioned above, the example operations of FIGS. 8, 11, 14, and 16 may be implemented using executable instructions (e.g., at least one of computer-readable or machine-readable instructions) stored on at least one of one or more non-transitory computer-readable media or one or more non-transitory machine-readable media. As used herein, the terms non-transitory computer-readable medium, non-transitory computer-readable storage medium, non-transitory machine-readable medium, and non-transitory machine-readable storage medium are expressly defined to include any type of computer-readable storage device or storage disk and to exclude propagating signals and to exclude transmission media. Examples of such non-transitory computer-readable medium, non-transitory computer-readable storage medium, non-transitory machine-readable medium, and non-transitory machine-readable storage medium include at least one of optical storage devices, magnetic storage devices, an HDD, a flash memory, a read-only memory (ROM), a CD, a DVD, a cache, a RAM of any type, a register, or any other storage device or storage disk in which information is stored for any duration (e.g., at least one of for extended time periods, permanently, for brief instances, for temporarily buffering, or for caching of the information). As used herein, the terms “non-transitory computer-readable storage device” and “non-transitory machine-readable storage device” are defined to include any physical (at least one of mechanical, magnetic, or electrical) hardware to retain information for a time period, but to exclude propagating signals and to exclude transmission media. Examples of at least one of non-transitory computer-readable storage devices or non-transitory machine-readable storage devices include at least one of random-access memory of any type, read only memory of any type, solid state memory, flash memory, optical discs, magnetic disks, disk drives, or redundant array of independent disks (RAID) systems. As used herein, the term “device” refers to physical structure such as one or more of at least one of mechanical or electrical equipment, hardware, or circuitry that may or may not be at least one of configured by computer-readable instructions, machine-readable instructions, etc., or manufactured to execute computer-readable instructions, machine-readable instructions, etc.

FIG. 17 is a block diagram of an example programmable circuitry platform 1700 structured to at least on of execute or instantiate the at least one of example machine-readable instructions or example operations of FIGS. 8, 11, 14, and 16 to implement the DPD corrector circuitry 106 of any of FIG. 2, 4, 5, 6A, or 7. The programmable circuitry platform 1700 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, a DVD player, a CD player, a digital video recorder, a Blu-ray player, a gaming console, a personal video recorder, a set top box, a headset (e.g., an augmented reality (AR) headset, a virtual reality (VR) headset, etc.) or other wearable device, or at least one of any other type of computing or any type of electronic device.

The programmable circuitry platform 1700 of the illustrated example includes programmable circuitry 1712. The programmable circuitry 1712 of the illustrated example is hardware. For example, the programmable circuitry 1712 can be implemented by at least one of one or more integrated circuits, one or more logic circuits, one or more FPGAs, one or more microprocessors, one or more CPUs, one or more GPUs, one or more DSPs, or one or more microcontrollers from any desired family or manufacturer. The programmable circuitry 1712 may be implemented by one or more semiconductor based (e.g., silicon based) devices. In this example, the programmable circuitry 1712 implements the processor circuitry 102, the pre-DPD interpolator circuitry 104, the DPD corrector circuitry 106, the transmitter circuitry 108, the transmitter DAC circuit 110, the DSA circuitry 112, the DSA circuitry 118, the feedback ADC circuit 120, the feedback circuitry 122, and the DPD estimator circuitry 124.

The programmable circuitry 1712 of the illustrated example includes a local memory 1713 (e.g., a cache, registers, etc.). The programmable circuitry 1712 of the illustrated example is in communication with main memory 1714, 1716, which includes a volatile memory 1714 and a non-volatile memory 1716, by a bus 1718. The volatile memory 1714 may be implemented by at least one of Synchronous Dynamic Random Access Memory (SDRAM), Dynamic Random Access Memory (DRAM), RAMBUS® Dynamic Random Access Memory (RDRAM®), or any other type of RAM device. The non-volatile memory 1716 may be implemented by at least one of flash memory or any other desired type of memory device. Access to the main memory 1714, 1716 of the illustrated example is controlled by a memory controller 1717. In some examples, the memory controller 1717 may be implemented by one or more integrated circuits, logic circuits, microcontrollers from any desired family or manufacturer, or any other type of circuitry to manage the flow of data going to and from the main memory 1714, 1716.

The programmable circuitry platform 1700 of the illustrated example also includes interface circuitry 1720. The interface circuitry 1720 may be implemented by hardware satisfying any type of interface standard, such as at least one of an Ethernet interface, a universal serial bus (USB) interface, a Bluetooth® interface, a near field communication (NFC) interface, a Peripheral Component Interconnect (PCI) interface, or a Peripheral Component Interconnect Express (PCIe) interface.

In the illustrated example, one or more input devices 1722 are connected to the interface circuitry 1720. The input device(s) 1722 permit(s) a user (e.g., a human user, a machine user, etc.) to enter at least one of data or commands into the programmable circuitry 1712. The input device(s) 1722 can be implemented by, for example, at least one of an audio sensor, a microphone, a camera (still or video), a keyboard, a button, a mouse, a touchscreen, a trackpad, a trackball, an isopoint device, or a voice recognition system.

One or more output devices 1724 are also connected to the interface circuitry 1720 of the illustrated example. The output device(s) 1724 can be implemented, for example, by at least one of display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, or speaker. The interface circuitry 1720 of the illustrated example, thus, may include at least one of a graphics driver card, a graphics driver chip, or graphics processor circuitry such as a GPU.

The interface circuitry 1720 of the illustrated example also includes a communication device such as at least one of a transmitter, a receiver, a transceiver, a modem, a residential gateway, a wireless access point, or a network interface to facilitate exchange of data with external machines (e.g., computing devices of any kind) by a network 1726. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 1700 of the illustrated example also includes one or more mass storage discs or devices 1728 to store at least one of firmware, software, or data. Examples of such mass storage discs or devices 1728 include at least one of magnetic storage devices (e.g., floppy disk, drives, HDDs, etc.), optical storage devices (e.g., Blu-ray disks, CDs, DVDs, etc.), RAID systems, or solid-state storage discs or devices such as at least one of flash memory devices or SSDs.

The machine-readable instructions 1732, which may be implemented by the machine-readable instructions of FIGS. 8, 11, 14, and 16, may be stored at least one of in the mass storage device 1728, in the volatile memory 1714, in the non-volatile memory 1716, or on at least one non-transitory computer-readable storage medium such as a CD or DVD which may be removable.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, e.g., the same entity or object. Also, although individual features may be included in different examples or claims, these may possibly be combined, and the inclusion in different examples or claims does not imply that a combination of features is at least one of not feasible or not advantageous.

As used herein, connection references (e.g., attached, coupled, connected, and joined) may include at least one of intermediate members between the elements referenced by the connection reference or relative movement between those elements unless otherwise indicated. As such, connection references do not necessarily infer that two elements are at least one of directly connected or in fixed relation to each other.

Unless specifically stated otherwise, descriptors such as “first,” “second,” “third,” etc., are used herein without imputing or otherwise indicating any meaning of at least one of priority, physical order, arrangement in a list, or ordering in any way, but are merely used as at least one of labels or arbitrary names to distinguish elements for ease of understanding the described examples. In some examples, the descriptor “first” may be used to refer to an element in the detailed description, while the same element may be referred to in a claim with a different descriptor such as “second” or “third.” In such instances, such descriptors are used merely for identifying those elements distinctly within the context of the discussion (e.g., within a claim) in which the elements might, for example, otherwise share a same name.

As used herein, the phrase “in communication,” including variations thereof, encompasses at least one of direct communication or indirect communication through one or more intermediary components, and does not require at least one of direct physical (e.g., wired) communication or constant communication, but rather also includes selective communication at one or more of periodic intervals, scheduled intervals, aperiodic intervals, or one-time events.

As used herein, “programmable circuitry” is defined to include at least one of (i) one or more special purpose electrical circuits (e.g., an application specific circuit (ASIC)) structured to perform specific operation(s) and including one or more semiconductor-based logic devices (e.g., electrical hardware implemented by one or more transistors), or (ii) one or more general purpose semiconductor-based electrical circuits programmable with instructions to perform at least one of specific functions(s) or specific operation(s) and including one or more semiconductor-based logic devices (e.g., electrical hardware implemented by one or more transistors). Examples of programmable circuitry include at least one of programmable microprocessors such as Central Processor Units (CPUs) that may execute first instructions to perform at least one of one or more operations or one or more functions, Field Programmable Gate Arrays (FPGAs) that may be programmed with second instructions to cause at least one of configuration or structuring of the FPGAs to instantiate at least one of one or more operations or one or more functions corresponding to the first instructions, Graphics Processor Units (GPUs) that may execute first instructions to perform at least one of one or more operations or one or more functions, Digital Signal Processors (DSPs) that may execute first instructions to perform at least one of one or more operations or one or more functions, XPUs, Network Processing Units (NPUs), one or more microcontrollers that may execute first instructions to perform at least one of one or more operations or one or more functions, or integrated circuits such as Application Specific Integrated Circuits (ASICs). For example, an XPU may be implemented by a heterogeneous computing system including multiple types of programmable circuitry (e.g., at least one of one or more FPGAs, one or more CPUs, one or more GPUs, one or more NPUs, one or more DSPs, etc., or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

In this description, the phrase “at least one of A or B” (or “at least one of A and B”) refers to implementations including any of: (a) at least one A; (b) at least one B; and (c) at least one A and at least one B.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Numerical identifiers such as “first,” “second,” “third,” etc. are used merely to distinguish between elements of substantially the same type in terms of at least one of structure or function. These identifiers, as used in the detailed description do not necessarily align with those used in the claims.

A device that is “configured to” perform a task or function may be at least one of configured (e.g., at least one of programmed or hardwired) at a time of manufacturing by a manufacturer to perform the function or configurable (or re-configurable) by a user after manufacturing to perform at least one of the function or other additional or alternative functions. The configuring may be through at least one of firmware or software programming of the device, through at least one of a construction or layout of hardware components and interconnections of the device, or a combination thereof.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

In the description and claims, described “circuitry” may include one or more circuits. A circuit or device that is described herein as including certain components may instead be adapted to be coupled to those components to form the described circuitry or device. For example, a structure described as including at least one of one or more semiconductor elements (such as transistors), one or more passive elements (such as resistors, capacitors, inductors, etc.), or one or more sources (such as voltage sources, current sources, etc.) may instead include only the semiconductor elements within a single physical device (e.g., at least one of a semiconductor die or integrated circuit (IC) package) and may be adapted to be coupled to one or more of at least some of the passive elements or at least some of the sources to form the described structure either at a time of manufacture or after a time of manufacture, for example, by at least one of an end-user or a third-party.

Circuits described herein are reconfigurable to include the replaced components to provide functionality at least partially similar to functionality available prior to the component replacement. Components shown as resistors, unless otherwise stated, are generally representative of any one or more elements coupled at least one of in series or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other example embodiments, additional or fewer features may be incorporated into the integrated circuit. In addition, at least one of (a) some or all of the features illustrated as being external to the integrated circuit may be included in the integrated circuit or (b) some features illustrated as being internal to the integrated circuit may be incorporated outside of the integrated. As used herein, the term “integrated circuit” means one or more circuits that are at least one of: (i) incorporated in/over a semiconductor substrate; (ii) incorporated in a single semiconductor package; (iii) incorporated into the same module; or (iv) incorporated in/on the same printed circuit board.

Uses of the phrase “ground” in the foregoing description include at least one of a chassis ground, an Earth ground, a floating ground, a virtual ground, a digital ground, a common ground, or any other form of ground connection applicable to, or suitable for, the teachings of this description. As used herein, “about” modifies its subjects/values to recognize the potential presence of variations that occur in real world applications. For example, “about” may modify values that may not be exact due to at least one of manufacturing tolerances or other real world imperfections as will be apparent to persons of ordinary skill in the art. Unless otherwise stated, “about” preceding a value means+/−10 percent of the stated value, or, if the value is zero, a reasonable range of values around zero.

Modifications are possible in the described embodiments, and other embodiments are possible, within the scope of the claims.

From the foregoing, it will be appreciated that example systems, apparatus, articles of manufacture, and methods have been described that improve digital pre-distortion. For example, examples described herein achieve an improved ACLR that is compliant with the value specified by the 3rd Generation Partnership Project (3GPP). As such, examples described herein achieve an ACLR that is better than other techniques. Examples described herein also support an oversampling rate of 860 MSPS and as such support DPD correction for signals having a bandwidth of 300 MHz. Examples described herein also reduce the on-chip area consumption to implement DPD correction compared to other techniques. Also, examples described herein reduce the power consumption of DPD corrector circuitry compared to other techniques.

Also, while example DPD correction described herein is described in the context of Equation 1 and 2, example DPD correction can also be applied in the context of an Equation of any order. For example Equation 15 below represents a generalized DPD model for any order.

$$y ( n ) = x ( n ) + {\sum }_{k = 1}^{{L}_{1}} x ( n - {l}_{1} ( k ) ) * {f}_{k} ( \vert x ( n - {l}_{2} ( k ) ) \vert ) + {\sum }_{p} {\sum }_{k = {L}_{1} + 1}^{{L}_{2}} {{x}^{*} ( n - {l}_{1} ( k ) )}^{p} * {f}_{k} ( \vert x ( n - {l}_{2} ( k ) ) \vert ) * {x}^{p + 1} ( n - {l}_{3} ( k ) ) + {\sum }_{q} {\sum }_{k = {L}_{2} + 1}^{M} x ( n - {l}_{1} ( k ) ) * {f}_{k} ( \vert x ( n - {l}_{2} ( k ) ) \vert ) * {\vert x ( n - {l}_{3} ( k ) ) \vert}^{q} \qquad Equation 15$$

In the example of Equation 15, x(n) represents an input signal, y(n) represents a pre-distorted version of the input signal, |x(n)| represents a function to compute the envelope of x(n), x*(n) represents a function to compute the conjugate of x(n), x² (n) represents a squared version of x(n), and |x(n)|² represents a squared envelope of x(n). The envelope (e.g., |x(n)|) of an input signal x(n) can be determined as described above (e.g., |x(n)|={square root over (Re(x(n))²+Im(x(n))²))}. Also, the conjugate (e.g., x*(n)) of the input signal x(n) can be determined as described above (e.g., x*(n)=a(n)−i*b(n)). In the example Equation 15, l₁(k) represent a delay (e.g., at least one of positive or negative) applied to x(n) and x*(n), and l₂(k) represents a delay applied to |x(n)|. Also, in Equation 15, l₃(k) represent a delay (e.g., at least one of positive or negative) applied to x^{p+1}(n) and |x(n)|^{q}. In the example of Equation 15, the non-linearity of PA circuitry is modeled by M non-linear functions ƒₖ( ). In Equation 15, ƒₖ(|x(n−l₂(k))|) represents an output of a non-linear function indexed by |x(n−l₂(k))|. To convert the DPD model of Equation 15 to the DPD model of Equation 2, p can be set to one and q can be set to two.

Described examples also include a LUT architecture that partitions R-entries of non-linear base-band function data across two R/2-entry memories. Example LUT architecture described herein reduces the amount of on-chip area consumed by LUTs and reduces the power consumption of DPD corrector circuitry. For example, described examples reduce the number of bits to be stored in memory by a factor of two which directly reduces the amount of area consumed on silicon to implement a LUT. Also, example input mapping circuitry can be shared across the LUTs for a given instance of transmitter circuitry which reduces the amount of area consumed on silicon to implement LUTs for DPD correction.

Examples described herein also facilitate accessing both of the R/2-entry memories in each clock cycle to generate two outputs per clock cycle and support parallelization. Described examples also selectively reorder values output from the two memories as described above. While example LUT architecture described herein is described in the context of DPD correction, example LUT architecture is also applicable to any scenario that utilizes one or more LUTs. For example, described LUT architecture can be used to represent the values of a function (e.g., a cosine function, a polynomial function, a logarithmic function, an anti-logarithmic function, a root function (e.g., a square root function, a higher order root function, etc.), etc.). Also, while examples described herein are described in the context of DPD correction in transmitter circuitry, examples described herein are also applicable to any non-linearity correction in digital circuitry. For example, described example can be used in receiver circuitry to perform non-linearity correction (e.g., DPD correction).

Described systems, apparatus, articles of manufacture, and methods improve the efficiency of using a computing device by reducing power consumption and area consumed on a chip to implement DPD correction. Examples described herein also increase the frequency range across which DPD correction can be performed. Described systems, apparatus, articles of manufacture, and methods are accordingly directed to one or more improvement(s) in the operation of a machine such as a computer or at least one of other electronic device or mechanical device.

What is claimed is:

1. An apparatus comprising:
envelope generator circuitry having an output terminal and an input terminal coupled to a digital pre-distortion (DPD) terminal;
first delay circuitry having a first output terminal, a second output terminal, a third output terminal, and an input terminal coupled to the output terminal of the envelope generator circuitry;
a first lookup table (LUT) having an output terminal and an input terminal coupled to the first output terminal of the first delay circuitry;
a second LUT having an output terminal and an input terminal coupled to the second output terminal of the first delay circuitry;
a third LUT having an output terminal and an input terminal coupled to the third output terminal of the first delay circuitry;
second delay circuitry having a first output terminal, a second output terminal, a third output terminal, a fourth output terminal, and an input terminal coupled to the DPD terminal;
a first multiplier circuit having an output terminal, a first input terminal coupled to the output terminal of the first LUT, and a second input terminal coupled to the first output terminal of the second delay circuitry;
conjugate generator circuitry having an output terminal and an input terminal coupled to the second output terminal of the second delay circuitry;
a second multiplier circuit having an output terminal, a first input terminal coupled to the output terminal of the second LUT, and a second input terminal coupled to the output terminal of the conjugate generator circuitry;
a third multiplier circuit having an output terminal, a first input terminal coupled to the output terminal of the third LUT, and a second input terminal coupled to the third output terminal of the second delay circuitry;
first adder circuitry having an output terminal, a first input terminal, a second input terminal, and a third input terminal, the first input terminal of the first adder circuitry coupled to the output terminal of the first multiplier circuit;
squared signal generator circuitry having an output terminal and an input terminal coupled to the DPD terminal;
third delay circuitry having an output terminal and an input terminal coupled to the output terminal of the squared signal generator circuitry;
a fourth multiplier circuit having an output terminal coupled to the second input terminal of the first adder circuitry, a first input terminal coupled to the output terminal of the second multiplier circuit, and a second input terminal coupled to the output terminal of the third delay circuitry;
squared envelope generator circuitry having an output terminal and an input terminal coupled to the DPD terminal;
fourth delay circuitry having an output terminal and an input terminal coupled to the output terminal of the squared envelope generator circuitry;
a fifth multiplier circuit having an output terminal coupled to the third input terminal of the first adder circuitry, a first input terminal coupled to the output terminal of the third multiplier circuit, and a second input terminal coupled to the output terminal of the fourth delay circuitry; and
second adder circuitry having an output terminal, a first input terminal coupled to the fourth output terminal of the second delay circuitry, and a second input terminal coupled to the output terminal of the first adder circuitry.

2. The apparatus of claim 1, wherein the envelope generator circuitry is first envelope generator circuitry, the input terminal of the first LUT is a first input terminal, and the apparatus further includes:
second envelope generator circuitry having an output terminal and an input terminal coupled to the second output terminal of the DPD terminal; and
fifth delay circuitry having an output terminal coupled to a second input terminal of the first LUT and an input terminal coupled to the output terminal of the second envelope generator circuitry.

3. The apparatus of claim 2, wherein the apparatus further includes a sixth multiplier circuit having an input terminal, and the first LUT includes:
input mapping circuitry having a first output terminal, a second output terminal, a third output terminal, a first input terminal coupled to the first output terminal of the first delay circuitry and a second input terminal coupled to the output terminal of the fifth delay circuitry;
first memory having an output terminal and an input terminal coupled to the first output terminal of the input mapping circuitry;
second memory having an output terminal and an input terminal coupled to the second output terminal of the input mapping circuitry; and
output mapping circuitry having a first output terminal coupled to the first input terminal of the first multiplier circuit, a second output terminal coupled to the input terminal of the sixth multiplier circuit, a control terminal coupled to the third output terminal of the input mapping circuitry, a first input terminal coupled to the output terminal of the first memory, and a second input terminal coupled to the output terminal of the second memory.

4. The apparatus of claim 3, wherein the input mapping circuitry includes:
first quantization circuitry having an output terminal and an input terminal coupled to the first output terminal of the first delay circuitry;
second quantization circuitry having an output terminal and an input terminal coupled to the output terminal of the fifth delay circuitry;
control circuitry having a first output terminal, a second output terminal, a third output terminal coupled to the control terminal of the output mapping circuitry, a first input terminal coupled to the output terminal of the first quantization circuitry, a second input terminal coupled to the first output terminal of the first delay circuitry, a third input terminal coupled to the output terminal of the fifth delay circuitry, and a fourth input terminal coupled to the output terminal of the second quantization circuitry;
first perturbation circuitry having an output terminal, a first input terminal coupled to the output terminal of the first quantization circuitry, and a second input terminal coupled to the first output terminal of the control circuitry;
second perturbation circuitry having an output terminal, a first input terminal coupled to the output terminal of the second quantization circuitry, and a second input terminal coupled to the second output terminal of the control circuitry; and
commutator circuitry having a first output terminal coupled to the input terminal of the first memory, a second output terminal coupled to the input terminal of the second memory, a control terminal coupled to the third output terminal of the control circuitry, a first input terminal coupled to the output terminal of the first perturbation circuitry, and a second input terminal coupled to the output terminal of the second perturbation circuitry.

5. The apparatus of claim 3, wherein the input mapping circuitry includes:
first quantization circuitry having an output terminal and an input terminal coupled to the first output terminal of the first delay circuitry;
second quantization circuitry having an output terminal and an input terminal coupled to the output terminal of the fifth delay circuitry;
sixth delay circuitry having a first output terminal, a second output terminal, a first input terminal coupled to the output terminal of the first quantization circuitry, a second input terminal coupled to the first output terminal of the first delay circuitry, a third input terminal coupled to the output terminal of the fifth delay circuitry, and a fourth input terminal coupled to the output terminal of the second quantization circuitry;
control circuitry having a first output terminal, a second output terminal, a third output terminal coupled to the control terminal of the output mapping circuitry, a first input terminal coupled to the first output terminal of the sixth delay circuitry, and a second input terminal coupled to the second output terminal of the sixth delay circuitry;
first perturbation circuitry having an output terminal, a first input terminal coupled to the output terminal of the first quantization circuitry, and a second input terminal coupled to the first output terminal of the control circuitry;
second perturbation circuitry having an output terminal, a first input terminal coupled to the output terminal of the second quantization circuitry, and a second input terminal coupled to the second output terminal of the control circuitry; and
delay and multiplexing circuitry having a first output terminal coupled to the input terminal of the first memory, a second output terminal coupled to the input terminal of the second memory, a control terminal coupled to the third output terminal of the control circuitry, a first input terminal coupled to the output terminal of the first perturbation circuitry, and a second input terminal coupled to the output terminal of the second perturbation circuitry.

6. The apparatus of claim 1, wherein:
the first LUT is structured to store a first amount of data; and
the first LUT includes first memory structured to store a first half of the first amount of data and second memory structured to store a second half of the first amount of data, the first memory to store even indexed entries of the first amount of data, the second memory to store odd indexed entries of the first amount of data.

7. An apparatus comprising:
envelope generator circuitry having an output terminal and an input terminal coupled to a digital pre-distortion (DPD) terminal;
first delay circuitry having a first output terminal, a second output terminal, a third output terminal, and an input terminal coupled to the output terminal of the envelope generator circuitry;
a first lookup table (LUT) having an output terminal and an input terminal coupled to the first output terminal of the first delay circuitry;
second delay circuitry having an output terminal and an input terminal coupled to the output terminal of the first LUT;
a second LUT having an output terminal and an input terminal coupled to the second output terminal of the first delay circuitry;
third delay circuitry having an output terminal and an input terminal coupled to the output terminal of the second LUT;
a third LUT having an output terminal and an input terminal coupled to the third output terminal of the first delay circuitry;
fourth delay circuitry having an output terminal and an input terminal coupled to the output terminal of the third LUT;
fifth delay circuitry having a first output terminal, a second output terminal, and an input terminal coupled to the DPD terminal;
squared envelope generator circuitry having an output terminal and an input terminal coupled to the DPD terminal;
squared signal generator circuitry having an output terminal and an input terminal coupled to the DPD terminal;
sixth delay circuitry having an output terminal and an input terminal coupled to the DPD terminal;
sub-term generator circuitry having a first output terminal, a second output terminal, a first input terminal coupled to the output terminal of the sixth delay circuitry, a second input terminal coupled to the output terminal of the squared envelope generator circuitry, and a third input terminal coupled to the output terminal of the squared signal generator circuitry;
seventh delay circuitry having an output terminal and an input terminal coupled to the first output terminal of the sub-term generator circuitry;
eighth delay circuitry having an output terminal and an input terminal coupled to the second output terminal of the sub-term generator circuitry;
a first multiplier circuit having an output terminal, a first input terminal coupled to the output terminal of the second delay circuitry, and a second input terminal coupled to the first output terminal of the fifth delay circuitry;
a second multiplier circuit having an output terminal, a first input terminal coupled to the output terminal of the third delay circuitry, and a second input terminal coupled to the output terminal of the seventh delay circuitry;
a third multiplier circuit having an output terminal, a first input terminal coupled to the output terminal of the fourth delay circuitry, and a second input terminal coupled to the output terminal of the eighth delay circuitry;
first adder circuitry having an output terminal, a first input terminal coupled to the output terminal of the first multiplier circuit, a second input terminal coupled to the output terminal of the second multiplier circuit, and a third input terminal coupled to the output terminal of the third multiplier circuit; and
second adder circuitry having an output terminal, a first input terminal coupled to the second output terminal of the fifth delay circuitry, and a second input terminal coupled to the output terminal of the first adder circuitry.

8. The apparatus of claim 7, wherein the envelope generator circuitry is first envelope generator circuitry, the input terminal of the first LUT is a first input terminal, and the apparatus further includes:
second envelope generator circuitry having an output terminal and an input terminal coupled to the second output terminal of the DPD terminal; and
ninth delay circuitry having an output terminal coupled to a second input terminal of the first LUT and an input terminal coupled to the output terminal of the second envelope generator circuitry.

9. The apparatus of claim 8, wherein the apparatus further includes a fourth multiplier circuit having an input terminal, and the first LUT includes:
input mapping circuitry having a first output terminal, a second output terminal, a third output terminal, a first input terminal coupled to the first output terminal of the first delay circuitry and a second input terminal coupled to the output terminal of the ninth delay circuitry;
first memory having an output terminal and an input terminal coupled to the first output terminal of the input mapping circuitry;
second memory having an output terminal and an input terminal coupled to the second output terminal of the input mapping circuitry; and
output mapping circuitry having a first output terminal coupled to the first input terminal of the first multiplier circuit, a second output terminal coupled to the input terminal of the fourth multiplier circuit, a control terminal coupled to the third output terminal of the input mapping circuitry, a first input terminal coupled to the output terminal of the first memory, and a second input terminal coupled to the output terminal of the second memory.

10. The apparatus of claim 9, wherein the input mapping circuitry includes:
first quantization circuitry having an output terminal and an input terminal coupled to the first output terminal of the first delay circuitry;
second quantization circuitry having an output terminal and an input terminal coupled to the output terminal of the ninth delay circuitry;
control circuitry having a first output terminal, a second output terminal, a third output terminal coupled to the control terminal of the output mapping circuitry, a first input terminal coupled to the output terminal of the first quantization circuitry, a second input terminal coupled to the first output terminal of the first delay circuitry, a third input terminal coupled to the output terminal of the ninth delay circuitry, and a fourth input terminal coupled to the output terminal of the second quantization circuitry;
first perturbation circuitry having an output terminal, a first input terminal coupled to the output terminal of the first quantization circuitry, and a second input terminal coupled to the first output terminal of the control circuitry;
second perturbation circuitry having an output terminal, a first input terminal coupled to the output terminal of the second quantization circuitry, and a second input terminal coupled to the second output terminal of the control circuitry; and
commutator circuitry having a first output terminal coupled to the input terminal of the first memory, a second output terminal coupled to the input terminal of the second memory, a control terminal coupled to the third output terminal of the control circuitry, a first input terminal coupled to the output terminal of the first perturbation circuitry, and a second input terminal coupled to the output terminal of the second perturbation circuitry.

11. The apparatus of claim 9, wherein the input mapping circuitry includes:
first quantization circuitry having an output terminal and an input terminal coupled to the first output terminal of the first delay circuitry;
second quantization circuitry having an output terminal and an input terminal coupled to the output terminal of the ninth delay circuitry;
tenth delay circuitry having a first output terminal, a second output terminal, a first input terminal coupled to the output terminal of the first quantization circuitry, a second input terminal coupled to the first output terminal of the first delay circuitry, a third input terminal coupled to the output terminal of the ninth delay circuitry, and a fourth input terminal coupled to the output terminal of the second quantization circuitry;
control circuitry having a first output terminal, a second output terminal, a third output terminal coupled to the control terminal of the output mapping circuitry, a first input terminal coupled to the first output terminal of the tenth delay circuitry, and a second input terminal coupled to the second output terminal of the tenth delay circuitry;
first perturbation circuitry having an output terminal, a first input terminal coupled to the output terminal of the first quantization circuitry, and a second input terminal coupled to the first output terminal of the control circuitry;
second perturbation circuitry having an output terminal, a first input terminal coupled to the output terminal of the second quantization circuitry, and a second input terminal coupled to the second output terminal of the control circuitry; and
delay and multiplexing circuitry having a first output terminal coupled to the input terminal of the first memory, a second output terminal coupled to the input terminal of the second memory, a control terminal coupled to the third output terminal of the control circuitry, a first input terminal coupled to the output terminal of the first perturbation circuitry, and a second input terminal coupled to the output terminal of the second perturbation circuitry.

12. The apparatus of claim 7, wherein:
the first LUT is structured to store a first amount of data; and
the first LUT includes first memory structured to store a first half of the first amount of data and second memory structured to store a second half of the first amount of data, the first memory to store even indexed entries of the first amount of data, the second memory to store odd indexed entries of the first amount of data.

13. The apparatus of claim 7, wherein the sub-term generator circuitry includes:
a fourth multiplier circuit having an output terminal coupled to the input terminal of the eighth delay circuitry, a first input terminal coupled to the output terminal of the sixth delay circuitry, and a second input terminal coupled to the output terminal of the squared envelope generator circuitry;
conjugate generator circuitry having an output terminal and an input terminal coupled to the output terminal of the sixth delay circuitry; and
a fifth multiplier circuit having an output terminal coupled to the input terminal of the seventh delay circuitry, a first input terminal coupled to the output terminal of the conjugate generator circuitry, and a second input terminal coupled to the output terminal of the squared signal generator circuitry.

14. The apparatus of claim 7, wherein:
the first LUT is to store data representative of (1) a first sub-LUT having U entries and a first width of V-bits and (2) a second sub-LUT having U entries and a second width of V-bits, the first LUT having U entries and a width of 2*V-bits; and
a first entry of the first LUT includes (1) first V-bits representative of a first V-bit entry of the first sub-LUT and (2) second V-bits representative of a second V-bit entry of the second sub-LUT.

15. The apparatus of claim 7, wherein the fifth delay circuitry has a third output terminal, the first adder circuitry has a fourth input terminal, and the apparatus further includes:
ninth delay circuitry having an output terminal and an input terminal coupled to the output terminal of the first LUT;
a fourth multiplier circuit having an output terminal, a first input terminal, and a second input terminal, the output terminal of the fourth multiplier circuit coupled to the fourth input terminal of the first adder circuitry, the second input terminal of the fourth multiplier circuit coupled to the third output terminal of the fifth delay circuitry; and
LUT adder circuitry having a first output terminal coupled to the first input terminal of the first multiplier circuit, a second output terminal coupled to the second input terminal of the fourth multiplier circuit, a first input terminal coupled to the output terminal of the second delay circuitry, and a second input terminal coupled to the output terminal of the ninth delay circuitry, the LUT adder circuitry to:
add a first value output from the second delay circuitry with a second value output from the ninth delay circuitry when (1) the first value and (2) the second value are to be multiplied by a delayed version of an input signal from the fifth delay circuitry; and
provide a sum of the first value and the second value to one of the first multiplier circuit or the fourth multiplier circuit to be multiplied by the delayed version of the input signal.

16. The apparatus of claim 7, wherein the first LUT corresponds to a first instance of transmitter circuitry, and the apparatus further includes:
a first multiplexer circuit having an output terminal, a control terminal, a first input terminal coupled to the first output terminal of the first delay circuitry, and a second input terminal coupled to an output terminal of ninth delay circuitry, the ninth delay circuitry corresponding to a second instance of transmitter circuitry;
a second multiplexer circuit having an output terminal, a control terminal, a first input terminal, and a second input terminal, the output terminal of the second multiplexer circuit coupled to the input terminal of the second delay circuitry, the first input terminal of the second multiplexer circuit coupled to the output terminal of the first LUT;
a spare LUT having an output terminal coupled to the second input terminal of the second multiplexer circuit and an input terminal coupled to the output terminal of the first multiplexer circuit;
a fourth LUT corresponding to the second instance of transmitter circuitry, the fourth LUT having an output terminal and an input terminal coupled to an output terminal of the ninth delay circuitry;
a third multiplexer circuit having an output terminal, a control terminal, a first input terminal, and a second input terminal, the output terminal of the third multiplexer circuit coupled to an input terminal of tenth delay circuitry, the first input terminal of the third multiplexer circuit coupled to the output terminal of the spare LUT, the second input terminal of the third multiplexer circuit coupled to the output terminal of the fourth LUT, the tenth delay circuitry corresponding to the second instance of transmitter circuitry; and
sequencer circuitry having a first output terminal coupled to the control terminal of the first multiplexer circuit, a second output terminal coupled to the control terminal of the second multiplexer circuit, and a third output terminal coupled to the control terminal of the third multiplexer circuit.

17. A method comprising:
switching a first multiplexer circuit associated with first delay circuitry from (a) a first sub-lookup table (LUT) of a first LUT of digital pre-distortion (DPD) corrector circuitry to (b) a first corresponding sub-LUT of a second LUT of the DPD corrector circuitry, the first sub-LUT associated with the first delay circuitry, the second LUT storing updated values to compensate for non-linearity of power amplifier circuitry of a transmitter including the DPD corrector circuitry; and
based on a value of a counter being equal to a difference between (1) a first delay of the first delay circuitry and (2) a second delay of second delay circuitry, switching a second multiplexer circuit associated with the second delay circuitry from (a) a second sub-LUT of the first LUT to (b) a second corresponding sub-LUT of the second LUT, the second sub-LUT associated with the second delay circuitry.

18. The method of claim 17, further including loading the second LUT with the updated values.

19. The method of claim 17, wherein the updated values include first updated values and second updated values, and the method further includes:
loading the first sub-LUT with the first updated values, the first updated values being stored in the first corresponding sub-LUT of the second LUT;
loading the second sub-LUT with the second updated values, the second updated values being stored in the second corresponding sub-LUT of the second LUT;
switching the first multiplexer circuit from (a) the first corresponding sub-LUT of the second LUT to (b) the first sub-LUT of the first LUT in a clock cycle; and
switching the second multiplexer circuit from (a) the second corresponding sub-LUT of the second LUT to (b) the second sub-LUT of the first LUT in the clock cycle.

20. The method of claim 17, further including:
determining a first remainder of a first quantized sample of an input signal to the first LUT and a second remainder of a second quantized sample of the input signal when divided by two;
based on the first remainder being equal to the second remainder, perturbing one of the first quantized sample or the second quantized sample;
determining a third remainder of the first quantized sample when divided by two;
based on the third remainder equaling zero, causing a first memory to be indexed by the first quantized sample and a second memory to be indexed by the second quantized sample; and
based on the third remainder not equaling zero, causing the first memory to be indexed by the second quantized sample and the second memory to be indexed by the first quantized sample.

21. The method of claim 20, further including:
determining (a) a first error between a first sample of the input signal and the first quantized sample and (2) a second error between a second sample of the input signal and the second quantized sample;
based on a first absolute value of the first error being greater than a second absolute value of the second error, perturbing the first quantized sample; and
based on the first absolute value being less than the second absolute value, perturbing the second quantized sample.

22. The method of claim 20, further including:
based on the first remainder not being equal to the second remainder, determining whether the first remainder equals zero;
based on the first remainder equaling zero, causing the first memory to be indexed by the first quantized sample and the second memory to be indexed by the second quantized sample; and
based on the first remainder not equaling zero, causing the first memory to be indexed by the second quantized sample and the second memory to be indexed by the first quantized sample.

23. An apparatus comprising:
processor circuitry having an output terminal, the processor circuitry configured to generate a signal;
digital pre-distortion (DPD) corrector circuitry having an input terminal and an output terminal, the input terminal coupled to the output terminal of the processor circuitry; and
power amplifier (PA) circuitry having an input terminal coupled to the output terminal of the DPD corrector circuitry, the DPD corrector circuitry configured to:
access at least one lookup table based on first delayed versions of an envelope of the signal to determine first values, second values, and third values of non-linear functions that model a non-linearity of the PA circuitry;
determine first products based on the first values and second delayed versions of the signal;
determine second products based on the second values, conjugates of the second delayed versions of the signal, and a squared version of the signal;
determine third products based on the third values, the second delayed versions of the signal, and a squared envelope of the signal; and
determine a pre-distorted version of the signal based on a pre-distortion signal and the signal, the pre-distortion signal based on the first products, the second products, and the third products.

24. The apparatus of claim 23, wherein the DPD corrector circuitry is to determine a sum of the first products, the second products, and the third products to determine the pre-distortion signal.

25. The apparatus of claim 23, wherein the DPD corrector circuitry is to at least one of determine the envelope of the signal, generate the conjugates of the second delayed versions of the signal, generate the squared version of the signal, or generate the squared envelope of the signal.
